(19) United States
(12) Patent Application Publication
(10) Pub. No.: US 2026/0282588 A1
(43) Pub. Date: Sep. 17, 2026

(54) IMAGE SENSOR

(71) Applicant: Samsung Electronics Co., Ltd., Suwon-si (KR)

(72) Inventors: Donghyun Kim, Suwon-si (KR); Jihun Kim, Suwon-si (KR); Dahye Lee, Suwon-si (KR); Jinyong Choi, Suwon-si (KR); Mihye Kim, Suwon-si (KR)

(73) Assignee: Samsung Electronics Co., Ltd., Suwon-si (KR)

(21) Appl. No.: 19/405,889

(22) Filed: Dec. 2, 2025

(30) Foreign Application Priority Data
Mar. 12, 2025 (KR) 10-2025-0032243

(51) Int. Cl. H10F 39/00; H10F 39/18

(52) U.S. Cl. CPC H10F 39/811; H10F 39/014; H10F 39/182; H10F 39/80373; H10F 39/8053; H10F 39/8063; H10F 39/807

(57) ABSTRACT

Disclosed is an image sensor. The image sensor includes a semiconductor substrate, a PD isolation pattern disposed in the semiconductor substrate and defining first and second PD regions, a first floating diffusion region provided in the semiconductor substrate of the first PD region, an interconnection conductive pattern disposed on a first surface of the semiconductor substrate and contacting the first floating diffusion region, a source follower gate electrode provided in the second PD region, the source follower gate electrode including a first portion disposed on the semiconductor substrate of the second PD region and a second portion extended from the first portion and disposed on the PD isolation pattern, the second portion being adjacent to the interconnection conductive pattern, and a common contact plug commonly connected to the source follower gate electrode and the interconnection conductive pattern.

### CROSS-REFERENCE TO RELATED APPLICATIONS

This present application claims priority to and the benefit under 35 U.S.C. § 119(a)-(d) of Korean Patent Application No. 10-2025-0032243, filed on Mar. 12, 2025 in the Korean Intellectual Property Office, the entire disclosure of which is incorporated herein by reference.

### BACKGROUND

The present disclosure relates to an image sensor, and in particular, to an image sensor with improved electrical and optical characteristics.

An image sensor is a device that converts optical signals into electrical signals. With the recent development of the computer and communication industries, there is an increasing desire for high-performance image sensors in a variety of applications such as digital cameras, camcorders, personal communication systems, gaming machines, security cameras, micro-cameras for medical applications, and/or robots.

The image sensors are generally classified into charge-coupled device (CCD) and complementary metal-oxide semiconductor (CMOS) image sensors. Since the CMOS image sensors enable integration of a signal processing chip into a single chip, products of the CMOS image sensors can be reduced in size. The CMOS image sensors have very low power consumption and thus can be applicable to products with a limited battery capacity. Furthermore, since the CMOS image sensors are compatible with CMOS process technology, the manufacturing cost of the CMOS image sensors can be reduced. Therefore, the use of CMOS image sensors is rapidly increasing since high-resolution CMOS image sensors can be achieved with the development of technology.

### SUMMARY

Embodiments of the disclosed concepts provides an image sensor with improved electrical and optical characteristics.

According to some example embodiments of the disclosed concepts, an image sensor may include a semiconductor substrate, a PD isolation pattern disposed in the semiconductor substrate and defining first and second PD regions, a first floating diffusion region provided in the semiconductor substrate of the first PD region, an interconnection conductive pattern disposed on a first surface of the semiconductor substrate and contacting the first floating diffusion region, a source follower gate electrode provided in the second PD region, the source follower gate electrode including a first portion disposed on the semiconductor substrate of the second PD region and a second portion extended from the first portion and disposed on the PD isolation pattern, the second portion being adjacent to the interconnection conductive pattern, and a common contact plug commonly connected to the source follower gate electrode and the interconnection conductive pattern.

According to some example embodiments of the disclosed concepts, an image sensor may include a semiconductor substrate, a PD isolation pattern disposed within the semiconductor substrate to define first and second PD regions, a first floating diffusion region provided in the semiconductor substrate in the first PD region, a second floating diffusion region provided in the semiconductor substrate in the second PD region, an interconnection conductive pattern disposed on a first surface of the semiconductor substrate and contacting the first floating diffusion region, a pixel transistor provided in the second PD region and including a pixel gate electrode and source/drain regions at opposite sides of the pixel gate electrode, and a common contact plug connecting the interconnection conductive pattern with either the pixel gate electrode or the source/drain regions.

According to some example embodiments of the disclosed concepts, an image sensor may include a semiconductor substrate having a first surface and a second surface opposite to the first surface, a PD isolation pattern disposed in the semiconductor substrate to define first to fourth PD regions, photoelectric conversion regions provided in the semiconductor substrate in the first to fourth PD regions, a device isolation layer adjacent to the first surface of the semiconductor substrate, the device isolation layer defining first and second active portions in each of the first to fourth PD regions, transfer gate electrodes provided in the first active portions of the first to fourth PD regions, floating diffusion regions provided in the first active portions of the first to fourth PD regions, pixel transistors provided in the second active portions of the first to fourth PD regions, one of the pixel transistors including a pixel gate electrode including a first portion disposed on the second active portions in the third and fourth PD regions and second portions extending from the first portion and disposed on the PD isolation pattern and adjacent to the floating diffusion regions in the first and second PD regions, interconnection conductive patterns contacting the floating diffusion regions of the first to fourth PD regions, respectively, common contact plugs connecting the pixel gate electrode with the interconnection conductive patterns of the first to fourth PD regions, color filters disposed corresponding to the PD regions on the second surface of the semiconductor substrate, a grid disposed between the color filters and overlapping with the PD isolation pattern, and micro-Attorney lenses on the color filters.

According to some example embodiments of the disclosed concepts, a method of fabricating an image sensor may include forming a PD isolation pattern defining first and second PD regions in a semiconductor substrate; forming a device isolation layer adjacent to a first surface of the semiconductor substrate, the device isolation layer defining first and second active portions in each of the first and second PD regions; forming floating diffusion regions in the first active portions of the first and second PD regions; forming pixel gate electrodes on the second active portions of the first and second PD regions; forming interconnection conductive patterns on the floating diffusion regions of the first and second PD regions and on the first surface of the semiconductor substrate; forming an interlayer insulating layer covering the first surface of the semiconductor substrate; patterning the interlayer insulating layer to form a common contact hole exposing one of the interconnection conductive patterns and one of the pixel gate electrodes; and forming a common contact plug in the common contact hole.

In some example embodiments, forming the interconnection conductive patterns may include: forming a spacer insulating layer that covers the pixel gate electrodes and the first surface of the semiconductor substrate with a substantially uniform thickness; patterning the spacer insulating layer to form a spacer insulating pattern exposing the floating diffusion regions; depositing a conductive layer contacting the floating diffusion regions on the spacer insulating pattern; and patterning the conductive layer.

In some example embodiments, one of the pixel gate electrodes may include a first portion disposed on the semiconductor substrate of the second PD region and a second portion extended from the first portion and disposed on the PD isolation pattern and adjacent to the floating diffusion regions.

In some example embodiments, the common contact plug may have a length in a first direction and a width less than the length in a second direction perpendicular to the first direction.

In some example embodiments, the common contact hole may expose a portion of the PD isolation pattern between one of the interconnection conductive patterns and one of the pixel gate electrodes.

### BRIEF DESCRIPTION OF THE DRAWINGS

FIG. 1 is a block diagram illustrating an image sensor according to embodiments of the disclosed concepts.

FIGS. 2A and 2B are circuit diagrams illustrating a unit pixel of an image sensor according to embodiments of the disclosed concepts.

FIG. 3 is a plan view illustrating a portion of an image sensor according to embodiments of the disclosed concepts.

FIGS. 4A, 4B, and 4C are cross-sectional views taken along a line A-A′, a line B-B′, and a line C-C′ of FIG. 3, respectively.

FIGS. 5A and 5B are plan views illustrating an image sensor according to some embodiments of the disclosed concepts.

FIG. 6 is a plan view illustrating an image sensor according to embodiments of the invention.

FIGS. 7A, 7B, and 7C are cross-sectional views taken along a line D-D′, a line E-E′, and a line F-F′ of FIG. 6, respectively.

FIGS. 8A, 8B, 8C, 8D, and 8E are plan views illustrating an image sensor according to some embodiments of the disclosed concepts.

FIGS. 9A, 9B, and 9C are plan views illustrating an image sensor according to some embodiments of the disclosed concepts.

FIGS. 10A, 10B, 10C, 10D, 10E, and 10F are plan views illustrating an image sensor according to some embodiments of the disclosed concepts.

FIGS. 11A, 11B, 11C, and 11D are plan views illustrating an image sensor according to some embodiments of the disclosed concepts.

FIGS. 12A, 12C, 12D, 12E, 12F, and 12G are plan views illustrating an image sensor according to some embodiments of the disclosed concepts.

FIG. 12B is a cross-sectional view taken along a line G-G′ of FIG. 12A.

FIGS. 13A, 13B, 13C, 13D, 13E, and 13F are plan views illustrating an image sensor according to some embodiments of the disclosed concepts.

FIGS. 14A, 14B, 14C, 14D, 14E, and 14F are plan views illustrating an image sensor according to some embodiments of the disclosed concepts.

FIGS. 15A, 15B, 15C, and 15D are plan views illustrating an image sensor according to some embodiments of the disclosed concepts.

FIG. 16 is a circuit diagram illustrating a unit pixel of an image sensor according to embodiments of the disclosed concepts.

FIGS. 17A and 18A are plan views illustrating an image sensor according to some embodiments of the disclosed concepts.

FIGS. 17B and 18B are cross-sectional views taken along a line H-H′ of FIGS. 17A and 18A, respectively.

FIGS. 19, 20, 21, and 22 are plan views illustrating an image sensor according to some embodiments of the disclosed concepts.

FIGS. 23 to 27 are cross-sectional views, which are taken along a line A-A′ of FIG. 3 to illustrate a method of fabricating an image sensor according to embodiments of the disclosed concepts.

FIG. 28 is a schematic plan view illustrating an image sensor according to embodiments of the disclosed concepts.

FIGS. 29 and 30 are cross-sectional views, which are taken along a line I-I′ of FIG. 28 to illustrate an image sensor according to some example embodiments.

### DETAILED DESCRIPTION

Example embodiments of the disclosed concepts will now be described more fully with reference to the accompanying drawings, in which example embodiments are shown.

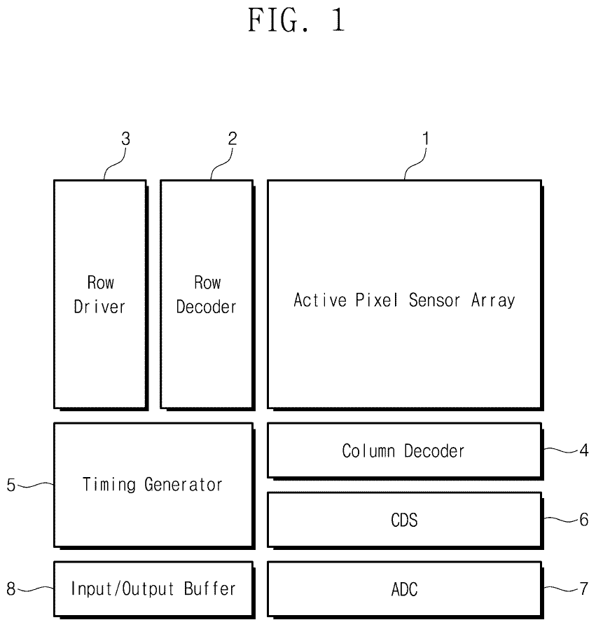

FIG. 1 is a block diagram illustrating an image sensor according to embodiments of the disclosed concepts.

Referring to FIG. 1, an image sensor may include an active pixel sensor array 1, a row decoder 2, a row driver 3, a column decoder 4, a timing generator 5, a correlated double sampler (CDS) 6, an analog-to-digital converter (ADC) 7, and an input/output buffer 8.

The active pixel sensor array 1 may include a plurality of two-dimensionally arranged unit pixels, each of which is configured to convert optical signals into electrical signals. The active pixel sensor array 1 may be driven by a plurality of driving signals such as a pixel selection signal, a reset signal, and a charge transfer signal from the row driver 3. The converted electrical signals may be provided for the correlated double sampler 6.

The row decoder 2 may provide the driving signals to the unit pixels of each row. In addition, electrical signals converted in the active pixel sensor array 1 may be provided to the correlated double sampler 6 in response to the driving signals.

The row driver 3 may provide the active pixel sensor array 1 with several driving signals for driving several unit pixels in accordance with a decoded result obtained from the row decoder 2. When the unit pixels are arranged in a matrix shape, the driving signals may be provided for respective rows.

The timing generator 5 may control the row and column decoders 2 and 4, the correlated double sampler 6, the analog-to-digital converter 7, and the input/output buffer 8 and may supply control signals (e.g., a clock signal, a timing control signal, etc.) in operation thereof. The timing generator 5 may include a logic control circuit, a phase lock loop (PLL) circuit, a timing control circuit, and a communication interface circuit.

The correlated double sampler (CDS) 6 may receive the electrical signals generated in the active pixel sensor array 1, and may hold and sample the received electrical signals. The correlated double sampler 6 may perform a double sampling operation to sample a specific noise level and a signal level of the electrical signal, and then output a difference level corresponding to a difference between the noise and signal levels.

The analog-to-digital converter (ADC) 7 may convert analog signals, which correspond to the difference level received from the correlated double sampler 6, into digital signals and then output the converted digital signals.

The input/output buffer 8 may latch the digital signals and then sequentially output the latched digital signals to an image signal processing unit (not shown) in response to the decoded result obtained from the column decoder 4.

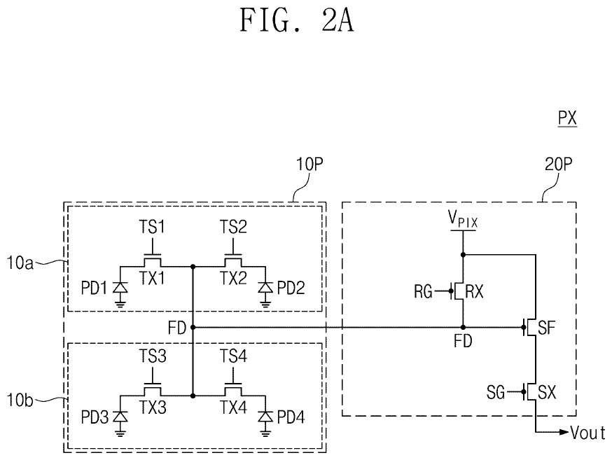

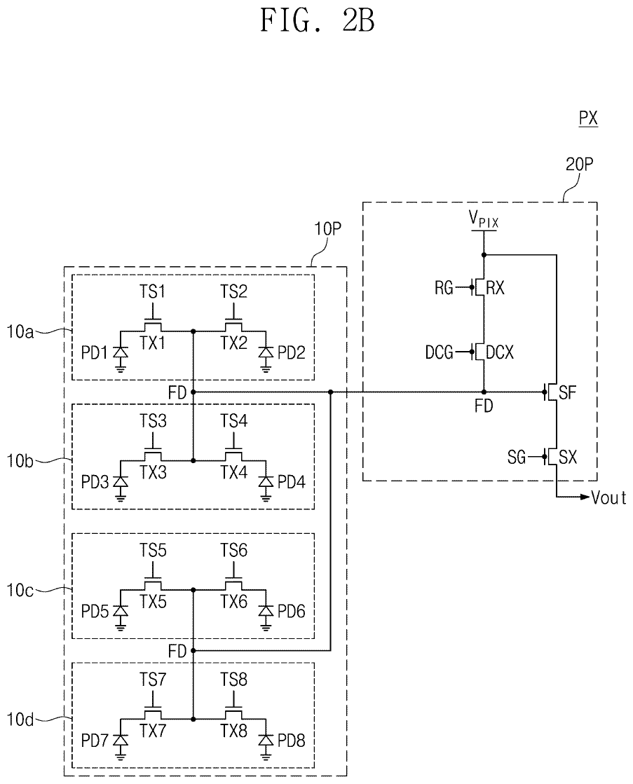

FIGS. 2A and 2B are circuit diagrams illustrating a unit pixel of an image sensor according to embodiments of the disclosed concepts.

Referring to FIG. 2A, a unit pixel PX may include a photoelectric conversion circuit 10P and a pixel circuit 20P.

The photoelectric conversion circuit 10P may include a plurality of photoelectric conversion groups 10a and 10b. The photoelectric conversion circuit 10P may comprise at least 2, 4, 8 or 16 photoelectric conversion groups 10a and 10b. Each of the photoelectric conversion groups 10a and 10b may include at least 2, 4, 8, or 16 photoelectric conversion elements (e.g., photodiodes), a plurality of transfer transistors, and a floating diffusion region.

In some embodiments, the photoelectric conversion circuit 10P may include first and second photoelectric conversion groups 10a and 10b.

The first photoelectric conversion group 10a may include a first photoelectric conversion element PD1, a second photoelectric conversion element PD2, a first transfer transistor TX1, and a second transfer transistor TX2. The first and second transfer transistors TX1 and TX2 transfer the charge accumulated in the first and second photoelectric conversion elements PD1 and PD2 to a floating diffusion region FD.

The second photoelectric conversion group 10b may include a third photoelectric conversion element PD3, a fourth photoelectric conversion element PD4, a third transfer transistor TX3, and a fourth transfer transistor TX4. The third and fourth transfer transistors TX3 and TX4 transfer the charges accumulated in the third and fourth photoelectric conversion elements PD3 and PD4 to the floating diffusion region FD.

The first to fourth transfer transistors TX1, TX2, TX3, and TX4 may share a floating diffusion region FD. Transmission gate electrodes of the first to fourth transmission transistors TX1, TX2, TX3, and TX4 may be controlled by the first to fourth transfer signals TS1, TS2, TS3, and TS4.

In detail, the first to fourth photoelectric conversion elements PD1 to PD4 may generate and accumulate a charge corresponding to incident light. The first to fourth photoelectric conversion elements PD1 to PD4 may be, for example, a photo diode, a photo transistor, a photo gate, a pinned photo diode (PPD), or a combination thereof.

The floating diffusion region FD receives and cumulatively stores the charge generated in at least one of the first to fourth photoelectric conversion elements PD1 to PD4. The source follower transistor SF may be controlled according to the amount of photo charges accumulated in the floating diffusion region FD.

The pixel circuit 20P may include a reset transistor RX, a source follower transistor SF, and a selection transistor SX. In some embodiments, it is disclosed that each unit pixel PX includes three pixel transistors, however, example embodiments are not limited thereto. The number of the pixel transistors in each unit pixel PX may be variously changed.

In detail, the reset transistor RX may periodically reset electric charges accumulated in the floating diffusion region FD by the reset signal RG applied to the reset gate electrode. In more detail, the reset transistor RX may include a source terminal connected to the floating diffusion region FD and a drain terminal connected to the power supply voltage VPIX. When the reset transistor RX is turned on, the power supply voltage VpIx may be transferred to the floating diffusion region FD. Accordingly, the electric charges accumulated in the floating diffusion region FD may be discharged to reset the floating diffusion region FD.

The source follower transistor SF may be a source follower buffer amplifier, which is configured to produce a source-drain current in proportional to a charge amount of the floating diffusion region FD to be input to a source follower gate electrode. The source follower transistor SF may amplify a change in electric potential of the charge detection node and may output the amplified signal to the output line Vout through the selection transistor SX. The source follower transistor SF may include a drain terminal connected to the power supply voltage VpIx and a source terminal connected to a drain terminal of the selection transistor SX.

The selection transistor SX may be used to select a row of unit pixels P to be read out. When the selection transistor SX is turned on by the selection signal SG applied to the selection gate electrode, an electrical signal output to the source electrode of the source follower transistor SF may be delivered to the output line Vout.

Referring to FIG. 2B, the photoelectric conversion circuit 10P may include first, second, third, and fourth photoelectric conversion groups 10a, 10b, 10c, and 10d. Each of the first, second, third, and fourth photoelectric conversion groups 10a, 10b, 10c, and 10d may include two photoelectric conversion elements and two transfer transistors.

In detail, the photoelectric conversion circuit 10P may include first to eighth photoelectric conversion elements PD1 to PD8, first to eighth transfer transistors TX1 to TX8, and a floating diffusion region FD. Here, the first and second photoelectric conversion elements PD1 and PD2 and the first and second transfer transistors TX1 and TX2 may constitute the first photoelectric conversion group 10a. The third and fourth photoelectric conversion elements PD3 and PD4 and the third and fourth transfer transistors TX3 and TX4 may constitute the second photoelectric conversion group 10b.

The fifth and sixth photoelectric conversion elements PD5 and PD6 and the fifth and sixth transfer transistors TX5 and TX6 may constitute the third photoelectric conversion group 10c. The seventh and eighth photoelectric conversion elements PD7 and PD8 and the seventh and eighth transfer transistors TX7 and TX8 may constitute the fourth photoelectric conversion group 10d.

The first to fourth photoelectric conversion groups 10a, 10b, 10c, and 10d may be commonly connected to the floating diffusion region FD. In other words, the first to eighth transfer transistors TX1 to TX8 may be commonly connected to the floating diffusion region FD.

Although each of the first to fourth photoelectric conversion groups 10a, 10b, 10c, and 10d is shown to include two photodiodes, the disclosed concepts is not limited thereto, and each photoelectric conversion group may include four or eight photodiodes.

The transfer gate electrodes of the first to eighth transfer transistors TX1 to TX8 may be controlled by the first to eighth charge transfer signals TS1 to TS8. The transfer gate electrode of each transfer transistor herein may have a dual vertical gate structure. The dual vertical gate structure may mean that there are two vertical transfer gates corresponding to one photodiode. The same transfer control signal may be applied to each of the two vertical transfer gates included in the dual vertical gate.

The floating diffusion region FD may receive and cumulatively store the charges generated in at least one of the first to eighth photoelectric conversion elements PD1 to PD8. The source follower transistor SF may be controlled according to the amount of photo charges accumulated in the floating diffusion region FD.

The pixel circuit 20P may include a reset transistor RX, a source follower transistor SF, and a selection transistor SX as described above with reference to FIG. 2A, and may further include a dual conversion gain transistor DCX.

The dual conversion gain transistor DCX may be connected between the floating diffusion region FD and the reset transistor RX. When the reset transistor RX and the dual conversion gain transistor DCX are turned on, the power supply voltage VpIx may be transferred to the floating diffusion region FD. Thus, the electric charges, which are accumulated in the floating diffusion region FD, may be discharged to reset the floating diffusion region FD.

The dual conversion gain transistor DCX may change a capacitance of the floating diffusion region FD in response to a dual conversion gain control signal DCG, thereby changing the conversion gain of the unit pixel PX.

In detail, during image capture, light of low brightness and high brightness may be incident into a pixel array, and the dual conversion gain transistor DCX may be turned on in a high brightness mode and may be turned off in a low brightness mode. Due to the dual conversion gain transistor DCX, it may be possible to realize different conversion gains in the high and low brightness modes.

When the dual conversion gain transistor DCX is turned on, the capacitance of the floating diffusion region FD may be increased and the conversion gain may be decreased, and when the dual conversion gain transistor DCX is turned off, the capacitance of the floating diffusion region FD may be decreased and the conversion gain may be increased.

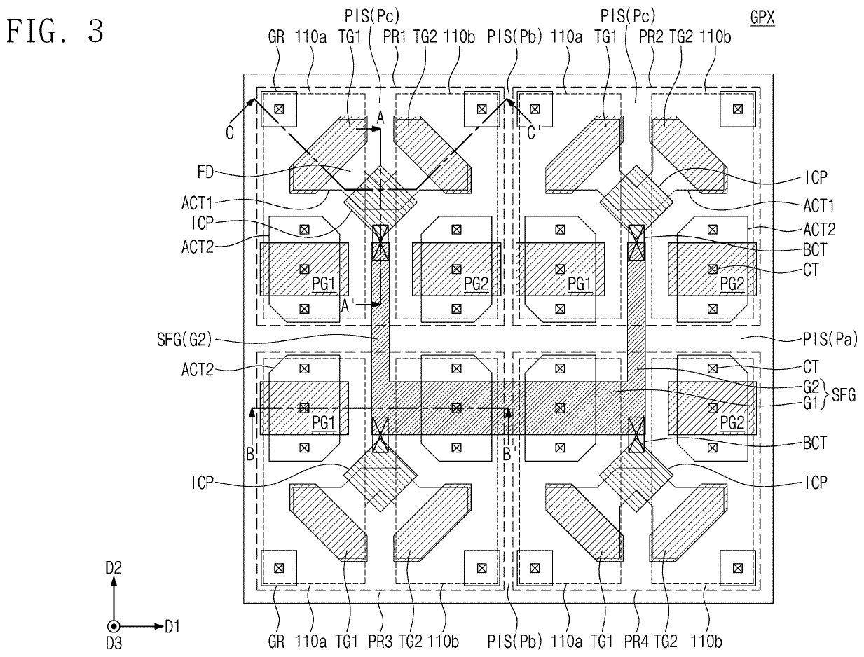

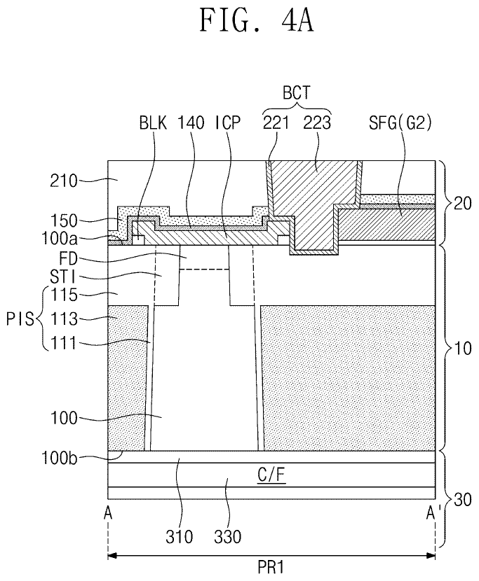

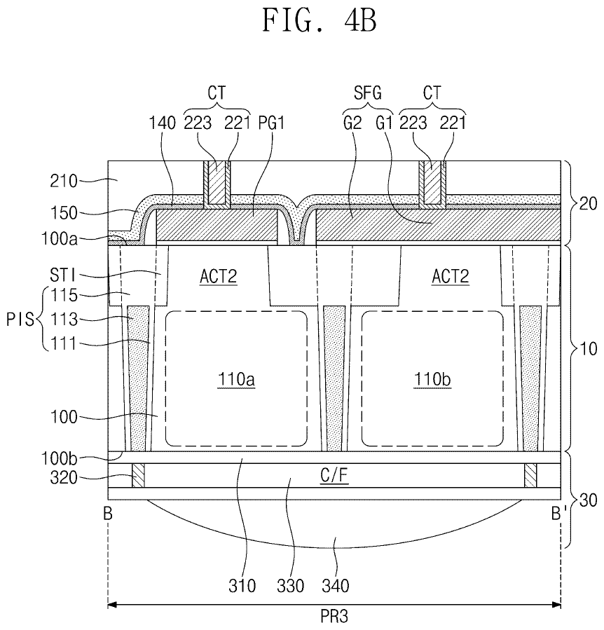

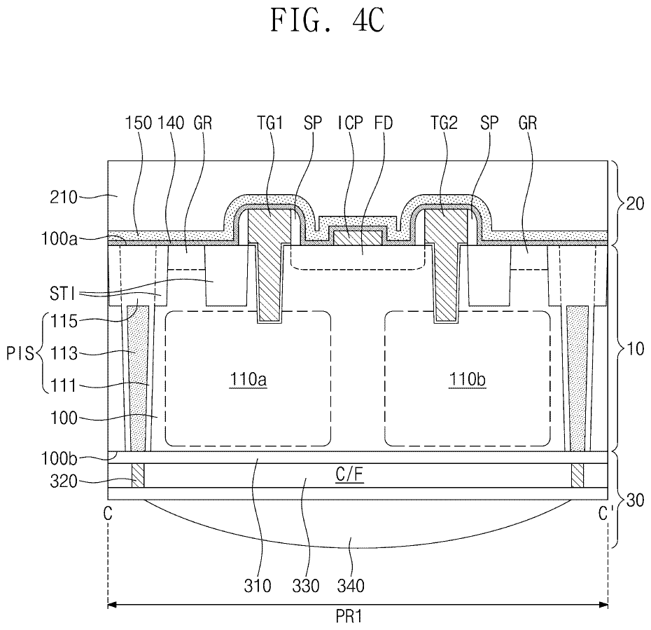

FIG. 3 is a plan view illustrating a portion of an image sensor according to embodiments of the disclosed concepts. FIGS. 4A, 4B, and 4C are cross-sectional views taken along a line A-A′, a line B-B′, and a line C-C′ of FIG. 3, respectively.

Referring to FIGS. 3, 4A, 4B, and 4C, an image sensor according to some example embodiments may include a photoelectric conversion circuit layer 10, a pixel circuit layer 20, and an optically-transparent layer 30.

The photoelectric conversion circuit layer 10 may be disposed between the pixel circuit layer 20 and the optically-transparent layer 30 in a plan view. The photoelectric conversion circuit layer 10 may include a semiconductor substrate 100, a PD isolation pattern PIS, a device isolation layer STI, photoelectric conversion regions 110a and 110b, transfer gate electrodes TG1 and TG2, and floating diffusion regions FD.

The pixel circuit layer 20 may include pixel circuits (e.g., MOS transistors) electrically connected to the floating diffusion regions FD. In other words, the pixel circuit layer 20 may include the reset transistor RX, the selection transistor SX, the dual conversion gain transistor DCX, and the source follower transistor SF, which were described with reference to FIGS. 2A and 2B, and interconnection lines, which are connected to the pixel circuit 20P of FIGS. 2A to 2B.

In detail, the semiconductor substrate 100 may have a first surface 100a (or a front surface) and a second surface 100b (or a rear surface) opposite to the first surface 100a. The semiconductor substrate 100 may be or may include a substrate of a first conductivity type (e.g., p-type) including a bulk silicon substrate and an epitaxial layer on the bulk silicon substrate. In the case where the bulk silicon substrate is removed during a process of fabricating the image sensor, the semiconductor substrate 100 may have only the p-type epitaxial layer. In some example embodiments, the semiconductor substrate 100 may be a bulk semiconductor substrate including a well of a first conductivity type.

The semiconductor substrate 100 may include a plurality of PD regions PR1, PR2, PR3, and PR4 defined by the PD isolation pattern PIS. The plurality of PD regions PR1, PR2, PR3, and PR4 may be arranged in a first direction D1 and a second direction D2 intersecting 14 the first direction D1, or in a matrix shape.

The plurality of PD regions may include first, second, third, and fourth PD regions PR1, PR2, PR3, and PR4. The first and second PD regions PR1 and PR2 may be disposed adjacent to each other in the first direction D1, and the first and third PD regions PR1 and PR3 may be disposed adjacent to each other in the second direction D2. The second and fourth PD regions PR2 and PR4 may be adjacent to each other in the second direction D2, and the second and third PD regions PR2 and PR3 may be disposed in a diagonal direction. Here, the first and second directions D1 and D2 are parallel to the first surface 100a of the semiconductor substrate 100 and may intersect with each other. The third direction D3 may be a direction perpendicular to the first surface 100a of the semiconductor substrate 100.

The first to fourth PD regions PR1 to PR4 may constitute a single PD group GPX. In some embodiments, each PD group GPX is illustrated to include four PD regions PR1, PR2, PR3, and PR4, but the disclosed concepts is not limited thereto. For example, the PD group GPX may be composed of 6, 8, 9, 16, or the like PD regions.

Each of the first to fourth PD regions PR1 to PR4 may be surrounded by the PD isolation pattern PIS in a plan view. Each of the first to fourth PD regions PR1 to PR4 may be defined by a pair of first portions Pa extending in the first direction D1 and a pair of second portions Pb extending in the second direction D2. In addition, the PD isolation pattern PIS may include at least one third portion Pc in each of the first to fourth PD regions PR1 to PR4. The third portion Pc may extend from the first portions Pa in the second direction D2.

In some embodiments, the PD isolation pattern PIS may penetrate the semiconductor substrate 100. In detail, the PD isolation pattern PIS may have a length in a direction perpendicular to the surface of the semiconductor substrate 100 (i.e., the third direction D3), and the length of the PD isolation pattern PIS may be substantially the same as the vertical thickness of the semiconductor substrate 100. As another example, the PD isolation pattern PIS may extend vertically from the first surface 100a to the second surface 100b of the semiconductor substrate 100, and may be spaced apart from the second surface 100b of the semiconductor substrate.

In some embodiments, the PD isolation pattern PIS may include a liner insulating pattern 111, a buried pattern 113, and a capping insulation pattern 115. The buried pattern 113 may vertically penetrate a portion of the semiconductor substrate 100, and the liner insulating pattern 111 may be provided between the buried pattern 113 and the semiconductor substrate 100. The capping insulation pattern 115 may be disposed on the buried pattern 113. Each of the liner insulating pattern 111 and the capping insulation pattern 115 may include at least one of a silicon oxide layer, a silicon oxynitride layer, or a silicon nitride layer. The buried pattern 113 may include an undoped poly-silicon layer and/or a doped poly-silicon layer. The buried pattern 113 may include an air gap or may define a void. The capping insulation pattern 115 of the PD isolation pattern PIS may be formed of or include the same insulating material as the device isolation layer STI, and in this case, there may be no visible or observable boundary or interface between the capping insulation pattern 115 and the device isolation layer STI.

According to some example embodiments, in each of the first to fourth PD regions PR1 to PR4, the first and second photoelectric conversion regions 110a and 110b may be provided in the semiconductor substrate 100. Light, which is incident from the outside, may be converted to electrical signals, in the first and second photoelectric conversion regions 110a and 110b.

The first and second photoelectric conversion regions 110a and 110b may be impurity regions, which are doped with impurities of a second conductivity type (e.g., n-type) opposite to the first conductivity type of the semiconductor substrate 100. The semiconductor substrate 100 of the first conductivity type and the first and second photoelectric conversion regions 110a and 110b may constitute a pair of photodiodes. For example, a junction serving as a photodiode may be formed by the semiconductor substrate 100 of the first conductivity type and the first or second photoelectric conversion region 110a or 110b of the second conductivity type. In the case where light is incident into the first and second photoelectric conversion regions 110a and 110b constituting the photodiode, photocharges may be generated and accumulated in proportion to an intensity of the incident light.

In each of the first to fourth PD regions PR1 to PR4, electrical signals, which are output from the first and second photoelectric conversion region 110a and 110b, may have a phase difference. The image sensor may be configured to measure a distance to a target object based on a difference in phase between the electrical signals, which are output from the pair of first and second photoelectric conversion regions 110a and 110b, to examine whether the target object is in focus or a degree to which it is out of focus, and to correct, e.g., to automatically correct the focus of the image sensor based the examined result.

Each of the first and second photoelectric conversion regions 110a and 110b may have a first width in the first direction D1 and a first length greater than the first width in the second direction D2. In In some embodiments, the first length may be about twice the first width.

The first and second photoelectric conversion regions 110a and 110b may be spaced apart from each other in the first direction D1 with the third portions Pc of the PD isolation pattern PIS interposed therebetween. The third portions Pc of the PD isolation pattern PIS may be configured to physically reflect the incident light at an edge of each of the first to fourth PD 17 regions PR1 to PR4 and thus, it may be possible to reduce a cross-talk between the first and second photoelectric conversion regions 110a and 110b.

The device isolation layer STI may be disposed adjacent to the first surface 100a of the semiconductor substrate 100, in each of the first to fourth PD regions PR1 to PR4. A lower surface of the device isolation layer STI may be spaced apart from the first and second photoelectric conversion regions 110a and 110b.

The device isolation layer STI may be provided in a trench, which is formed by recessing a portion of the first surface 100a of the semiconductor substrate 100. The device isolation layer STI may be formed of an insulating material. In some embodiments, the device isolation layer STI may include a liner oxide layer and a liner nitride layer, which are formed to conformally cover an inner surface of the trench, and a buried oxide layer filling the trench in which the liner oxide layer and the liner nitride layer are formed. The buried oxide layer may include, for example, at least one of a silicon oxide layer, a silicon oxynitride layer, or a silicon nitride layer.

According to some embodiments, the device isolation layer STI may define a first active portion ACT1 and second active portions ACT2 in each of the first to fourth PD regions PR1 to PR4. In some example embodiments, one first active portion ACT1 and two second active portions ACT2 may be provided in each of the PD regions PR1 to PR4, but example embodiments are not limited thereto.

The first and second active portions ACT1 and ACT2 may be portions of the semiconductor substrate 100. The first and second active portions ACT1 and ACT2 may have polygonal shapes of various shapes, such as rhombuses.

In some example embodiments, the first active portion ACT1 may include a first portion overlapping with the first photoelectric conversion region 110a, a second portion overlapping with the second photoelectric conversion region 110b, and a connecting portion connecting the first portion and the second portion. The connecting portion of the first active portion ACT1 may be disposed between the first and second photoelectric conversion regions 110a and 110b.

The second active portions ACT2 may overlap the first and second photoelectric conversion regions 110a and 110b, respectively, in a plan view. The second active portions ACT2 may be spaced apart from the first active portion ACT1 by the device isolation layer STI therebetween. The second active portions ACT2 may have a long axis in the second direction D2 and may have a short axis in the first direction D1. Each of the second active portions ACT2 may have a second length smaller than the first length of the first or second photoelectric conversion regions 110a and 110b in the second direction D2.

The first and second active portions ACT1 and ACT2 of the third and fourth PD regions PR3 and PR4 may be disposed mirror symmetrically with the first and second active portions ACT1 and ACT2 of the first and second PD regions PR1 and PR2.

In each of the first to fourth PD regions PR1 to PR4, the first and second transfer gate electrodes TG1 and TG2 may be disposed on the first surface 100a of the semiconductor substrate 100. The first and second transfer gate electrodes TG1 and TG2 may be disposed on the first active portion ACT1. Portions of the first and second transfer gate electrodes TG1 and TG2 may be disposed in a trench, which is formed by recessing the first surface 100a of the semiconductor substrate 100. A gate insulating layer may be interposed between the first and second transfer gate electrodes TG1 and TG2 and the semiconductor substrate 100. Insulating spacers SP may be disposed on opposite sidewalls of each of the first and second transfer gate electrodes TG1 and TG2.

In some embodiments, each of the first and second transfer gate electrodes TG1 and TG2 may have a dual vertical gate electrode structure, in which two vertical portions are extended into the semiconductor substrate 100. In some embodiments, the shapes and positions of the first and second transfer gate electrodes TG1 and TG2 may be variously modified.

In each of the first to fourth PD regions PR1 to PR4, the floating diffusion region FD may be provided in a portion of the first active portion ACT1 between the first and second transfer gate electrodes TG1 and TG2.

The floating diffusion region FD may be formed by doping dopants of a second conductivity type opposite to the first conductivity type of the semiconductor substrate 100. For example, the floating diffusion region FD may be an n-type dopant region.

In each of the first to fourth PD regions PR1 to PR4, pixel transistors may be provided on the second active portions ACT2. The pixel transistors may include the source follower transistor SF of FIGS. 2A and 2B, the reset transistor RX of FIGS. 2A and 2B, the dual-conversion gain transistor DCX of FIG. 2B, and the select transistor SX of FIGS. 2A and 2B.

In each of the first and second PD regions PR1 and PR2, first and second pixel gate electrodes PG1 and PG2 may be respectively disposed on the second active portions ACT2. In the third PD region PR3, the first pixel gate electrode PG1 may be disposed on one of the second active portions ACT2. In the fourth PD region PR4, the second pixel gate electrode PG2 may be disposed on the one of the second active portions ACT2.

Source/drain regions SDR may be provided in the second active portions ACT2 at opposite sides of the first and second pixel gate electrodes PG1 and PG2. The insulating spacers SP may be disposed on opposite sidewalls of the first and second pixel gate electrodes PG1 and PG2.

In each of the first to fourth PD regions PR1 to PR4, the first and second pixel gate electrodes PG1 and PG2 may constitute at least one of the pixel transistors (e.g., the reset, source follower, dual conversion gain, and selection transistors RX, SF, DCX, and SX) previously described with reference to FIGS. 2A and 2B. Functions of the first and second pixel gate electrodes PG1 and PG2 in the first to fourth PD regions PR1 to PR4 may be variously changed.

According to some embodiments, a third pixel gate electrode may be commonly disposed on the second active portions ACT2 adjacent to each other in the third and fourth PD regions PR3 and PR4. The third pixel gate electrode may correspond to a source follower gate electrode SFG of the source follower transistor SF described with reference to FIGS. 2A and 2B.

Source/drain regions SDR may be provided in the second active portions ACT2 at opposite sides of the source follower gate electrode SFG. The insulating spacers SP may be disposed on opposite sidewalls of the source follower gate electrode SFG.

The source follower gate electrode SFG may be longer than the first and second pixel gate electrodes PG1 and PG2 in the first direction D1. In some embodiments, the source follower gate electrode SFG may cross the second active portions ACT2 adjacent to each other in the third and fourth PD regions PR3 and PR4.

According to some embodiments, the source follower gate electrode SFG may include a first portion G1 crossing the second active portions ACT2 in the third and fourth PD regions PR3 and PR4 and second portions G2 extended from the first portion G1 in the second direction D2 and disposed adjacent to the floating diffusion regions FD of the first and second PD regions 21 PR1 and PR2. The second portions G2 of the source follower gate electrode SFG may be disposed on the PD isolation pattern PSI or the device isolation layer STI.

One of the second portions G2 of the source follower gate electrode SFG may be adjacent to the floating diffusion region FD in the first PD region PR1, and the other one of the second portions G2 may be adjacent to the floating diffusion region FD in the second PD region PR2. A width of the second portions G2 may be less than that of the first portion G1.

Further, ground impurity regions GR may be provided in each of the first to fourth PD regions PR1 to PR4. The ground impurity regions GR may be adjacent to the first surface 100a of the semiconductor substrate 100, and may overlap the first and second photoelectric conversion regions 110a and 110b in a plan view. The ground impurity regions GR may be formed by doping dopants of the same first conductivity type as the semiconductor substrate 100.

According to some embodiments, an interconnection conductive pattern ICP may be disposed on the first surface 100a of the semiconductor substrate 100, and may contact the floating diffusion region FD provided in the first active portion ACT1 in each of the first to fourth PD regions PR1 to PR4.

In a plan view, the interconnection conductive pattern ICP may have various polygonal shapes such as a square, a rectangle, a circle, and a rhombus. The interconnection conductive pattern ICP may be formed of or include a conductive material. The interconnection conductive pattern ICP may be formed of single crystal silicon or poly-crystalline silicon that is doped with dopants of the second conductivity type. In addition, the interconnection conductive pattern ICP may include at least one of metallic materials such as tungsten, titanium, tantalum, cobalt, or the like. A concentration of the second conductivity type dopants in the interconnection conductive pattern ICP may be higher than a doping concentration in the floating diffusion region FD.

The interconnection conductive pattern ICP may have a first thickness on a first surface 100a of the semiconductor substrate 100, and each of the first and second pixel gate electrodes PG1 and PG2 and the source follower gate electrode SFG may have a second thickness on the first surface 100a of the semiconductor substrate 100. Here, the second thickness may be greater than the first thickness.

The interconnection conductive patterns ICP of the first and second PD regions PR1 and PR2 may be adjacent to the second portions G2 of the source follower gate electrode SFG. The interconnection conductive patterns ICP of the third and fourth PD regions PR3 and PR4 may be adjacent to the first portion G1 of the source follower gate electrode SFG.

In addition, the interconnection conductive pattern ICP may include an edge portion adjacent to an outer sidewall thereof and a pad portion contacting the floating diffusion region FD. The interconnection conductive pattern ICP may have a first top surface at an edge portion thereof and a second top surface at a pad portion thereof, and the first top surface may be positioned at a higher level than the second top surface with respect to the first surface 100a of the semiconductor substrate 100. The interconnection conductive pattern ICP may have a first lower surface contacting the device isolation layer STI and a second lower surface contacting the floating diffusion region FD, and the first lower surface and the second lower surface may be located at different levels.

According to some embodiments, a blocking pattern BLK may be disposed between an edge portion of the interconnection conductive pattern ICP and the semiconductor substrate 100, the device isolation layer STI, or the PD isolation pattern PIS. The blocking pattern BLK may be disposed along the outer sidewall of the interconnection conductive pattern ICP.

The blocking pattern BLK may include the same insulating material as the insulating spacers SP disposed on opposite sidewalls of the first and second transfer gate electrodes TG1 and TG2 and disposed on opposite sidewalls of first and second pixel gate electrodes PG1 and PG2. The blocking pattern BLK may include, for example, silicon oxide, silicon nitride, and/or silicon oxynitride. The blocking pattern BLK may prevent the edge portion of the interconnection conductive pattern ICP from contacting the first and second active portions ACT1 and ACT2.

First and second etch stop layers 140 and 150 may be sequentially stacked on the first surface 100a of the semiconductor substrate 100. The first and second etch stop layers 140 and 150 may cover the first and second transfer gate electrodes TG1 and TG2, the first and second pixel gate electrodes PG1 and PG2, the pixel gate electrode PG, and the interconnection conductive pattern ICP with a substantially uniform thickness. The first and second etch stop layers 140 and 150 may include, for example, silicon oxide, silicon nitride, or silicon oxynitride. The second etch stop layer 150 may be thicker than the first etch stop layer 140. The first etch stop layer 140 may cover an outer sidewall of the blocking pattern BLK and the outer sidewall of the interconnection conductive pattern ICP with a substantially uniform thickness.

An interlayer insulating layer 210 may be disposed on the first surface 100a of the semiconductor substrate 100, and the interlayer insulating layer 210 may cover the first and second transfer gate electrodes TG1 and TG2 and the pixel transistors RX, SF, DCX, and SX of FIGS. 2A and 2B. The interlayer insulating layer 210 may include, for example, silicon oxide, silicon nitride, and/or silicon oxynitride.

The pixel circuit 20P of FIGS. 2A and 2B, contact plugs CT, and common contact plugs BCT may be disposed in the interlayer insulating layer 210.

The contact plugs CT may penetrate the interlayer insulating layer 210 and the first and second etch stop layers 140 and 150 to be connected to the first and second pixel gate electrodes PG1 and PG2 and the source/drain regions SDR, respectively.

According to some embodiments, the common contact plugs BCT may be commonly connected to the source follower gate electrode SFG and the interconnection conductive patterns ICP of the first to fourth PD regions PR1 to PR4.

The common contact plugs BCT may electrically and commonly connect the source follower gate electrode SFG with the interconnection conductive patterns ICP of the first to fourth PD regions PR1 to PR4.

In detail, in the first and second PD regions PR1 and PR2, the common contact plugs BCT may be disposed between the interconnection conductive patterns ICP and the second portions G2 of the source follower gate electrode SFG.

In the third and fourth PD regions PR3 and PR4, the common contact plugs BCT may be disposed between the interconnection conductive patterns ICP and the first portion G1 of the source follower gate electrode SFG.

Each of the common contact plugs BCT may contact a portion of the top surface of the interconnection conductive pattern ICP, and may contact a portion of a top surface of the source follower gate electrode SFG. In addition, a portion of each common contact plug BCT may directly contact the device isolation layer STI or the PD isolation pattern PIS between the interconnection conductive pattern ICP and the source follower gate electrode SFG. In addition, each of the common contact plugs BCT may directly contact one sidewall of the source follower gate electrode SFG and one sidewall of the interconnection conductive pattern ICP.

In some example embodiments, each of the common contact plugs BCT may have a width in the first direction D1 and a length greater than a width in the second direction D2. A length of each common contact plug BCT may be greater than a distance between the interconnection conductive pattern ICP and the second portion G2 of the source follower gate electrode SFG. Each of the common contact plugs BCT may have a rectangular or elliptical shape in a plan view.

A bottom surface of the common contact plugs BCT may be continuously extended from the top surface of the interconnection conductive pattern ICP to the top surface of the source follower gate electrode SFG. The bottom surfaces of the common contact plugs BCT may be located at different levels from bottom surfaces of the contact plugs CT.

The lower surface of the common contact plugs BCT between the interconnection conductive pattern ICP and the source follower gate electrode SFG may be located at a lower level than the top surface of the device isolation layer STI or the PD isolation pattern PIS.

The top surfaces of the common contact plugs BCT may be substantially coplanar with the top surfaces of the contact plugs CT. In addition, the top surfaces of the common contact plugs BCT may be substantially coplanar with a top surface of the interlayer insulating layer 210.

Each of the contact plugs CT and the common contact plugs BCT may include a barrier metal pattern 221 and a metal pattern 223. The barrier metal pattern 221 may cover the lower surface and sidewalls of the metal pattern 223 with a substantially uniform thickness. The barrier metal pattern 221 may include a conductive metal nitride layer such as titanium nitride (TiN), tantalum nitride (TaN), and tungsten nitride (WN). The metal pattern 223 may include metallic materials such as tungsten (W), titanium (Ti), tantalum (Ta), copper (Cu), or an alloy thereof.

According to some embodiments, the floating diffusion regions FD in the first to fourth PD regions PR1 to PR4 may be commonly and electrically connected to one source follower gate electrode SFG through the interconnection conductive patterns ICP and the common contact plugs BCT.

The optically-transparent layer 30 may be disposed on the second surface 100b of the semiconductor substrate 100. The optically-transparent layer 30 may include a planarization insulating layer 310, a grid 320, color filters 330, and micro-lenses 340. The optically-transparent layer 30 may perform an operation of focusing and filtering light, which is incident from the outside, and to provide the light to the photoelectric conversion circuit layer 10.

The planarization insulating layer 310 may cover the second surface 100b of the semiconductor substrate 100. The planarization insulating layer 310 may be formed of a transparent insulating material, and may include a plurality of layers. The planarization insulating layer 310 may be formed of an insulating material having a refractive index different from the semiconductor substrate 100. The planarization insulating layer 310 may include a metal oxide and/or a silicon oxide.

The grid 320 may be disposed on the planarization insulating layer 310. The grid 320 may have a grating shape in a plan view, similar to the PD isolation pattern PIS. The grid 320 may overlap the PD isolation pattern PIS in a plan view. In other words, the grid 320 may include first portions extending in the first direction D1, and second portions extending in the second direction D2 and crossing the first portions. A width of the grid 320 may be substantially equal to or less than the minimum width of the PD isolation pattern PIS.

The grid 320 may include a light-blocking pattern and/or a low refractive pattern. The light-blocking pattern may comprise, for example, a metallic material such as titanium, tantalum or tungsten. The low refractive pattern may be formed of a material having a lower refractive index than the conductive pattern. The low refractive pattern may be formed of an organic material and may have a refractive index of about 1.1 to 1.3. For example, the grid 320 may be a polymer layer containing silica nanoparticle.

The color filters 330 may be formed to correspond to the first to fourth PD regions PR1 to PR4. The color filters 330 may be provided to fill spaces defined by the grid 320. The color filters 330 may include red, green, or blue color filters or magenta, cyan, or yellow color filters, which are determined based on positions of the unit pixels. In some embodiments, at least one of the color filters 330 may include an infrared filter.

The micro-lenses 340 may be disposed on the color filters 330. The micro-lenses 340 may have a convex shape and may have a predetermined radius of curvature. The micro-lenses 340 may be formed of an optically transparent resin. The micro-lenses 340 may be disposed on the color filters 330 to correspond to each of PD regions PR1 to PR4. In some embodiments, at least one of the micro-lenses 340 may be commonly disposed on the at least two PD regions PR1 to PR4.

Hereinafter, an image sensor according to various example embodiments of the disclosed concepts will be described. For concise description, the same technical features as the image sensor described above with reference to FIGS. 3, 4A, 4B, and 4C may be omitted from the following description, and different technical features will be described.

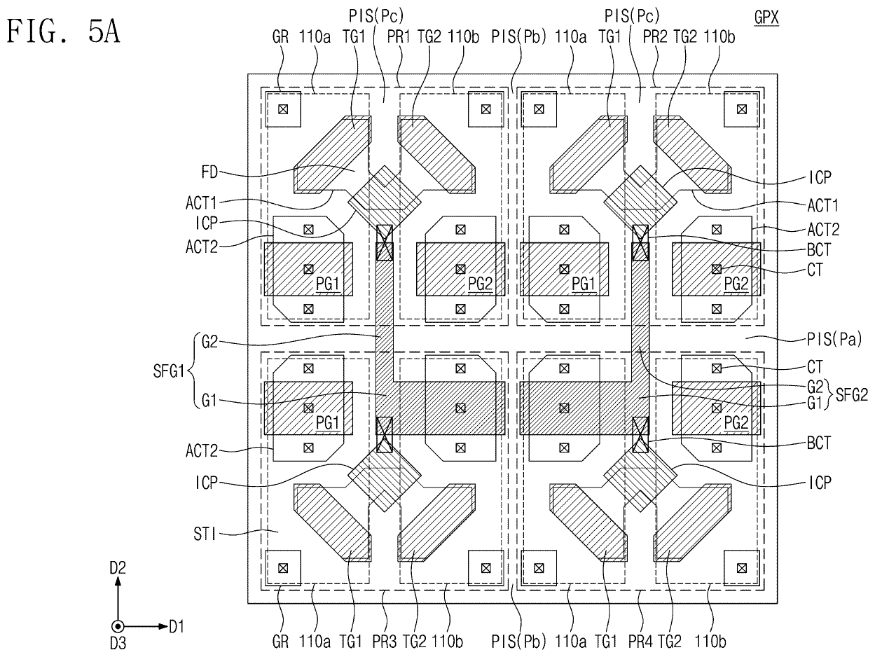

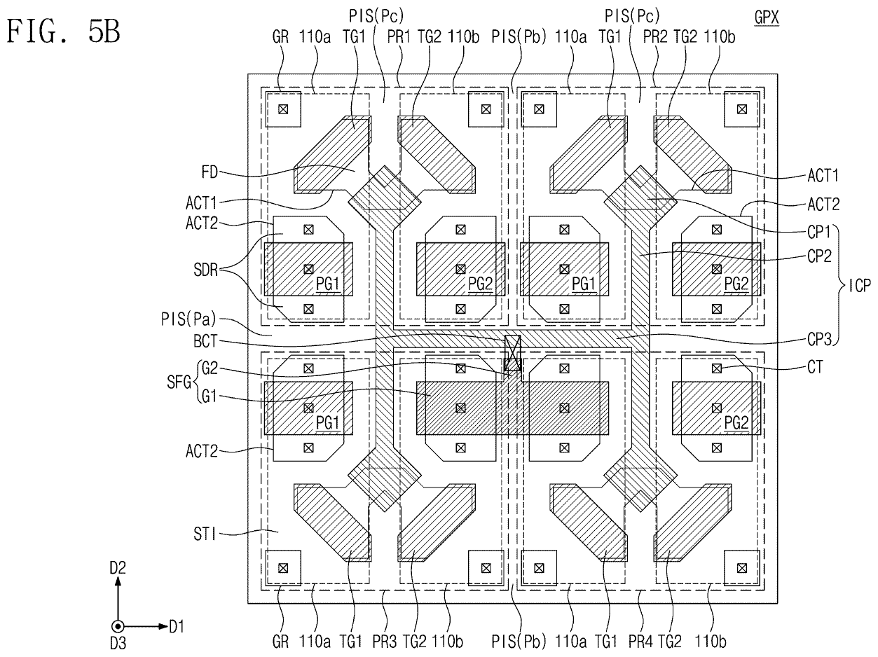

FIGS. 5A and 5B are plan views illustrating an image sensor according to some embodiments of the disclosed concepts.

Referring to FIG. 5A, the first to fourth PD regions PR1 to PR4 may constitute one PD group GPX.

A first source follower gate electrode SFG1 may be provided on the first and third PD regions PR1 and PR3, and a second source follower gate electrodes SFG2 may be provided on second and fourth PD regions PR2 and PR4.

Each of the first and second source follower gate electrodes SFG1 and SFG2 may include a first portion G1 on the second active portion ACT2 and a second portion G2 extended from the first portion G1 and disposed on the PD isolation pattern PIS or the device isolation layer STI. The first and second source follower gate electrodes SFG1 and SFG2 may be disposed mirror-symmetrically to each other.

The first source follower gate electrode SFG1 may be connected in common with the interconnection conductive patterns ICP of the first and third PD regions PR1 and PR3 through the common contact plugs BCT. The second source follower gate electrode SFG2 may be connected in common with the interconnection conductive patterns ICP of the second and fourth PD regions PR2 and PR4 through the common contact plugs BCT.

Referring to FIG. 5B, the first to fourth PD regions PR1 to PR4 may constitute one PD group GPX, and the one PD group GPX may include one interconnection conductive pattern ICP.

In detail, the interconnection conductive pattern ICP may be commonly connected to the floating diffusion regions FD in the first to fourth PD regions PR1 to PR4.

The interconnection conductive pattern ICP may include, in a plan view, first connection portions CP1 contacting the floating diffusion regions FD, second connection portions CP2 extended from the first connection portions CP1 in the second direction D2, and a third connection portion CP3 extending in the first direction D1 and connecting the second connection portions CP2 to each other.

The source follower gate electrode SFG may be commonly disposed on the second active portions ACT2 adjacent to each other in the third and fourth PD regions PR3 and PR4. The source follower gate electrode SFG may include a first portion G1 and a second portion G2 extended from the first portion G1 in the second direction D2. The first portion G1 may cross the second active portions ACT2 adjacent to each other in the third and fourth PD regions PR3 and PR4. The second portion G2 may be disposed on the PD isolation pattern PIS or the device isolation layer STI. The second portion G2 may be adjacent to the third connection portion CP3 of the interconnection conductive pattern ICP.

In some embodiments, the common contact plug BCT may be disposed between the third connection portion CP3 of the interconnection conductive pattern ICP and the second portion G2 of the source follower gate electrode SFG. In other words, the common contact plug BCT may directly contact the third connection portion CP3 of the interconnection conductive pattern ICP and the second portion G2 of the source follower gate electrode SFG.

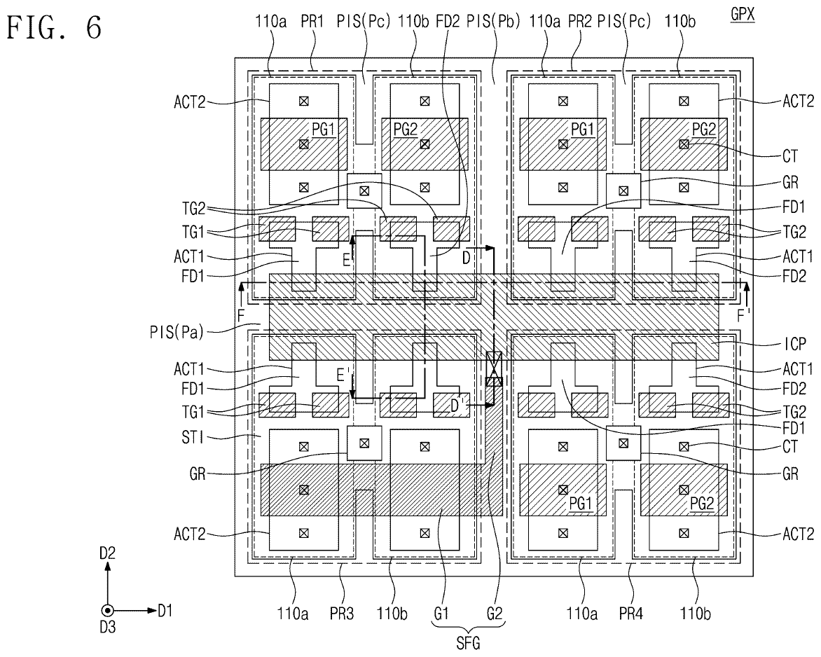

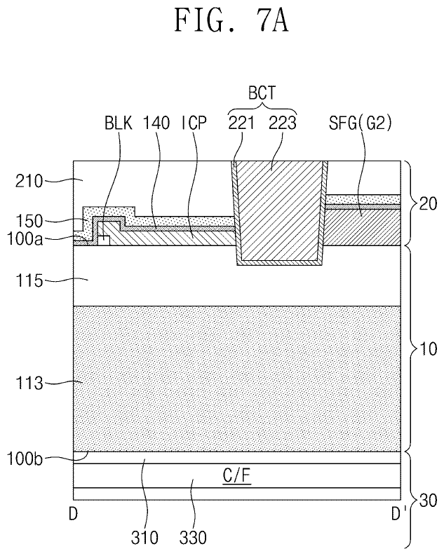

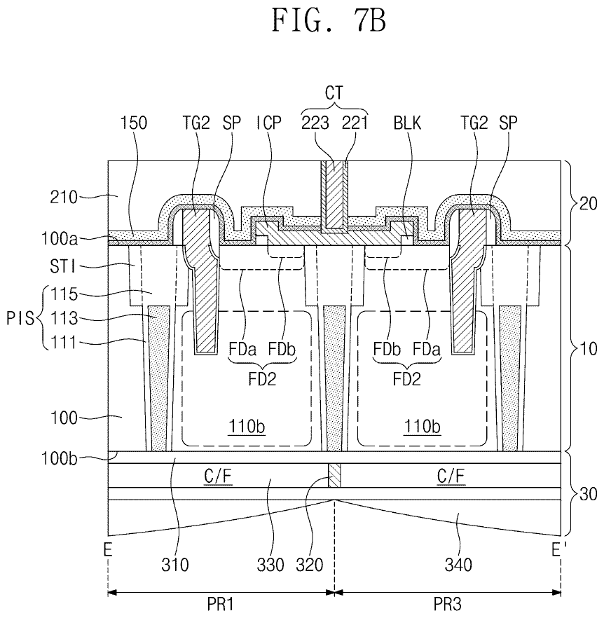

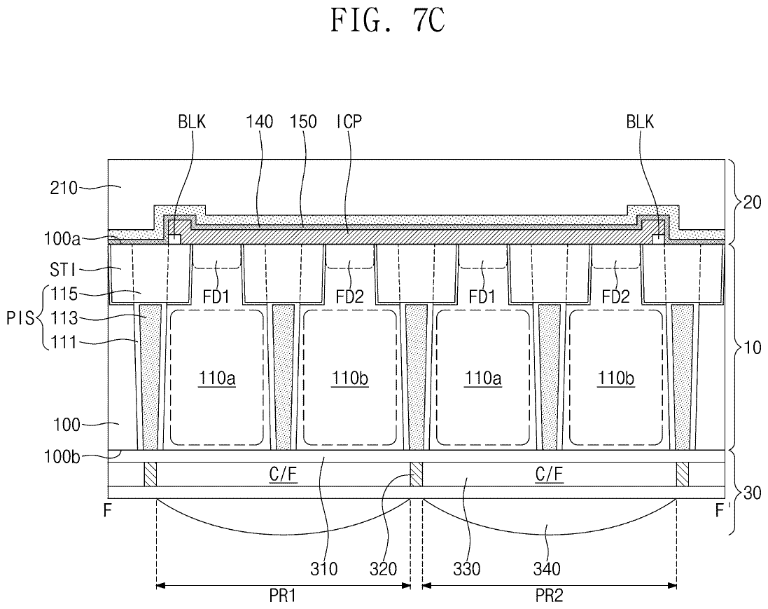

FIG. 6 is a plan view illustrating an image sensor according to embodiments of the invention. FIGS. 7A, 7B, and 7C are cross-sectional views taken along a line D-D′, a line E-E′, and a line F-F′ of FIG. 6, respectively.

Referring to FIGS. 6, 7A, 7B, and 7C, the PD isolation pattern PIS defining first to fourth PD regions PR1 to PR4 may be disposed in the semiconductor substrate 100.

Each of the first to fourth PD regions PR1 to PR4 may be surrounded by the PD isolation pattern PIS in a plan view. Each of the first to fourth PD regions PR1 to PR4 may be defined by a pair of first portions Pa extending in the first direction D1 and a pair of second portions Pb extending in the second direction D2. In addition, the PD isolation pattern PIS may include a pair of third portions Pc in each of the first to fourth PD regions PR1 to PR4. The third portions Pc may be extended from the first portions Pa in the second direction D2 or from the second portions Pb in the first direction D1 and may be spaced apart from each other.

In each of the first to fourth PD regions PR1 to PR4, the first and second photoelectric conversion regions 110a and 110b may be provided in the semiconductor substrate 100.

The device isolation layer STI may be disposed adjacent to the first surface 100a of the semiconductor substrate 100 in each of the first to fourth PD regions PR1 to PR4. A bottom surface of the device isolation layer STI may be spaced apart from the first and second photoelectric conversion regions 110a and 110b.

According to some embodiments, the device isolation layer STI may define first and second active portions ACT1 and ACT2 in each of the first to fourth PD regions PR1 to PR4. The first and second active portions ACT1 and ACT2 may be portions of the semiconductor substrate 100. In a plan view, the first and second active portions ACT1 and ACT2 may overlap each of the first and second photoelectric conversion regions 110a and 110b. In other words, two first active portions ACT1 and two second active portions ACT2 may be provided in each of the PD regions PR1 to PR4, but example embodiments are not limited thereto.

The first active portion ACT1 and the second active portion ACT2 may be spaced apart from each other in the second direction D2 by the device isolation layer STI, and may have different sizes and shapes. The first active portion ACT1 may have the shape of a letter ‘T’, but example embodiments are not limited thereto, for example, the first active portion ACT1 may have a rectangular shape or various polygonal shapes. The second active portion ACT2 may have a long axis in the second direction D2 and may have a short axis in the first direction D1. The first or second photoelectric conversion regions 110a and 110b may have a first length in the second direction D2, and each of the second active portions ACT2 may have a second length smaller than the first length in the second direction D2.

The first and second active portions ACT1 and ACT2 of the third and fourth PD regions PR3 and PR4 may be disposed mirror symmetrically with the first and second active portion ACT1 and ACT2 of the first and second PD regions PR1 and PR2.

In each of the first to fourth PD regions PR1 to PR4, the first and second transfer gate electrodes TG1 and TG2 may be respectively disposed on the first active portion ACT1. Each of the first and second transfer gate electrodes TG1, TG2 may have a dual vertical gate electrode structure including two vertical portions extending into the semiconductor substrate 100.

In each of the first to fourth PD regions PR1 to PR4, a first floating diffusion region FD1 may be provided in the first active portion ACT1 at one side of the first transfer gate electrode TG1. The second floating diffusion region FD2 may be provided in the first active portion ACT1 at one side of the second transfer gate electrode TG2.

Each of the first and second floating diffusion regions FD1 and FD2 may include a first doped region FDa and a second doped region FDb in the first doped region FDa. A doping concentration of the second doped region FDb may be higher than that of the first doping region FDa.

Further, a ground impurity region GR may be provided between the first and second photoelectric conversion regions 110a and 110b in each of the first to fourth PD regions PR1 to PR4. The ground impurity region GR may be provided between the third portions Pc of the PD isolation pattern PIS. The ground impurity region GR may be formed by doping dopants of the same first conductivity type as the semiconductor substrate 100.

According to some embodiments, the interconnection conductive pattern ICP may be disposed on the first surface 100a of the semiconductor substrate 100, and may be commonly connected to the first and second floating diffusion regions FD1 and FD2 provided in the first to fourth PD regions PR1 to PR4. A portion of the interconnection conductive pattern ICP may contact the top surface of the device isolation layer STI and the top surface of a PD isolation pattern PIS.

The interconnection conductive pattern ICP may be formed of a conductive material. The interconnection conductive pattern ICP may be formed of single crystal silicon or poly-crystalline silicon that is doped with dopants of the second conductivity type.

The interconnection conductive pattern ICP may include an edge portion adjacent to an outer sidewall thereof and a pad portion contacting the first and second floating diffusion regions FD1 and FD2. In addition, the interconnection conductive pattern ICP may have a substantially uniform width in the second direction D2 in a plan view and may extend along the first direction D1.

In each of the first, second, and fourth PD regions PR1, PR2, and PR4, the first and second pixel gate electrodes PG1 and PG2 may be respectively disposed on the second active portions ACT2. In each of the first, second, and fourth PD regions PR1, PR2, and PR4, the first pixel gate electrode PG1 may overlap the first photoelectric conversion region 110a, and the second pixel gate electrode PG2 may overlap the second photoelectric conversion region 110b.

In the third PD region PR3, the source follower gate electrode SFG may be disposed on the second active portions ACT2. In the third PD region PR3, the source follower gate electrode SFG may be longer than the first and second gate electrodes PG1 and PG2 in the first direction D1. For example, the source follower gate electrode SFG may cross the second active portions ACT2 of the third PD region PR3.

The source follower gate electrode SFG may include a first portion G1 crossing the second active portions ACT2 and a second portion G2 extended from the first portion G1 in the second direction D2 and disposed on the PD isolation pattern PSI or the device isolation layer STI, as described above. The second portion G2 may be disposed adjacent to the interconnection conductive pattern ICP. For example, the second portion G2 of the source follower gate electrode SFG may be disposed on the PD isolation pattern PSI between the third PD region PR3 and the fourth PD region PR4.

The common contact plug BCT may electrically connect the source follower gate electrode SFG and the interconnection conductive pattern ICP. The common contact plug BCT may be disposed between the second portion G2 of the source follower gate electrode SFG and the interconnection conductive pattern ICP.

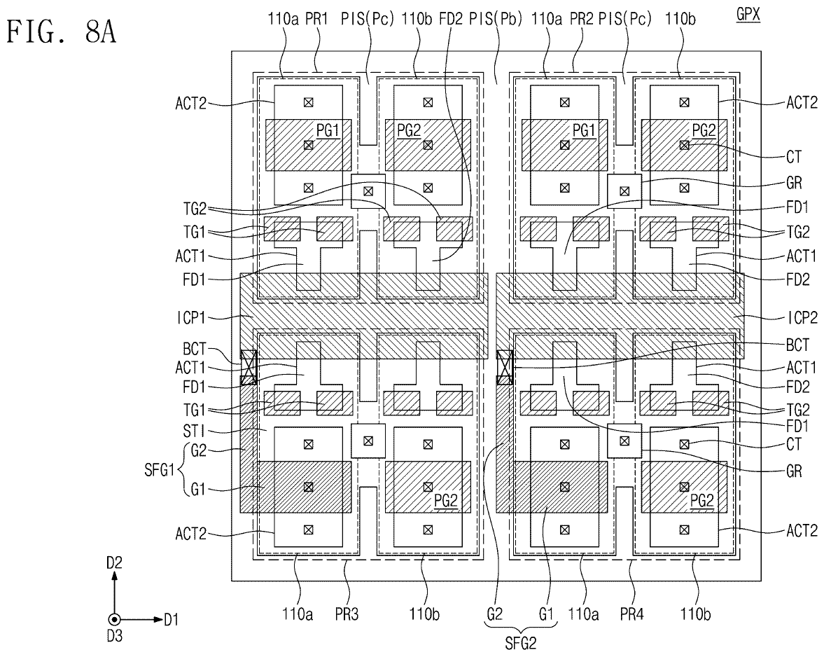

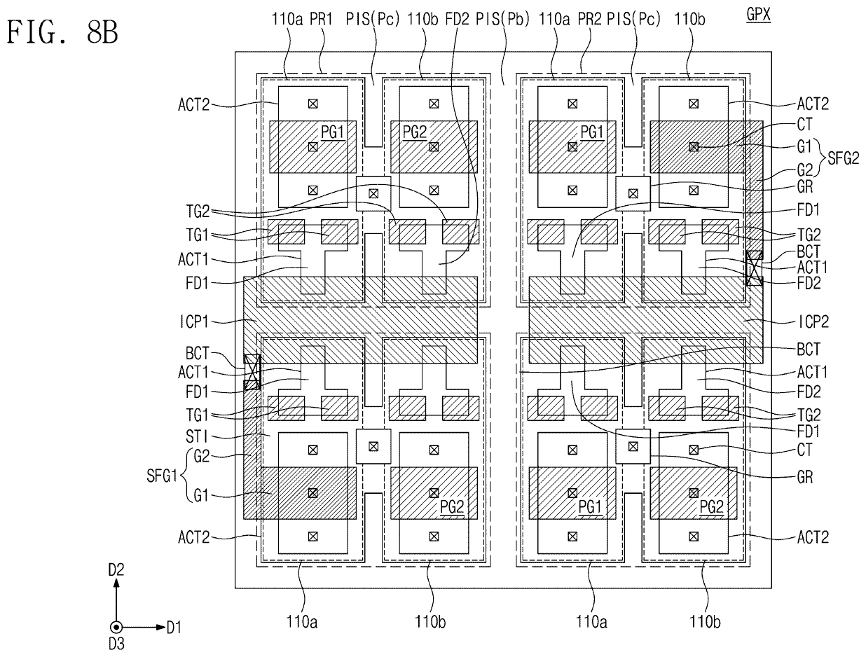

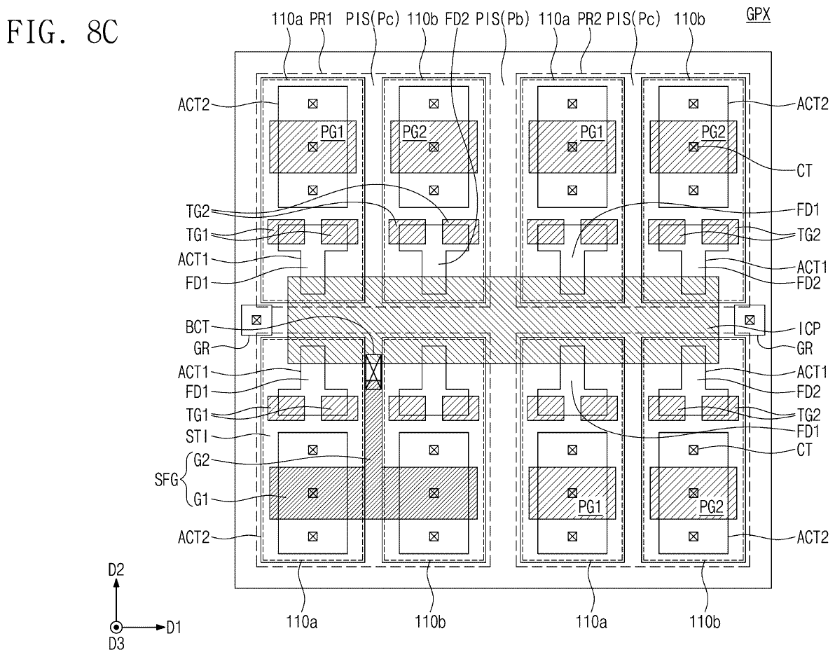

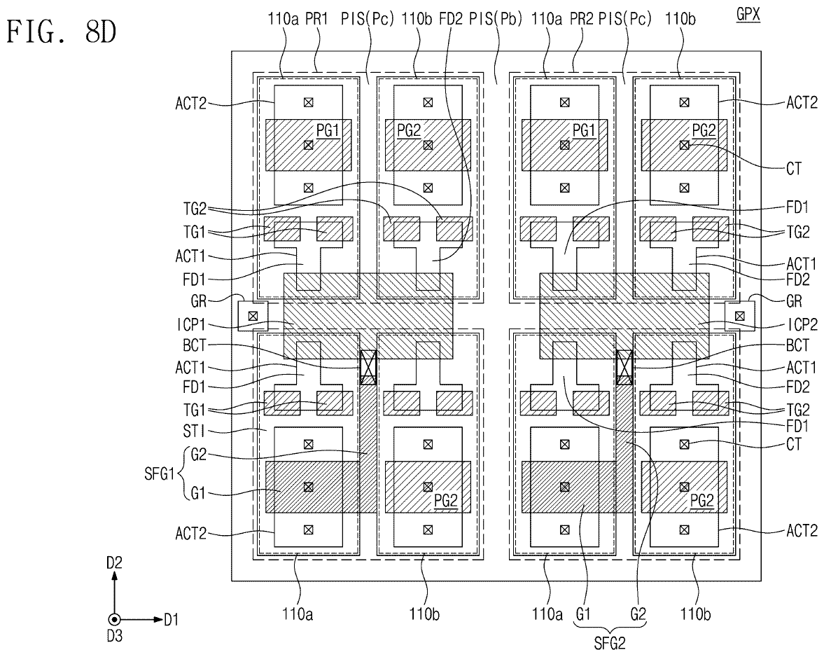

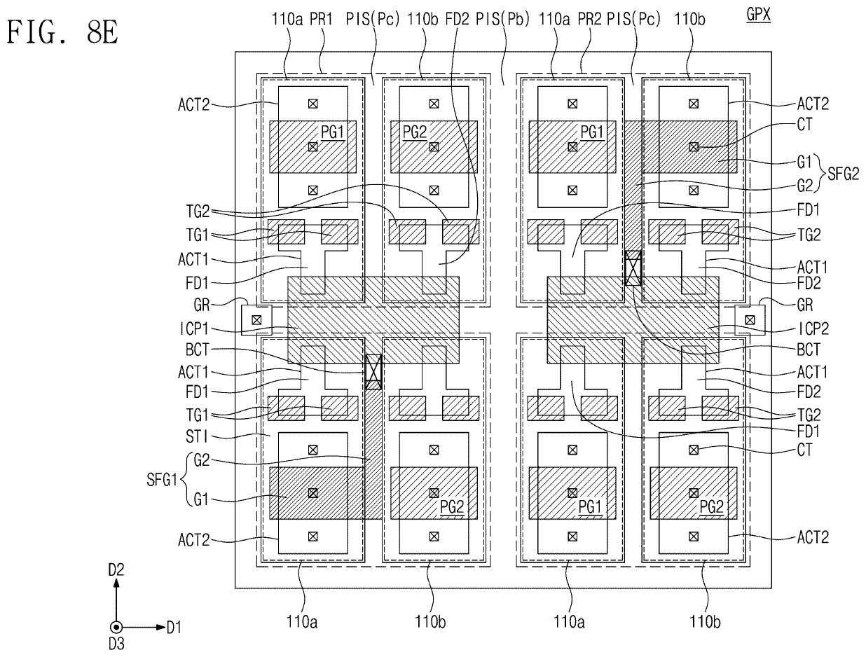

FIGS. 8A, 8B, 8C, 8D, and 8E are plan views illustrating an image sensor according to some embodiments of the disclosed concepts. For concise description, the same technical features as the image sensor described with reference to FIGS. 6, 7A, 7B, and 7C may be omitted from the following description, and different technical features will be described below.

Referring to FIG. 8A, a first interconnection conductive pattern ICP1 may be disposed on the first and third PD regions PR1 and PR3, and the first source follower gate electrode SFG1 may be provided on one of the second active portions ACT2 of the third PD region PR3.

A second interconnection conductive pattern ICP2 may be disposed on the second and fourth PD regions PR2 and PR4, and a second source follower gate electrode SFG2 may be provided in one of the second active portions ACT2 of the fourth PD region PR4.

Each of the first and second source follower gate electrodes SFG1 and SFG2 may include a first portion G1 crossing one of the second active portions ACT2 and a second portion G2 extended from the first portion G1 in the second direction D2 and disposed on the PD isolation pattern PIS or the device isolation layer STI.

The first interconnection conductive pattern ICP1 may be commonly connected to the first and second floating diffusion regions FD1 and FD2 provided in the first and third PD regions PR1 and PR3. The second interconnection conductive pattern ICP2 may be commonly connected to the first and second floating diffusion regions FD1 and FD2 provided in the second and fourth PD regions PR2 and PR4.

The common contact plugs BCT may be respectively connected between the first interconnection conductive pattern ICP1 and the first source follower gate electrode SFG1, and between the second interconnection conductive pattern ICP2 and the second source follower gate electrodes SFG2.

Referring to FIG. 8B, as described above, the first source follower gate electrode SFG1 may be provided on one of the second active portions ACT2 of the third PD region PR3, and the second source follower gate electrodes SFG2 may be provided on one of the second active portions ACT2 in the second PD region PR2. The first and second source follower gate electrodes SFG1 and SFG2 may be arranged in point symmetry in a plan view.

Referring to FIG. 8C, unlike the embodiment shown in FIG. 8A, ground impurity regions GR may be provided between the first and third PD regions PR1 and PR3, and between the second and fourth PD regions PR2 and PR4.

One interconnection conductive pattern ICP may be commonly connected to the floating diffusion regions FD in the first to fourth PD regions PR1 to PR4, and one source follower gate electrode SFG may be disposed on the second active portions ACT2 of the third PD region PR3.

The source follower gate electrode SFG may include a first portion G1 crossing the second active portions ACT2 and a second portion G2 extended from the first portion G1 in the second direction D2 and disposed on the PD isolation pattern PIS or the device isolation layer STI. The second portion G2 may be disposed between the first active portions ACT1, and between the second active portions ACT2, in the third PD region PR3.

The common contact plug BCT may electrically connect the second portion G2 of the source follower gate electrode SFG and the interconnection conductive pattern ICP on the third PD region PR3.

Referring to FIG. 8D, the first source follower gate electrode SFG1 may be provided in one of the second active portions ACT2 of the third PD region PR3, and a second source follower gate electrodes SFG2 may be provided in one of the second active portions ACT2 in the fourth PD region PR4.

Each of the first and second source follower gate electrodes SFG1 and SFG2 may include a first portion G1 crossing one of the second active portions ACT2 and a second portion G2 extended from the first portion G1 in the second direction D2 and disposed on the PD isolation pattern PIS or the device isolation layer STI. The second portion G2 of each of the first and second source follower gate electrodes SFG1 and SFG2 may be disposed between the first active portions ACT1 and between the second active portions ACT2.

Referring to FIG. 8E, unlike the embodiment shown in FIG. 8D, a second source follower gate electrode SFG2 may be provided on the second active portions ACT2 of the second PD region PR2. The second portion G2 of the second source follower gate electrode SFG2 may be disposed between the first active portions ACT1, and between the second active portions ACT2 in the second PD region PR2.

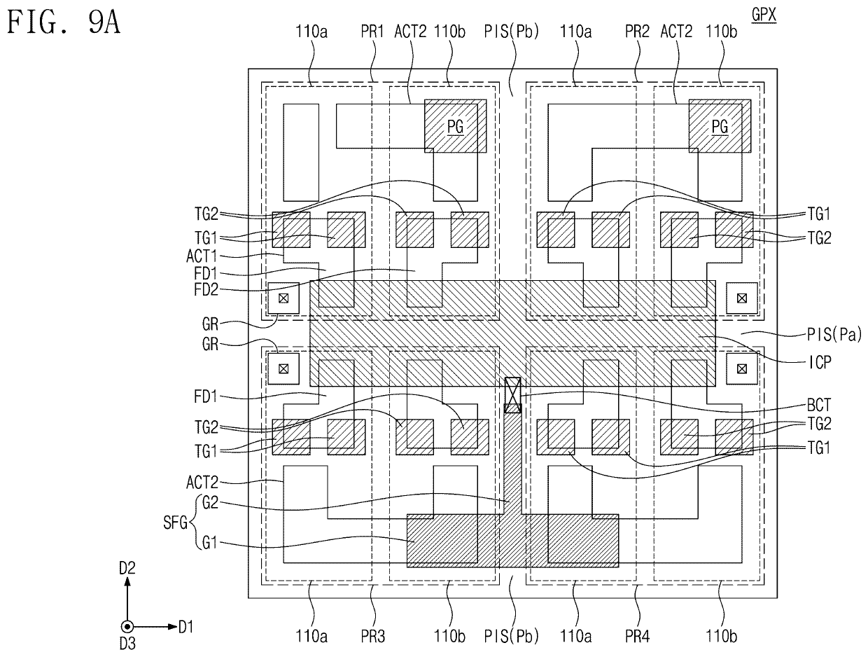

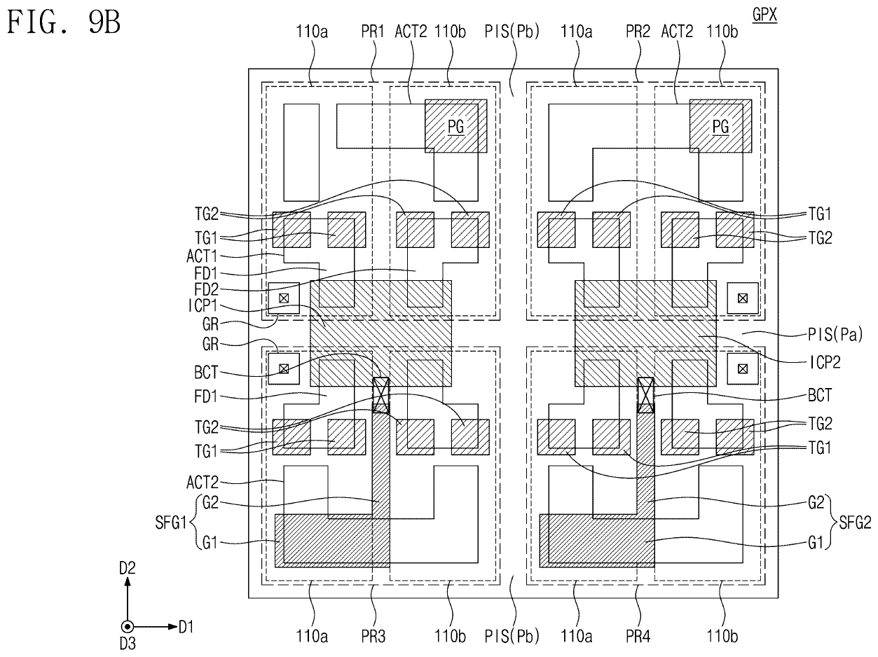

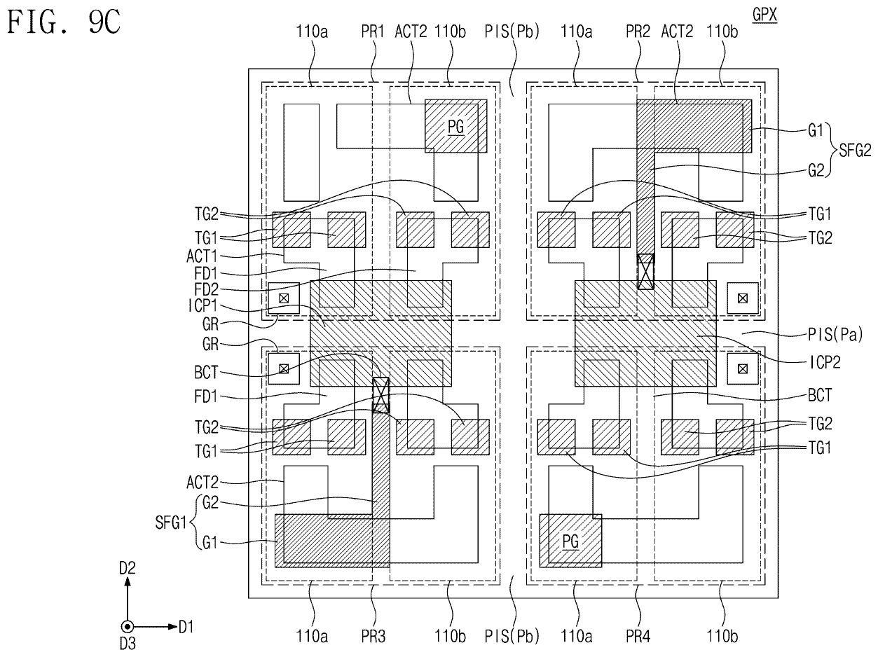

FIGS. 9A, 9B, and 9C are plan views illustrating an image sensor according to some embodiments of the disclosed concepts. For concise description, the same technical features as the image sensor described with reference to FIGS. 6, 7A, 7B, and 7C may be omitted from the following description, and different technical features will be described below.

Referring to FIGS. 9A, 9B, and 9C, the first to fourth PD regions PR1 to PR4 may be defined by the PD isolation pattern PIS. The first active portions ACT1 and the second active portion ACT2 may be defined by the device isolation layer STI in each of the first to fourth PD regions PR1 to PR4. In some embodiments, each of the first to fourth PD regions PR1 to PR4 may include two first active portions ACT1 and at least one second active portion ACT2.

Each of the first active portions ACT1 may have a brass shape or a shape of a letter ‘L’. In each of the first to fourth PD regions PR1 to PR4, the first active portions ACT1 may be disposed mirror-symmetrically to each other. The second active portion ACT2 in each of the first to fourth PD regions PR1 to PR4 may have an L-shape or a U-shape.

Referring to FIG. 9A, pixel gate electrodes PG may be disposed on the second active portions ACT2 of the first and second PD regions PR1 and PR2, respectively.

The source follower gate electrode SFG may be disposed on the second active portions ACT2 of the third and fourth PD regions PR3 and PR4. The second portion G2 of the source follower gate electrode SFG may be disposed on the PD isolation pattern PIS between the third and fourth PD regions PR3 and PR4.

The interconnection conductive pattern ICP may be commonly connected to the first and second floating diffusion regions FD1 and FD2 provided in the first to fourth PD regions PR1 to PR4. The interconnection conductive pattern ICP may have a uniform width and extend in the first direction D1.

Referring to FIG. 9B, the first interconnection conductive pattern ICP1 may be commonly connected to the first and second floating diffusion regions FD1 and FD2 in the first and third PD regions PR1 and PR3. The second interconnection conductive pattern ICP2 may be commonly connected to the first and second floating diffusion regions FD1 and FD2 in the second and fourth PD regions PR2 and PR4.

The first source follower gate electrode SFG1 may be provided on the second active portion ACT2 of the third PD region PR3, and the second source follower gate electrodes SFG2 may be provided on the second active portion ACT2 of the fourth PD region PR4.

The second portion G2 of the first source follower gate electrode SFG1 may be disposed between the first active portions ACT1 of the third PD region PR3. The second portion G2 of the second source follower gate electrode SFG2 may be disposed between the first active portions ACT1 of the fourth PD region PR4.

Referring to FIG. 9C, unlike FIG. 9B, the second source follower gate electrode SFG2 may be provided on the second active portion ACT2 of the second PD region PR2. The second portion G2 of the second source follower gate electrode SFG2 may be disposed between the first active portions ACT1 in the second PD region PR2.

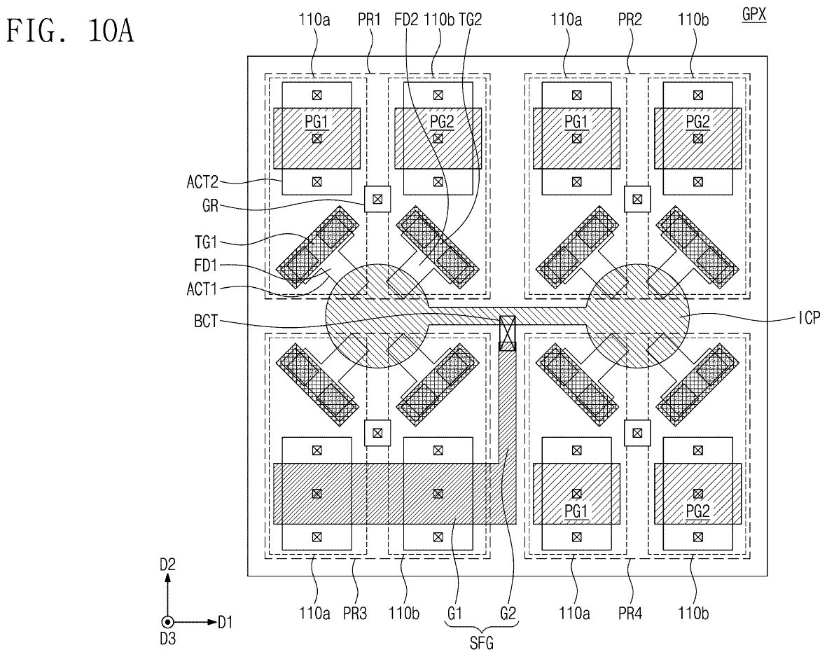

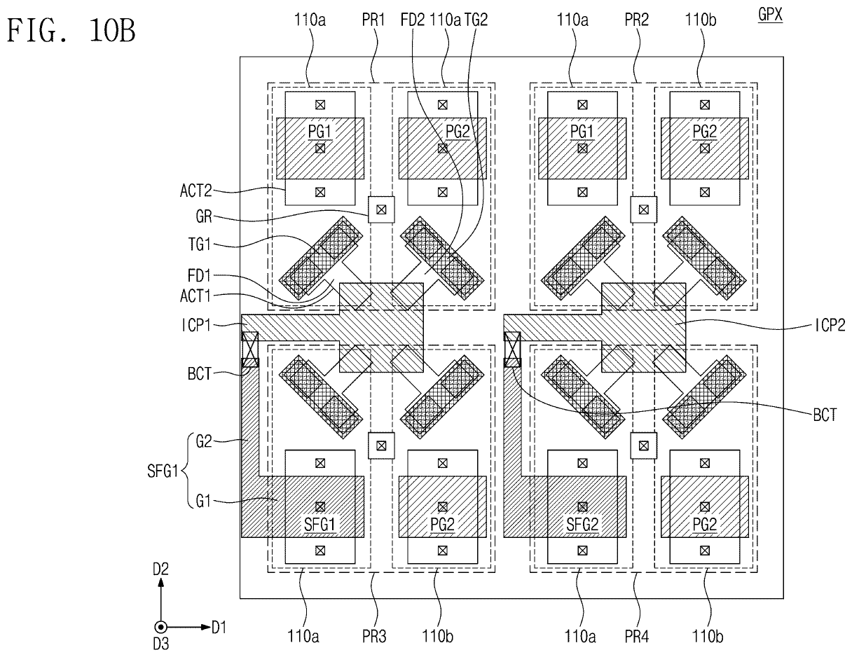

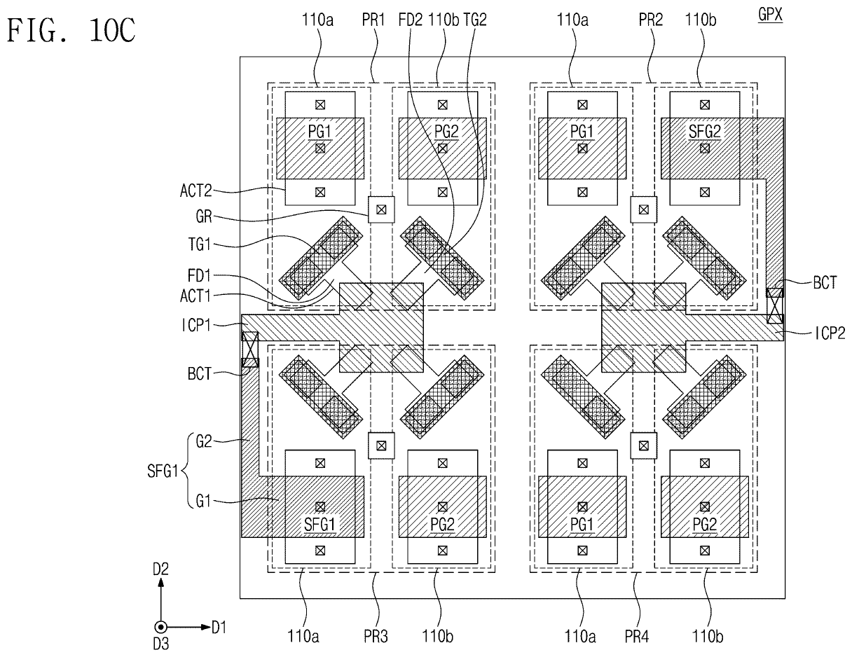

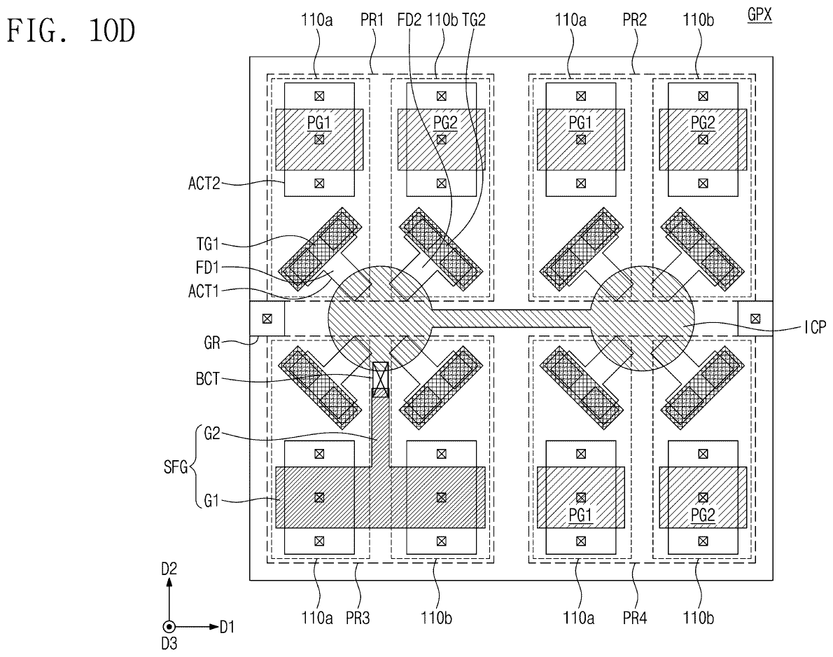

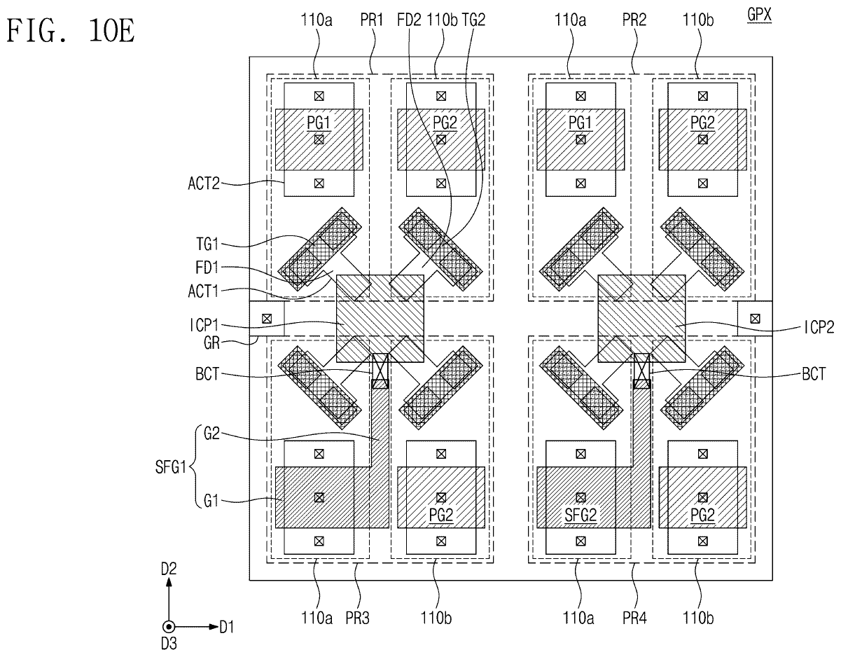

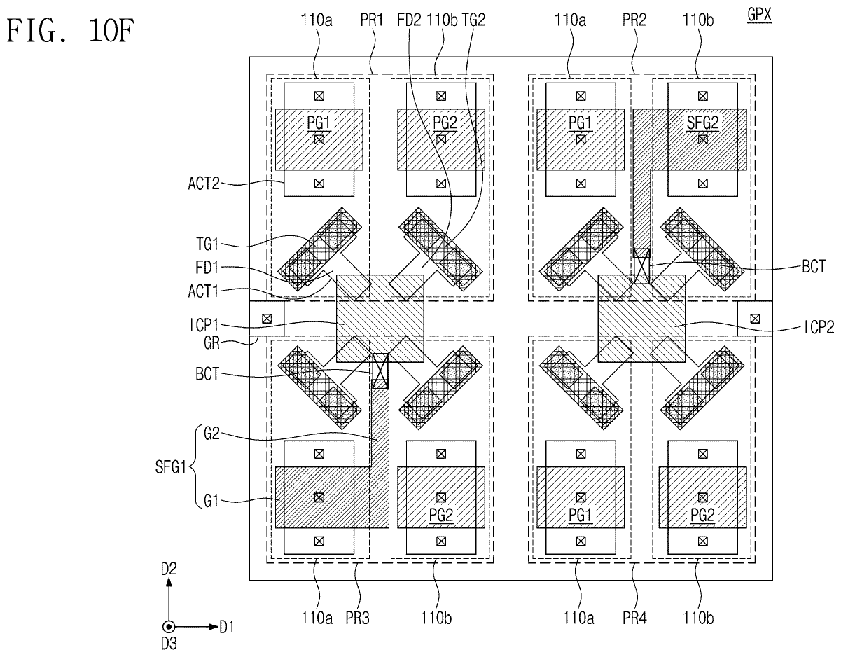

FIGS. 10A, 10B, 10C, 10D, 10E, and 10F are plan views illustrating an image sensor according to some embodiments of the disclosed concepts. For concise description, the same technical features as the image sensor described with reference to FIGS. 6, 7A, 7B, and 7C may be omitted from the following description, and different technical features will be described below.

Referring to FIGS. 10A to 10F, the first to fourth PD regions PR1 to PR4 may be defined by the PD isolation pattern PIS. The first active portions ACT1 and the second active portions ACT2 may be defined by the device isolation layer STI in each of the first to fourth PD regions PR1 to PR4.

Each of the first active portions ACT1 may have a shape of a letter ‘T’ and may be disposed in a diagonal direction with respect to the first and second directions D1 and D2. In other words, the first active portions ACT1 may be tilted with respect to the first and second directions D1 and D2.

Referring to FIG. 10A, the interconnection conductive pattern ICP may be commonly connected to the first and second floating diffusion regions FD1 and FD2 in the first to fourth PD regions PR1 to PR4. In some embodiments, the interconnection conductive pattern ICP may include a first connection portion contacting the first and second floating diffusion regions FD1 and FD2 of the first and third PD regions PR1 and PR3, a second connection portion contacting the first and second flotation diffusion regions FD1 and FD2 in the second and fourth PD regions PR2 and PR4, and a third connection portion connecting the first and second connection portions. Here, the first and second connection portions may have a circular shape, and the third connection portion may have a line shape.

In the third PD region PR3, the source follower gate electrode SFG may be disposed on the second active portions ACT2 of the third PD region PR3. The second portion G2 of the source follower gate electrode SFG may be disposed on the PD isolation pattern PIS between the third PD region PR3 and the fourth PD region PR4, and may be electrically connected to the interconnection conductive pattern ICP through the common contact plug BCT.

Referring to FIG. 10B, the first interconnection conductive pattern ICP1 may be commonly connected to the first and second floating diffusion regions FD1 and FD2 in the first and third PD regions PR1 and PR3. The second interconnection conductive pattern ICP2 may be commonly connected to the first and second floating diffusion regions FD1 and FD2 in the second and fourth PD regions PR2 and PR4.

Each of the first and second interconnection conductive patterns ICP1 and ICP2 may include a first connection portion commonly contacting the first and second floating diffusion regions FD1 and FD2 and a second connection portion extended from the first connection portion in the first direction D1 and disposed on the PD isolation pattern PIS or the device isolation layer STI.

The first source follower gate electrode SFG1 may be provided in one of the second active portions ACT2 of the third PD region PR3, and a second source follower gate electrodes SFG2 may be provided in one of the second active portions ACT2 of the fourth PD region PR4.

One of the common contact plugs BCT may connect the second connection portion of the first interconnection conductive pattern ICP1 and the second portion G2 of the first source follower gate electrode SFG1. The other one of the common contact plugs BCT may connect the second connection portion of the second interconnection conductive pattern ICP2 and the second portion G2 of the second source follower gate electrode SFG2.

Referring to FIG. 10C, unlike FIG. 10B, the first source follower gate electrode SFG1 may be provided in one of the second active portions ACT2 of the third PD region PR3, and a second source follower gate electrodes SFG2 may be provided in one of the second active portions ACT2 of the second PD region PR2. The first and second source follower gate electrodes SFG1 and SFG2 may be arranged in point symmetry in a plan view.

Referring to FIG. 10D, unlike the embodiment shown in FIG. 10A, in the third PD region PR3, a source follower gate electrode SFG may be disposed on the second active portions ACT2 of the third PD region PR3, and a second portion G2 of the source follower gate electrodes SFG may be disposed between the first active portions ACT1 and between the second active portions ACT2 of the third PD region PR3.

Referring to FIG. 10E, the first interconnection conductive pattern ICP1 may be commonly connected to the first and second floating diffusion regions FD1 and FD2 provided in the first and third PD regions PR1 and PR3. The second interconnection conductive pattern ICP2 may be commonly connected to the first and second floating diffusion regions FD1 and FD2 provided in the second and fourth PD regions PR2 and PR4.

The first source follower gate electrode SFG1 may be provided on second active portions ACT2 of the third PD region PR3, and the second source follower gate electrodes SFG2 may be provided on the second active portions ACT2 of the fourth PD region PR4.

The second portion G2 of the first source follower gate electrode SFG1 may be disposed between the first active portions ACT1 of the third PD region PR3. The second portion G2 of the second source follower gate electrode SFG2 may be disposed between the first active portions ACT1 of the fourth PD region PR4.

Referring to FIG. 10F, unlike the embodiment shown in FIG. 10D, the second source follower gate electrode SFG2 may be provided on the second active portions ACT2 of the second PD region PR2. The second portion G2 of the second source follower gate electrode SFG2 may be disposed between the first active portions ACT1 of the second PD region PR2.

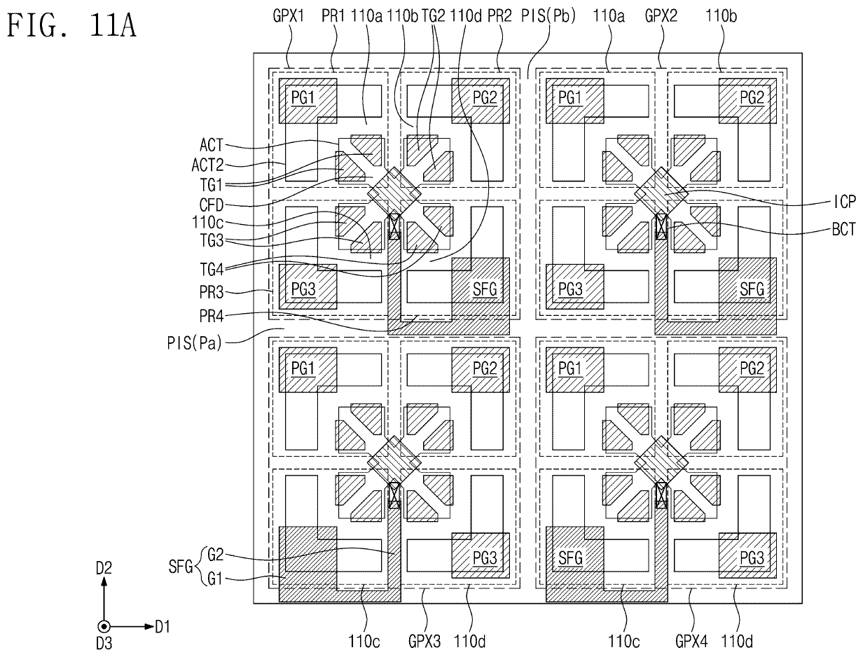

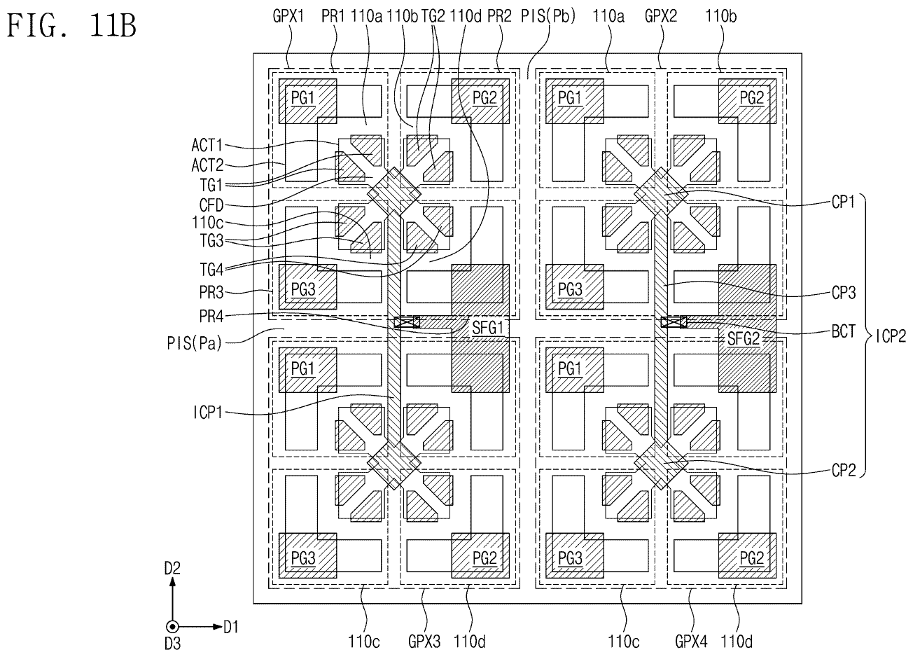

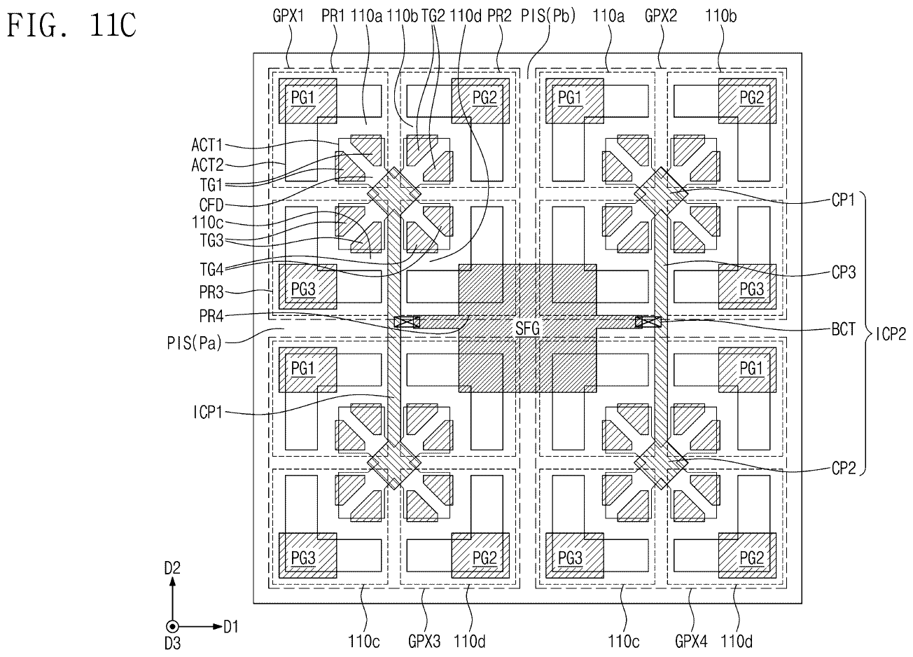

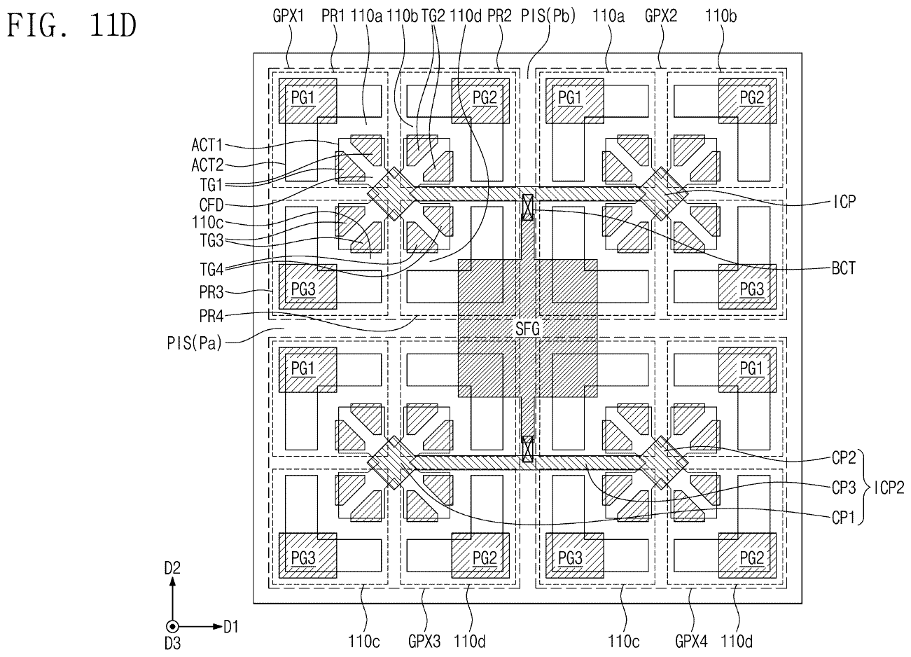

FIGS. 11A, 11B, 11C, and 11D are plan views illustrating an image sensor according to some embodiments of the disclosed concepts.

Referring to FIG. 11A, the semiconductor substrate 100 may include a plurality of PD groups GPX1 to GPX4. Each of the PD groups GPX1 to GPX4 may include at least 4, 8, or 16 PD regions PR1 to PR4. In each of the PD groups GPX1 to GPX4, the PD regions PR1 to PR4 may be arranged in a matrix shape along the first direction D1 and the second direction D2 crossing each other.

The first to fourth photoelectric conversion regions 110a to 110d may be respectively provided in the first to fourth PD regions PR1 to PR4.

A common active portion ACT may be provided in each of the PD groups GPX1 to GPX4, and a second active portion ACT2 may be provided in each of the first to fourth PD regions PR1 to PR4. In other words, the common active portion ACT may be provided in common to the first to fourth PD regions PR1 to PR4. The common active portion ACT and the second active portions ACT2 may be defined by the device isolation layer STI adjacent to the first surface 100a of the semiconductor substrate 100.

The first to fourth transfer gate electrodes TG1 to TG4 may be provided on the common active portion ACT in each of the first to fourth PD regions PR1 to PR4. Each of the first to fourth transfer gate electrodes TG1, TG2, TG3, and TG4 may have a dual vertical gate electrode structure including two vertical portions extending into the semiconductor substrate, as described above.

A common floating diffusion region CFD may be provided in the common active portion ACT at a center of each PD group GPX1 to GPX4. In some embodiments, the common floating diffusion region CFD may be commonly provided in the first to fourth PD regions PR1 to PR4. The first portions Pa of the PD isolation pattern PIS may be spaced apart from each other in the first direction D1, and the second portions Pb of the PD isolation pattern PIS may be spaced apart from each other in the second direction D2. The common floating diffuse region CFD may be disposed between the first portions Pa and between the second portions Pb.

An interconnection conductive pattern ICP may be connected to the common floating diffusion region CFD in each of the PD groups GPX1 to GPX4. As described above, the interconnection conductive pattern ICP may directly contact the common floating diffusion region CFD on the first surface 100a of the semiconductor substrate 100.

In each of the first to fourth PD regions PR1 to PR4 of each of the PD groups GPX1 to GPX4, a pixel transistor may be provided on the second active portion ACT2. The first to fourth pixel gate electrodes PG1, PG2, PG3, and SFG may be provided on the second active portions ACT2 of the first to fourth PD regions PR1 to PR4.

The fourth pixel gate electrode may be a source follower gate electrode SFG of the source follower transistor SX described with reference to FIGS. 2A and 2B. The source follower gate electrode SFG may be provided on at least one of the second active portions ACT2 in each of the PD groups GPX1 to GPX4. The positions of the source follower gate electrodes SFG may be different from each other in the PD groups GPX1 to GPX4.

In some embodiments, the source follower gate electrodes SFG in the first and second PD groups GPX1 and GPX2 may be disposed on the second active portions ACT2 of the fourth PD regions PR4, and the source follower gate electrodes SFG in the third and fourth PD groups GPX3 and GPX4 may be disposed on the second active portions ACT2 of the third PD regions PR3.

The source follower gate electrode SFG may include a first portion G1 disposed on the second active portion ACT2 and a second portion G2 extended from the first portion G1 and disposed on the device isolation layer STI or the PD isolation pattern PIS. The second portion G2 of the source follower gate electrode SFG may be disposed between adjacent second active portions ACT2 and may be adjacent to the interconnection conductive pattern ICP.

The common contact plug BCT is disposed between the second portion G2 of the source follower gate electrode SFG and the interconnection conductive pattern ICP, and may electrically connect the source follower gate electrode SFG to the interconnection conductive pattern ICP.

Referring to FIG. 11B, unlike the embodiment shown in FIG. 11A, the first interconnection conductive pattern ICP1 may be commonly connected to the common floating diffusion regions CFD provided in the first and third PD groups GPX1 and GPX3. A second interconnection conductive pattern ICP2 may be commonly connected to the common floating diffusion regions CFD provided in the second and fourth PD groups GPX2 and GPX4.

In some embodiments, each of the first and second interconnection conductive patterns ICP1 and ICP2 may include a first connection portion CP1 contacting the common floating diffusion region CFD of the first or second PD group GPX1 or GPX2, a second connection portion CP2 contacting the common floating diffusion regions CFD of the third or fourth PD group GPX3 or GPX4, and a third connection portion CP3 connecting the first and second connecting portions CP1 and CP2. Here, the first and second connection portions CP1 and CP2 may have a circular shape or a quadrangular shape, and the third connection portion CP3 may have a line shape.

A first source follower gate electrode SFG1 may be provided in common to the fourth PD region PR4 of the PD groups GPX1 and the second PD region of the third PD group GPX3, and a second source follower gate electrodes SFG2 may be provided in common to the fourth PD regions PR4 of the second PD groups GPX2 and the second PD group GPX4.

The second portion G2 of the first source follower gate electrode SFG1 may be disposed on the PD isolation pattern PIS between the first and third PD groups GPX1 and GPX3. The second portion G2 of the second source follower gate electrode SFG2 may be disposed on the PD isolation pattern PIS between the second and fourth PD groups GPX2 and GPX4.

Referring to FIG. 11C, unlike the embodiment shown in FIG. 11B, the source follower gate electrode SFG may be provided in common to the first to fourth PD groups GPX1 to GPX4. In other words, the source follower gate electrode SFG may be commonly provided on the four second active portions ACT2 adjacent to each other in the first to fourth PD groups GPX1 to GPX4. In other words, the source follower gate electrode SFG may be provided in the fourth PD region PR4 of the first PD group GPX1, the third PD region PR3 of the second PD group GPX2, the second PD region PR2 of the third PD group GPX3, and the first PD region PR1 of the fourth PD group GPX4.

The source follower gate electrode SFG may include second portions G2 protruding toward the first and second interconnection conductive patterns ICP1 and ICP2. The common contact plugs BCT may be commonly connected to the first and second interconnection conductive patterns ICP1 and ICP2 and the second portions G2 of the source follower gate electrode SFG.

Referring to FIG. 11D, unlike the embodiment shown in FIG. 11C, the first interconnection conductive pattern ICP1 may be commonly connected to the first and second floating diffusion regions FD1 and FD2 provided in the first and second PD groups GPX1 and GPX2. The second interconnection conductive pattern ICP2 may be commonly connected to the first and second floating diffusion regions FD1 and FD2 provided in the third and fourth PD groups GPX3 and GPX4. The source follower gate electrode SFG may include second portions G2 protruding toward the first and second interconnection conductive patterns ICP1 and ICP2.

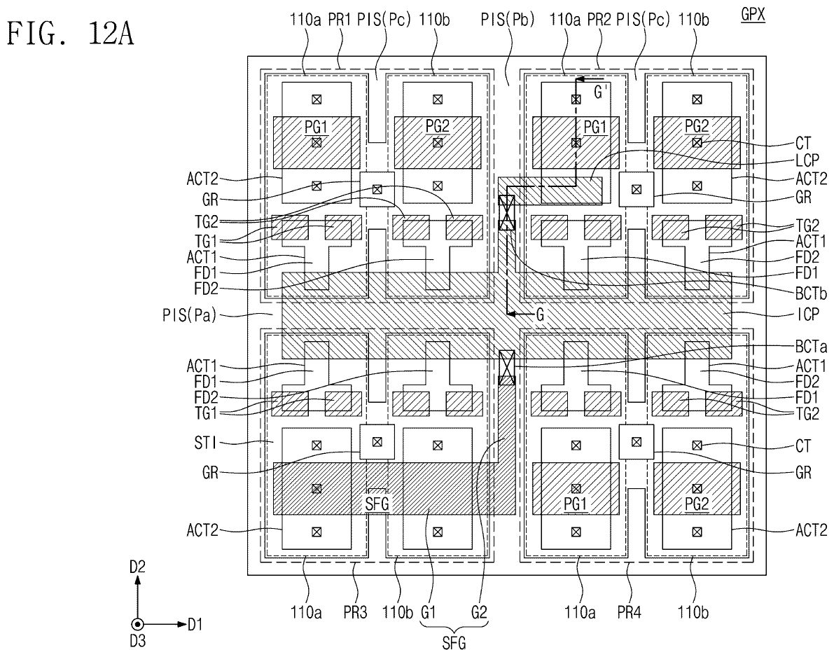

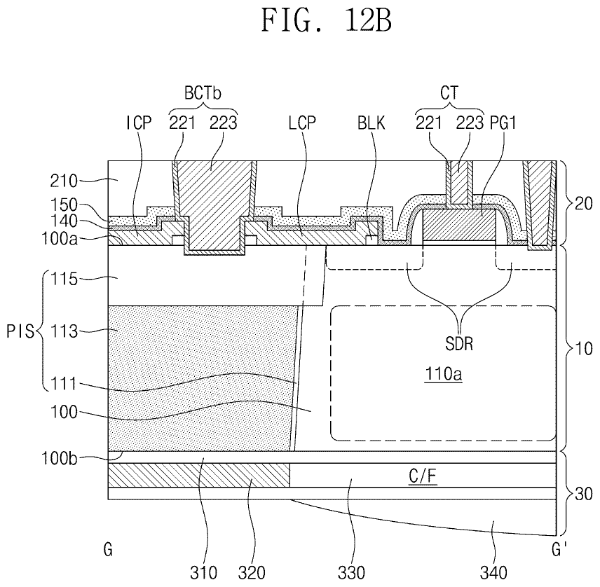

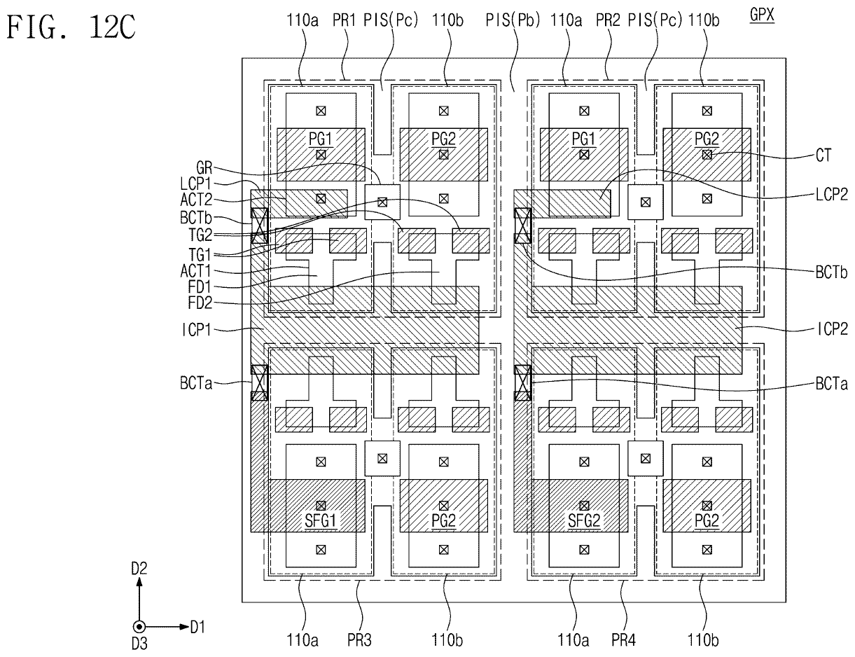

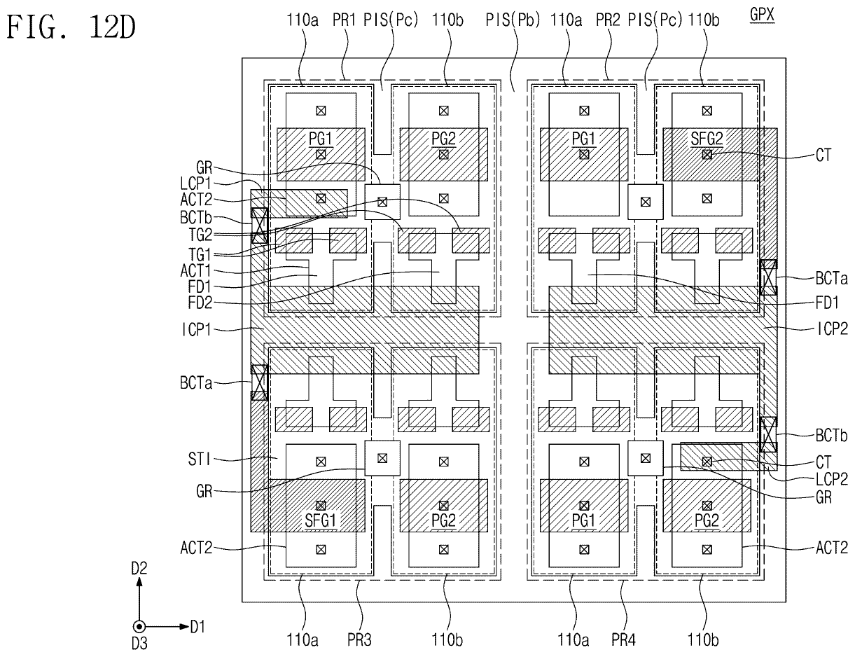

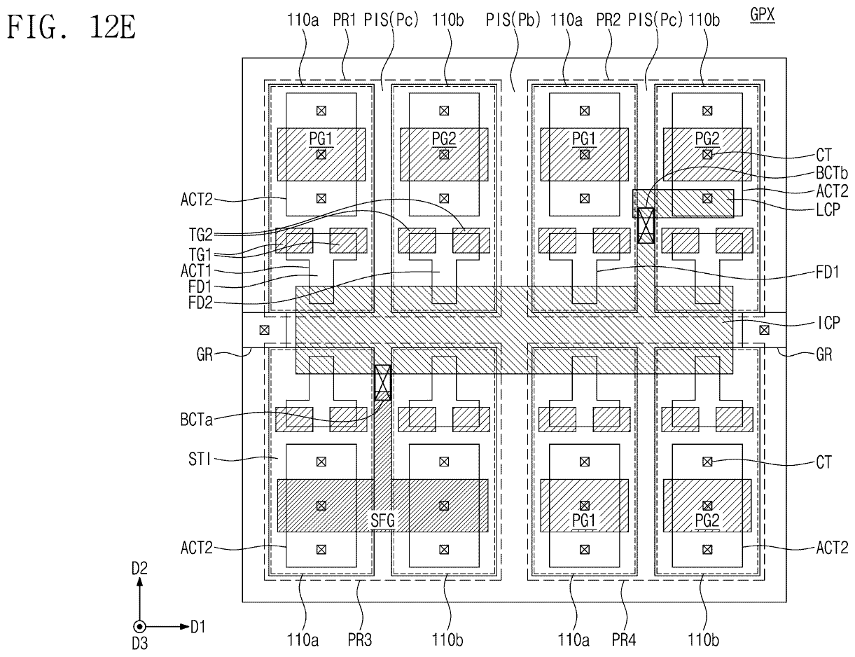

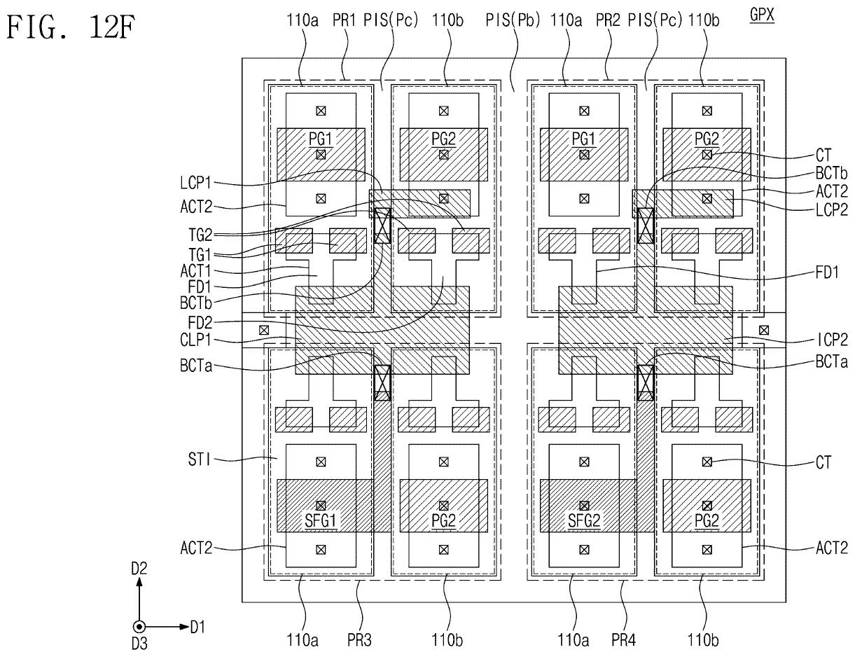

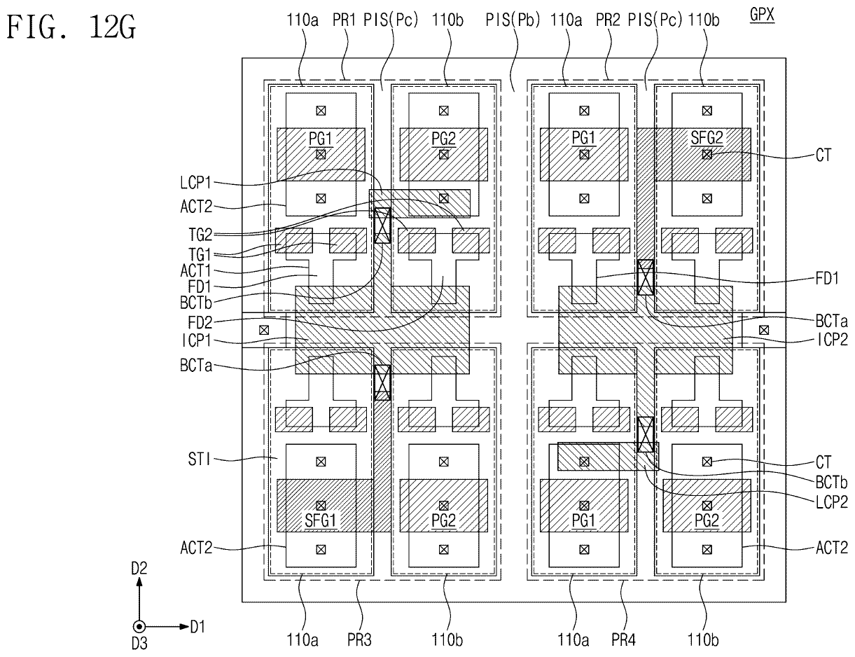

FIGS. 12A, 12C 12D, 12E, and 12F are plan views illustrating an image sensor according to some embodiments of the disclosed concepts. FIG. 12B is a cross-sectional view taken along a line G-G′ of FIG. 12A.

Referring to FIGS. 12A and 12B, as described with reference to FIG. 6, the first to fourth PD regions PR1 to PR4 may be defined by the PD isolation pattern PIS. The first active portions ACT1 and the second active portions ACT2 may be defined by the device isolation layer STI in each of the first to fourth PD regions PR1 to PR4.

The first active portions ACT1 may be spaced apart from the second active portions ACT2 in the second direction D2 by the device isolation layer STI. The first and second active portions ACT1 and ACT2 may have different sizes and shapes. For example, each of the first active portions ACT1 may have a T-shape, and each of the second active portions ACT2 may have a bar shape.

In each of the first, second, and fourth PD regions PR1, PR2, and PR4, the first and second pixel gate electrodes PG1 and PG2 may be respectively disposed on the second active portions ACT2.

In the third PD region PR3, the source follower gate electrode SFG may be disposed on the second active portions ACT2. The second portion G2 of the source follower gate electrode SFG may be disposed between the third PD region PR3 and the fourth PD region PR4, and may be electrically connected to the interconnection conductive pattern ICP through the common contact plug BCT.

The interconnection conductive pattern ICP may be commonly connected to the first and second floating diffusion regions FD1 and FD2 provided in the first to fourth PD regions PR1 to PR4.

In some embodiments, a local conductive pad LCP may be provided on the source/drain region SDR at one side of the first pixel gate electrode PG1 in the second PD region PR2.

The local conductive pad LCP may contact the source/drain region SDR and may extend on a top surface of the device isolation layer STI or the PD isolation pattern PIS. The local conductive pad LCP may be formed of the same conductive material as the interconnection conductive pattern ICP, and may have substantially the same thickness as the interconnection conductive patterns ICP.

In some embodiments, a first common contact plug BCTa may electrically connect the portion of the source follower gate electrode SFG and the interconnection conductive pattern ICP. A second common contact plug BCTb or a connection contact plug may electrically connect the second portion G2 of the interconnection conductive pattern ICP and the local conductive pad LCP. The second common contact plug BCTb may directly contact a top surface of the interconnection conductive pattern ICP and a top surface of the local conductive pad LCP.

In some embodiments, in the second PD region PR2, the first pixel gate electrodes PG1 and the source/drain regions SDR at opposite sides of the first pixel gate electrode PG1 may constitute the reset transistor RX of FIGS. 2A and 2B or the dual-conversion gain transistor DCX of FIGS. 2A and 2B.

Referring to FIG. 12C, as described with reference to FIG. 8A, the first source follower gate electrode SFG1 may be provided on one of the second active portions ACT2 of the third PD region PR3, and the second source follower gate electrodes SFG2 may be provided on the one of the second active portions ACT2 in the second PD region PR2.

The first interconnection conductive pattern ICP1 may be commonly connected to the first and second floating diffusion regions FD1 and FD2 provided in the first and third PD regions PR1 and PR3. The second interconnection conductive pattern ICP2 may be commonly connected to the first and second floating diffusion regions FD1 and FD2 provided in the second and fourth PD regions PR2 and PR4.

Each of the first and second interconnection conductive patterns ICP1 and ICP2 may include a first connection portion commonly contacting the first and second floating diffusion regions FD1 and FD2 and a second connection portion extended from the first connection portion in the first direction D2 and disposed on the PD isolation pattern PIS or the device isolation layer STI.

The first interconnection conductive pattern ICP1 may be connected to the second portion G2 of the first source follower gate electrode SFG1 through the first common contact plug BCTa. The second interconnection conductive pattern ICP2 may be connected to the second portion G2 of the second source follower gate electrode SFG2 through the first common contact plug BCTa.

In some embodiments, a first local conductive pad LCP1 may be provided on the source/drain region SDR at one side of the first pixel gate electrode PG1 in the first PD region PR1. The first local conductive pad LCP1 may be electrically connected to the first interconnection conductive pattern ICP1 through the second common contact plug BCTb.

A second local conductive pad LCP2 may be provided on the source/drain region SDR at one side of the first pixel gate electrode PG1 in the second PD region PR2. The second local conductive pad LCP2 may be electrically connected to the second interconnection conductive pattern ICP2 through the second common contact plug BCTb.

Referring to FIG. 12D, unlike the embodiment shown in FIG. 12C, the second source follower gate electrode SFG2, the second interconnection conductive pattern ICP2, and the second local conductive pad LCP2 may be arranged point-symmetrically with the first source follower gate electrodes SFG1, the first interconnection conductive pattern ICP1, and the first local conductive pad LCP1.

In other words, the second source follower gate electrode SFG2 may be disposed on the second active portion ACT2 of the second PD region PR2, and the second local conductive pad LCP2 may be disposed at one side of the second pixel gate electrode PG2 of the fourth PD region PR4.

Referring to FIG. 12E, one interconnection conductive pattern ICP may be commonly connected to the floating diffusion regions FD of the first to fourth PD regions PR1 to PR4. The interconnection conductive pattern ICP may include a connection portion protruding in the second direction D2 and disposed between the first active portions ACT1 and the second active portions ACT2 of the second PD region PR2. the first common contact plug BCTa may be connected between the second portion G2 of the source follower gate electrode SFG and the interconnection conductive pattern ICP.

One source follower gate electrode SFG may be commonly disposed on the second active portions ACT2 of the third PD region PR3.

A local conductive pad LCP may be provided on the source/drain region SDR at one side of the second pixel gate electrode PG2 in the second PD region PR2. The local conductive pad LCP may contact the source/drain region SDR and may extend on a top surface of the device isolation layer STI or the PD isolation pattern PIS. The local conductive pad LCP and the second common contact plug BCTb may be electrically connected to a connection portion of the interconnection conductive pattern ICP.

Referring to FIG. 12F, a first source follower gate electrode SFG1 may be provided on second active portions ACT2 of the third PD region PR3, and a second source follower gate electrodes SFG2 may be provided on the second active portions ACT2 of the fourth PD region PR4.

The first interconnection conductive pattern ICP1 may be commonly connected to the first and second floating diffusion regions FD1 and FD2 provided in the first and third PD regions PR1 and PR3. The second interconnection conductive pattern ICP2 may be commonly connected to the first and second floating diffusion regions FD1 and FD2 provided in the second and fourth PD regions PR2 and PR4.

Each of the first and second interconnection conductive patterns ICP1 and ICP2 protrudes in the second direction D2 and may include a connection portion disposed on the PD isolation pattern PIS or the device isolation layer STI.

A first local conductive pad LCP1 may be provided on the source/drain region SDR at one side of the second pixel gate electrode PG2 in the first PD region PR1. The first local conductive pad LCP1 may be electrically connected to the first interconnection conductive pattern ICP1 through the second common contact plug BCTb.

A second local conductive pad LCP2 may be provided on the source/drain region SDR at one side of the second pixel gate electrode PG2 in the second PD region PR2. The second local conductive pad LCP2 may be electrically connected to the second interconnection conductive pattern ICP2 through the second common contact plug BCTb.

Referring to FIG. 12G, unlike the embodiment shown in FIG. 12F, the second source follower gate electrode SFG2, the second interconnection conductive pattern ICP2, and the second local conductive pad LCP2 may be arranged point-symmetrically with the first source follower gate electrodes SFG1, the first interconnection conductive pattern ICP1, and the first local conductive pad LCP1.

In other words, the first local conductive pad LCP1 may be disposed at one side of the second pixel gate electrode PG2 of the first PD region PR1, and the second local conductive pad LCP2 may be disposed on the one side of the first pixel gate electrode PG1 of the fourth PD region.

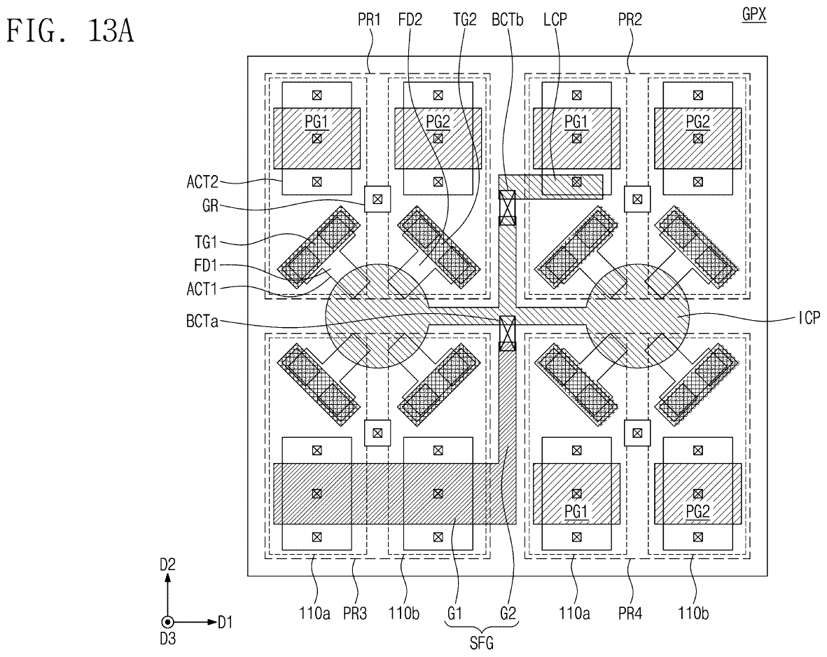

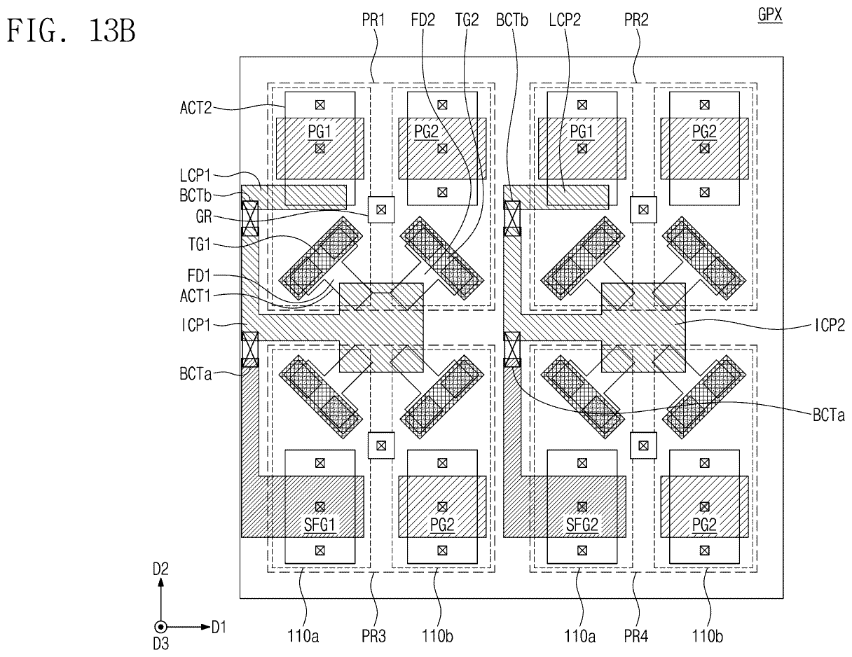

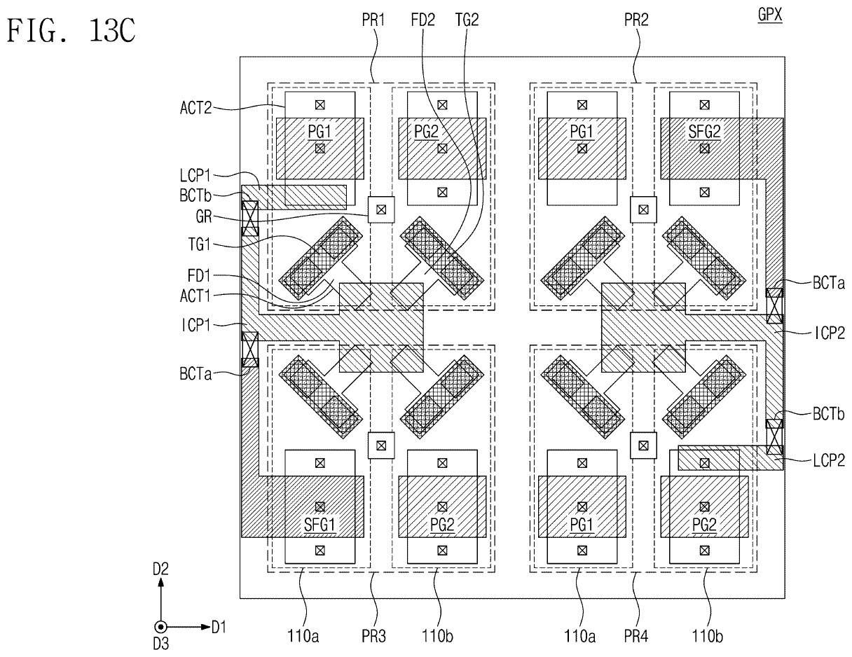

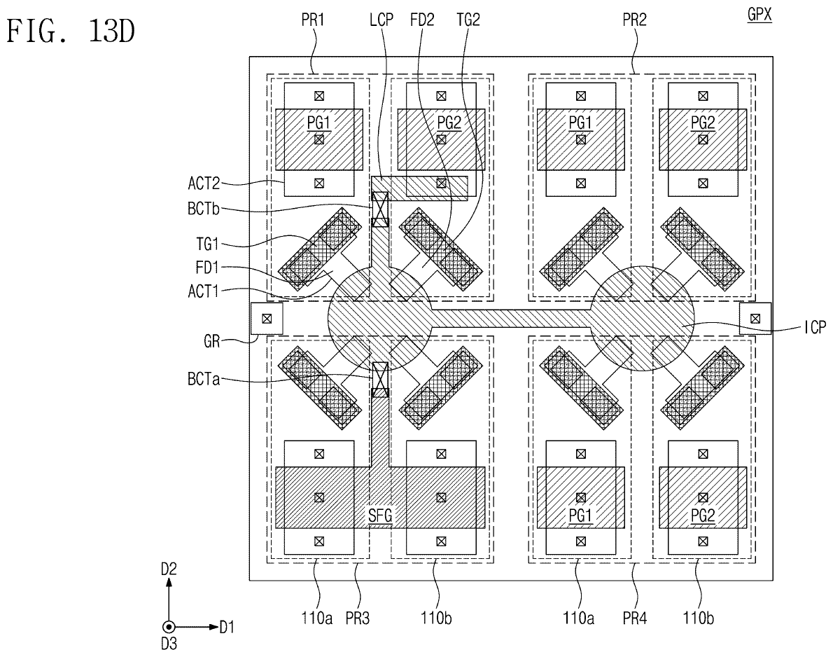

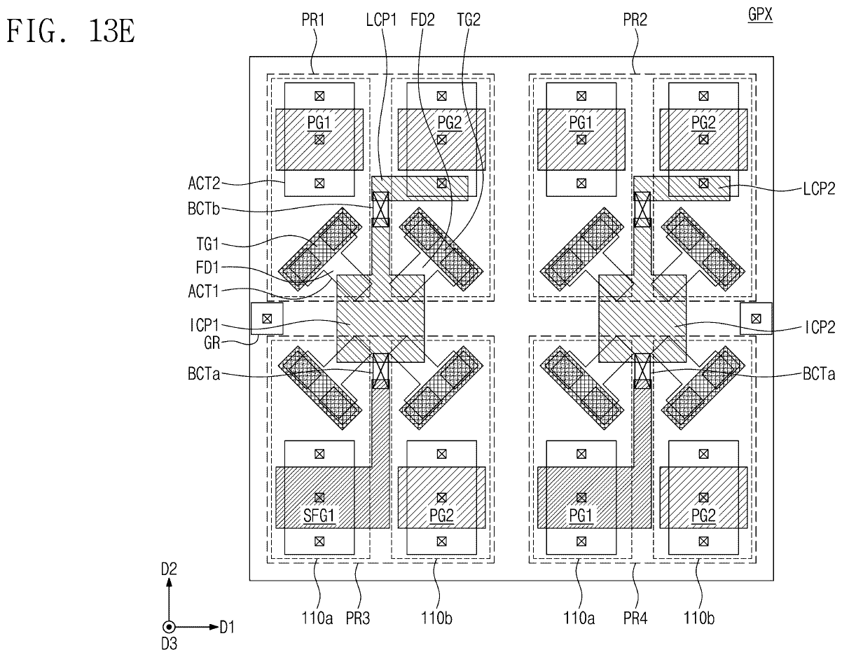

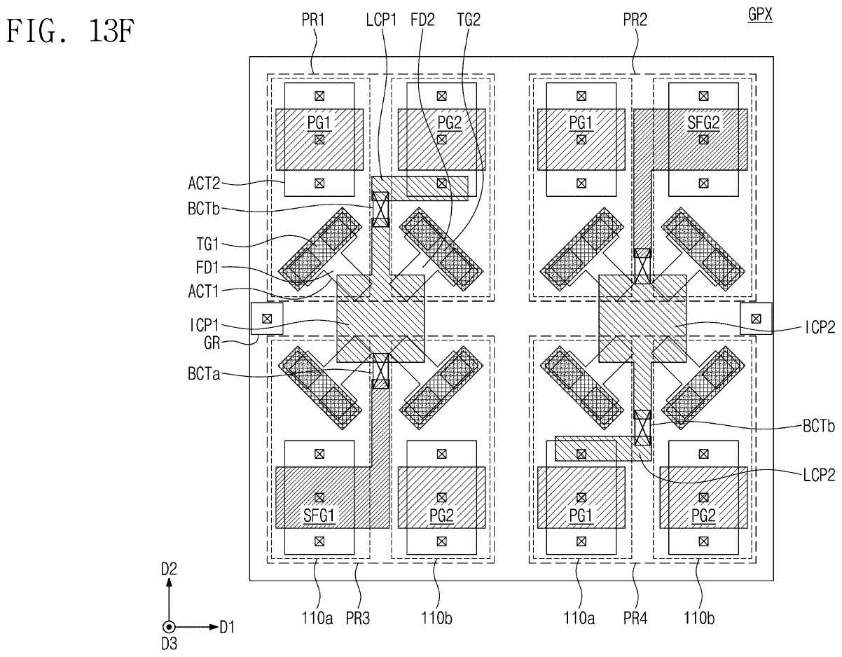

FIGS. 13A, 13C 13D, 13E, and 13F are plan views illustrating an image sensor according to some embodiments of the disclosed concepts. For concise description, the same technical features as the image sensor described with reference to FIGS. 10A to 10F may be omitted from the following description, and different technical features will be described below.

Referring to FIGS. 13A to 13F, as described above with reference to FIGS. 10A to 10F, each of the first active portions ACT1 in each of the first to fourth PD regions PR1 to PR4 may have a T-shape and may be disposed obliquely with respect to the first and second directions D1 and D2.

Referring to FIG. 13A, as described with reference to FIG. 10A, the interconnection conductive pattern ICP may be commonly connected to the first and second floating diffusion regions FD1 and FD2 provided in the first to fourth PD regions PR1 to PR4. In addition, the interconnection conductive pattern ICP may further include a connection portion protruding in the second direction D2 and disposed on the device isolation layer STI or the PD isolation pattern PIS.

In addition, as described with reference to FIG. 12A, the local conductive pad LCP may be provided on the source/drain region SDR at one side of the first pixel gate electrode PG1 in the second PD region PR2.

Referring to FIG. 13B, as described with reference to FIG. 12C, the first source follower gate electrode SFG1 may be provided in one of the second active portions ACT2 of the third PD region PR3, and the second source follower gate electrodes SFG2 may be provided in the one of the second active portions ACT2 in the fourth PD region PR4.

The first interconnection conductive pattern ICP1 may be commonly connected to the first and second floating diffusion regions FD1 and FD2 provided in the first and third PD regions PR1 and PR3. The second interconnection conductive pattern ICP2 may be commonly connected to the first and second floating diffusion regions FD1 and FD2 provided in the second and fourth PD regions PR2 and PR4.

In the first PD region PR1, a first local conductive pad LCP1 may be provided on the source/drain region SDR at one side of the first pixel gate electrode PG1, and in the second PD region PR2, a second local conductive pad LCP2 may be provided on a source/drain regions SDR on one sides of the first pixel gateway electrode PG1.

Referring to FIG. 13C, unlike the embodiment shown in FIG. 13B, the second source follower gate electrode SFG2, the second interconnection conductive pattern ICP2, and the second local conductive pad LCP2 may be arranged point-symmetrically with the first source follower gate electrodes SFG1, the first interconnection conductive pattern ICP1, and the first local conductive pad LCP1.

Referring to FIG. 13D, one interconnection conductive pattern ICP may be commonly connected to the floating diffusion regions FD of the first to fourth PD regions PR1 to PR4. The interconnection conductive pattern ICP may include a connection portion protruding in the second direction D2 and disposed between the first active portions ACT1 and the second active portions ACT2 of the first PD region PR1. One source follower gate electrode SFG may be commonly disposed on the second active portions ACT2 of the third PD region PR3. The local conductive pad LCP may be provided on the source/drain region SDR at one side of the second pixel gate electrode PG2 in the first PD region PR1. In the local conductive pad LCP, the second common contact plug BCTb may be electrically connected to a connection portion of the interconnection conductive pattern ICP in the first PD region PR1.

Referring to FIG. 13E, as described with reference to FIG. 12F, the first interconnection conductive pattern ICP1 may be electrically connected to the first source follower gate electrode SFG1 and the first local conductive pad LCP1 through the first and second common contact plugs BCTa and BCTb.

The second interconnection conductive pattern ICP2 may be electrically connected to the second source follower gate electrode SFG2 and the second local conductive pad LCP2 through the first and second common contact plugs BCTa and BCTb.

Referring to FIG. 13F, unlike the embodiment shown in FIG. 13E, the second source follower gate electrode SFG2, the second interconnection conductive pattern ICP2, and the second local conductive pad LCP2 may be arranged point-symmetrically with the first source follower gate electrodes SFG1, the first interconnection conductive pattern ICP1, and the first local conductive pad LCP1.

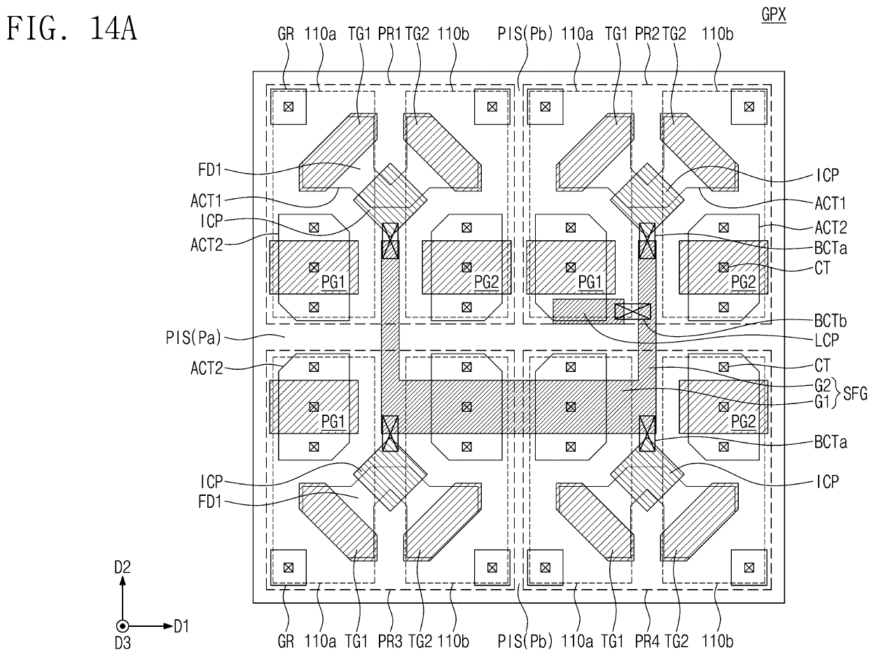

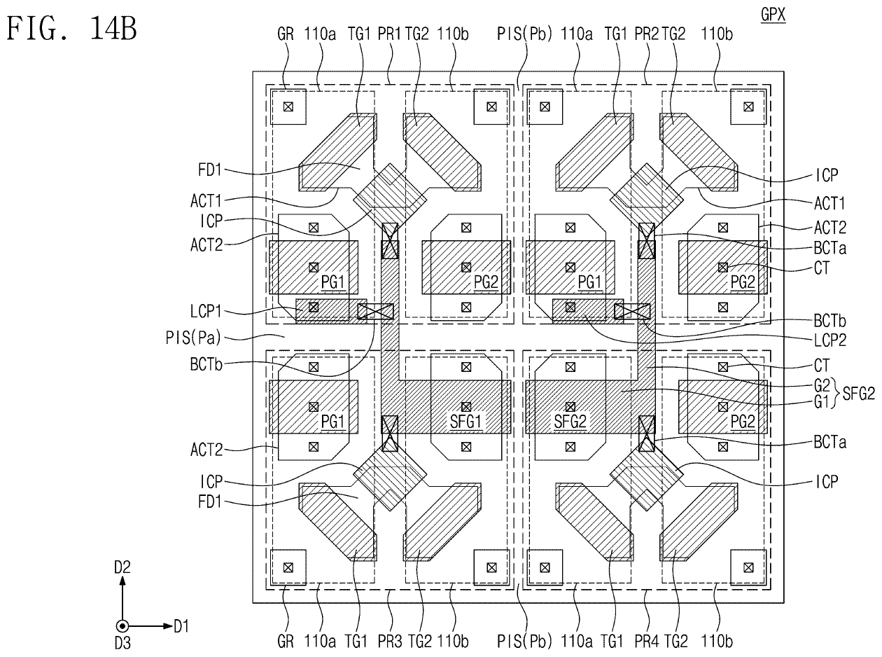

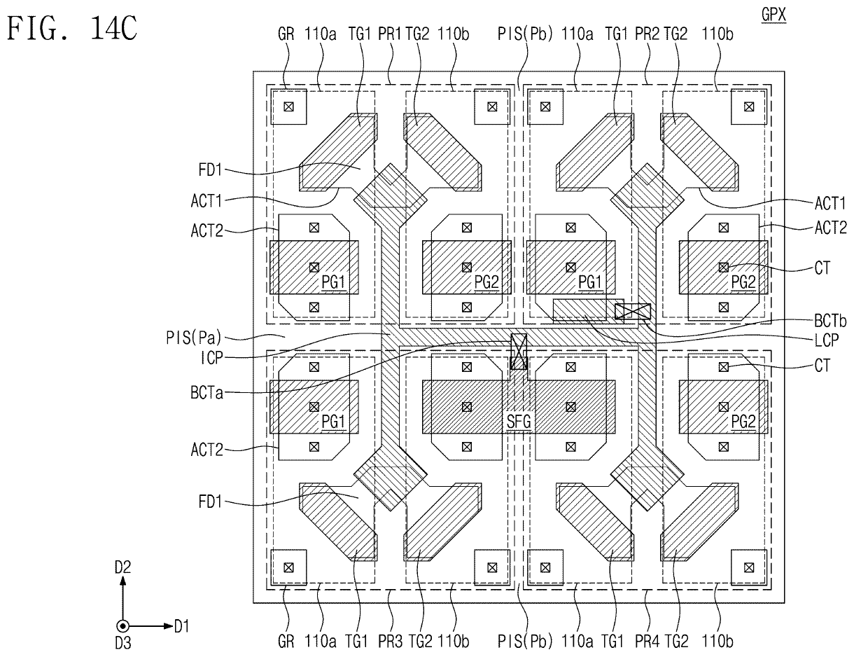

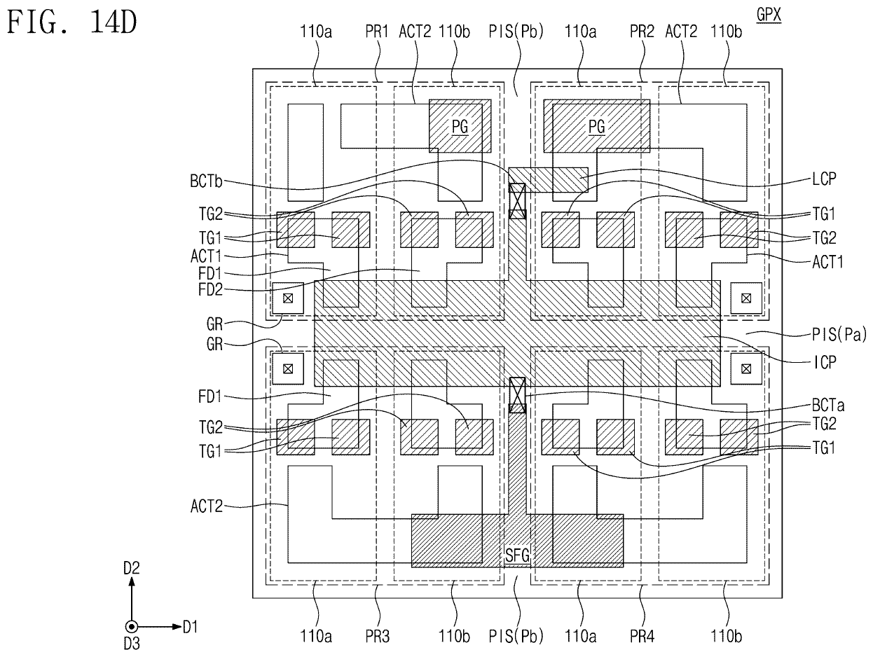

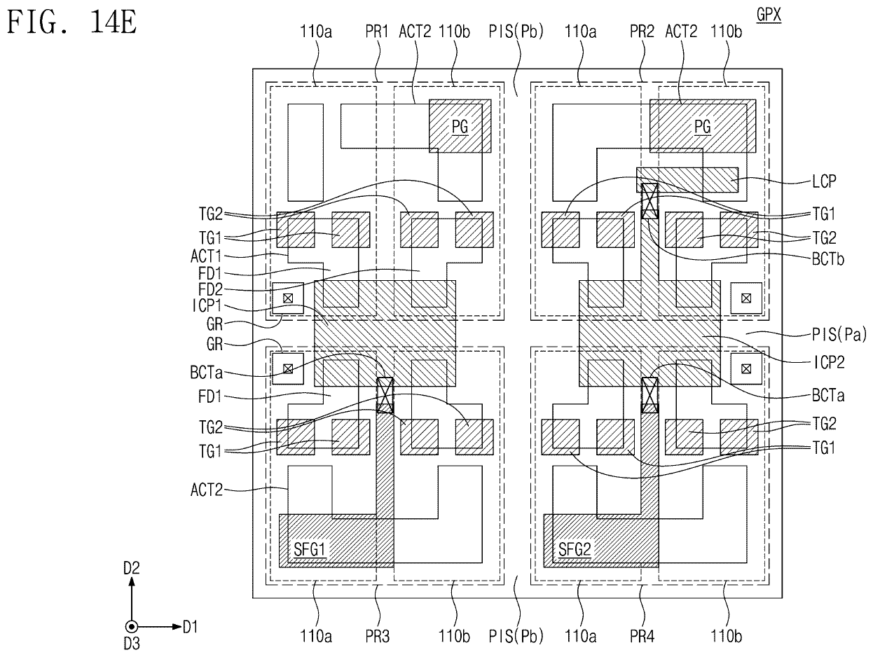

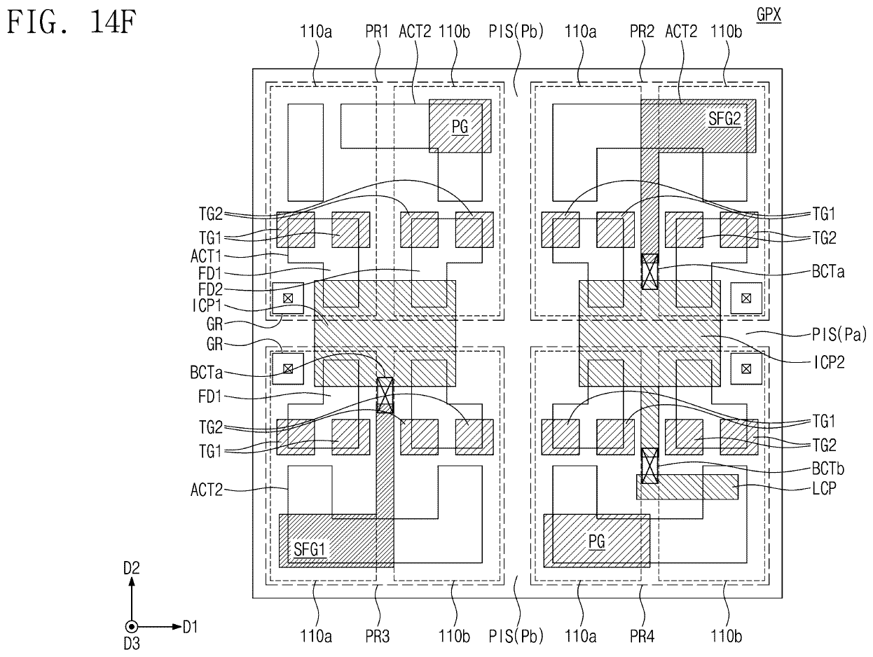

FIGS. 14A, 14B, 14C 14D, 14E, and 14F are plan views illustrating an image sensor according to some embodiments of the disclosed concepts. For concise description, the same technical features as the image sensor described with reference to FIGS. 3, 5A, and 5B may be omitted from the following description, and different technical features will be described below.

Referring to FIG. 14A, in addition to the embodiment shown in FIG. 3, the image sensor may further include a local conductive pad LCP in the second PD region PR2. The local conductive pad LCP may be disposed on the source/drain region SDR at one side of the first pixel gate electrode PG1 in the second PD region PR2. The local conductive pad LCP may contact the source/drain region SDR and may extend on a top surface of the device isolation layer STI or the PD isolation pattern PIS. The local conductive pad LCP may be connected to the second portion G2 of the source follower gate electrode SFG through the second common contact plug BCTb.

Referring to FIG. 14B, in addition to the embodiment shown in FIG. 5A, the image sensor may further include a first local conductive pad LCP1 in the first PD region PR1 and a second local conductive pad LCP2 in the second PD region PR2.

The first local conductive pad LCP1 may be disposed on the source/drain region SDR at one side of the first pixel gate electrode PG1 in the first PD region PR1. The first local conductive pad LCP1 may be connected to the second portion G2 of the first source follower gate electrode SFG1 through the second common contact plug BCTb.

The second local conductive pad LCP2 may be disposed on the source/drain region SDR at one side of the first pixel gate electrode PG1 in the second PD region PR2. The second local conductive pad LCP2 may be connected to the second portion G2 of the second source follower gate electrode SFG2 through the second common contact plug BCTb.

Referring to FIG. 14C, in addition to the embodiment shown in FIG. 5B, the image sensor may further include a local conductive pad LCP in the second PD region PR2. The local conductive pad LCP may be disposed on the source/drain region SDR at one side of the first pixel gate electrode PG1 in the second PD region PR2.

The interconnection conductive pattern ICP may be commonly connected to the floating diffusion regions FD of the first to fourth PD regions PR1 to PR4, and the local conductive pad LCP may be connected to the interconnection conductive pattern ICP through the second common contact plug BCTb.

FIGS. 14D, 14E, and 14F are plan views illustrating an image sensor according to some embodiments of the disclosed concepts. For concise description, the same technical features as the image sensor described with reference to FIGS. 9A, 9B, and 9C may be omitted from the following description, and different technical features will be described below.

Referring to FIG. 14D, in addition to the embodiment shown in FIG. 9A, the image sensor may further include a local conductive pad LCP in the second PD region PR2.

The local conductive pad LCP may be disposed on the source/drain region SDR at one side of the pixel gate electrode PG in the second PD region PR2. The local conductive pad LCP may contact the source/drain region SDR and may extend on a top surface of the device isolation layer STI or the PD isolation pattern PIS.

The interconnection conductive pattern ICP may further include a connection portion protruding in the second direction D2 and disposed on the device isolation layer STI or the PD isolation pattern PIS. The local conductive pad LCP may be connected to the connection portion of the interconnection conductive pattern ICP through the second common contact plug BCTb.

Referring to FIG. 14E, in addition to the embodiment shown in FIG. 9B, the image sensor may further include a local conductive pad LCP in the second PD region PR2. The second interconnection conductive pattern ICP2 may further include a connection portion protruding in the second direction D2 and disposed between the first active portions ACT1 of the second PD region PR2. The local conductive pad LCP may be connected to a connection portion of the second interconnection conductive pattern ICP2 through the second common contact plug BCTb.

Referring to FIG. 14F, in addition to the embodiment shown in FIG. 9C, the image sensor may further include a local conductive pad LCP in the fourth PD region PR4. The second interconnection conductive pattern ICP2 may further include a connection portion protruding in the second direction D2 and disposed between the first active portions ACT1 of the fourth PD region PR4. The local conductive pad LCP may be connected to a connection portion of the second interconnection conductive pattern ICP2 through the second common contact plug BCTb.

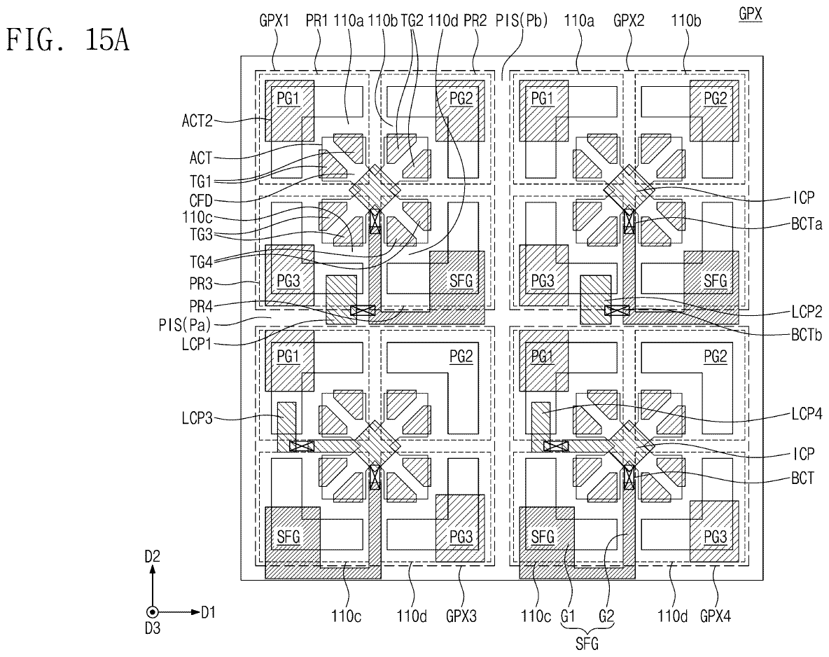

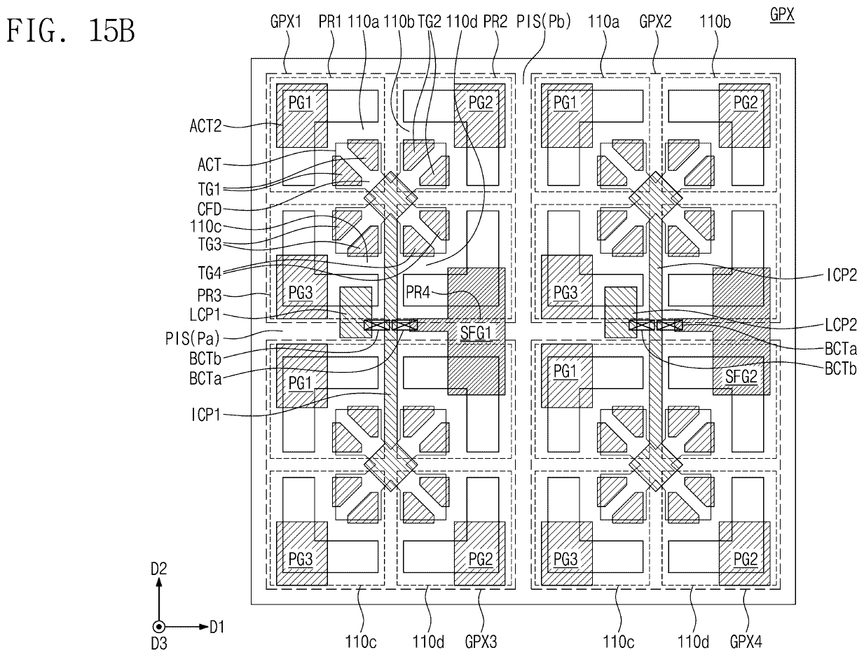

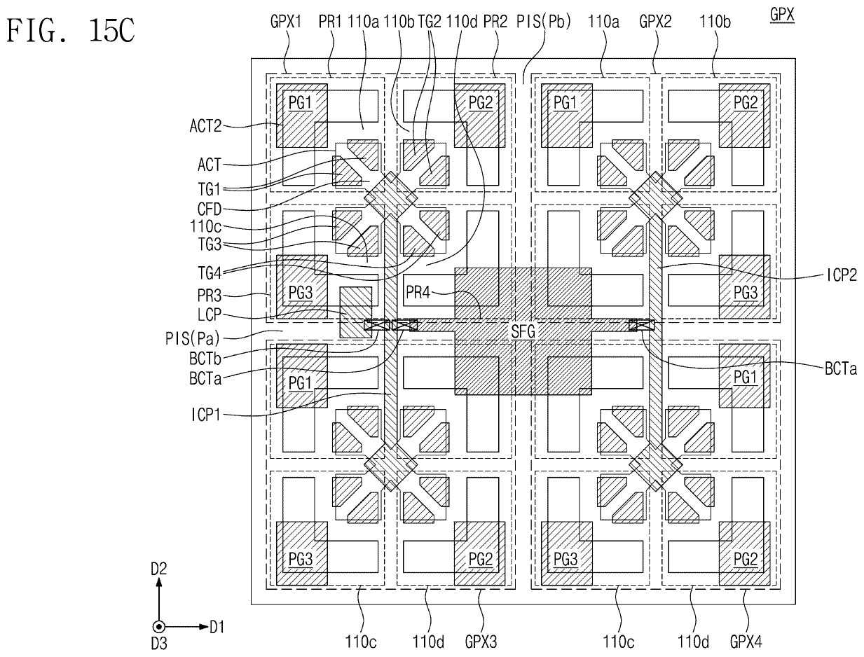

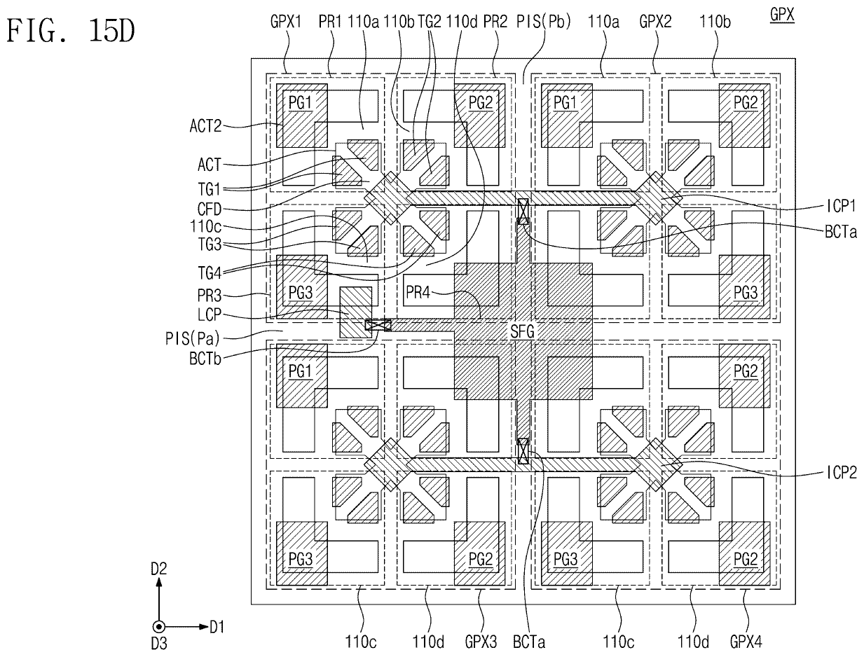

FIGS. 15A, 15B, 15C, and 15D are plan views illustrating an image sensor according to some embodiments of the disclosed concepts. For concise description, the same technical features as the image sensor described with reference to FIGS. 11A to 11D may be omitted from the following description, and different technical features will be described below.

Referring to FIG. 15A, in addition to the embodiment shown in FIG. 11A, in the first PD group GPX1, the first local conductive pad LCP1 may be disposed at one side of the third pixel gate electrode PG3 of the third PD region PR3. In the second PD group GPX2, the second local conductive pad LCP2 may be disposed at one side of the third pixel gate electrode PG3 of the third PD region PR3.

In the third PD group GPX1, the third local conductive pad LCP3 may be disposed at one side of the first pixel gate electrode PG1 of the first PD region PR1. In the fourth PD group GPX4, the fourth local conductive pad LCP4 may be disposed at one side of the first pixel gate electrode PG1 of the first PD region PR1.

In each of the third and fourth PD groups GPX3 and GPX4, the interconnection conductive pattern ICP may further include a connection portion protruding in the first direction D1 and disposed on the device isolation layer STI or the PD isolation pattern PIS.

The first local conductive pad LCP1 may be electrically connected to the interconnection conductive pattern ICP of the first PD group GPX1 through the second common contact plug BCTb. The second local conductive pad LCP2 may be electrically connected to the interconnection conductive pattern ICP of the second PD group GPX2 through the second common contact plug BCTb. The third local conductive pad LCP3 may be electrically connected to the connection portion of the interconnection conductive pattern ICP of the third PD group GPX3 through the second common contact plug BCTb. The fourth local conductive pad LCP4 may be electrically connected to the connection portion of the interconnection conductive pattern ICP of the fourth PD group GPX4 through the second common contact plug BCTb.

Referring to FIG. 15B, in addition to the embodiment shown in FIG. 11B, in the first PD group GPX1, the first local conductive pad LCP1 may be disposed at one side of the third pixel gate electrode PG3 of the third PD region PR3. In the second PD group GPX2, the second local conductive pad LCP2 may be disposed at one side of the third pixel gate electrode PG3 of the third PD region PR3.

The first local conductive pad LCP1 may be electrically connected to the first interconnection conductive pattern ICP1 through the second common contact plug BCTb. The second local conductive pad LCP2 may be electrically connected to the second interconnection conductive pattern ICP2 through the second common contact plug BCTb.

Referring to FIG. 15C, in addition to the embodiment shown in FIG. 11C, in the first PD group GPX1, a local conductive pad LCP may be disposed at one side of the third pixel gate electrode PG3 of the third PD region PR3.

The local conductive pad LCP may be electrically connected to the first interconnection conductive pattern ICP1 through the second common contact plug BCTb. That is, the local conductive pad LCP may be electrically connected to the source follower gate electrode SFG through the second common contact plug BCTb, the first interconnection conductive pattern ICP1, and the first common contact plug BCTa. In other words, the local conductive pad LCP may be electrically connected to the common floating diffusion regions CFDs of the first to fourth PD groups GPX1 to GPX4.

Referring to FIG. 15D, in addition to the embodiment shown in FIG. 11D, in the first PD group GPX1, a local conductive pad LCP may be disposed at one side of the third pixel gate electrode PG3 of the third PD region PR3. The source follower gate electrode SFG may include a portion extending in the first direction D1 and adjacent to the local conductive pad LCP. The local conductive pad LCP may be electrically connected to a portion of the source follower gate electrode SFG through the second common contact plug BCTb.

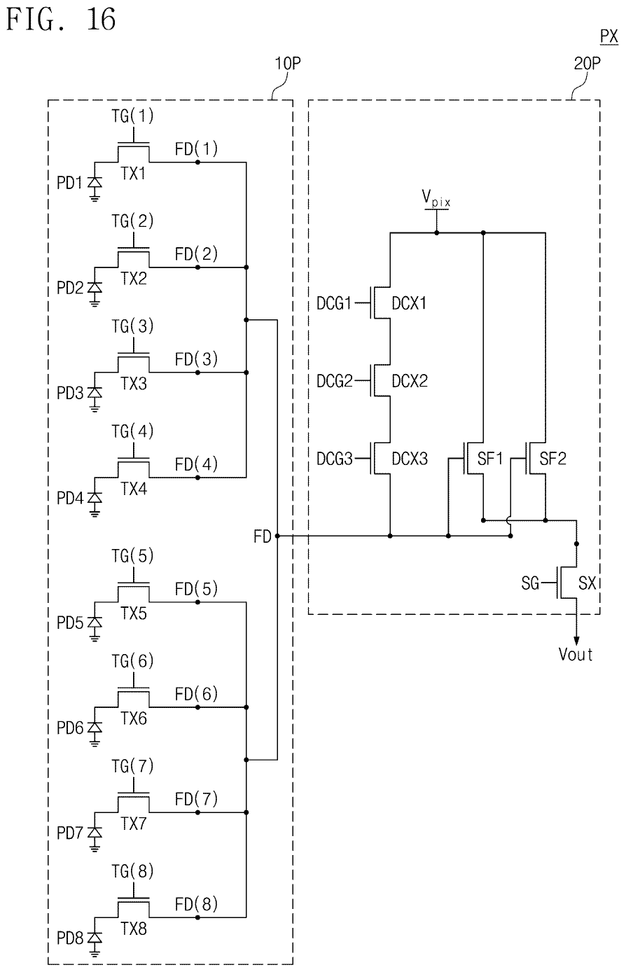

FIG. 16 is a circuit diagram illustrating a unit pixel of an image sensor according to embodiments of the disclosed concepts.

Referring to FIG. 16, the unit pixel PX may include a photoelectric conversion circuit 10P and a pixel circuit 20P, as described above with reference to FIGS. 2A and 2B.

The photoelectric conversion circuit 10P may include first to eighth photoelectric conversion elements PD1 to PD8, first to eighth transfer transistors TX1 to TX8, and a floating diffusion region FD.

The pixel circuit 20P may include first, second, and third dual-conversion gain transistors DCX1, DCX2, and DCX3, first and second source follower transistors SF1 and SF2, and a selection transistor SX.

The first source follower transistor SF1 may be connected between the power supply voltage VpIx and the selection transistor SX. The second source follower transistor SF2 may be connected between the power supply voltage VpIx and the selection transistor SX. The first and second source follower transistors SF1 and SF2 may be connected in parallel.

The first, second, and third dual-conversion gain transistors DCX1, DCX2, and DCX3 may be connected between the power supply voltage VpIx and the floating diffusion region FD. The first, second, and third dual conversion gain transistors DCX1, DCX2, and DCX3 may vary the dual conversion gain of the unit pixel PX by varying the capacitance of the floating diffusion region FD in response to the first, second, or third dual conversion gain control signals DCG1, DCG2, and DCG3.

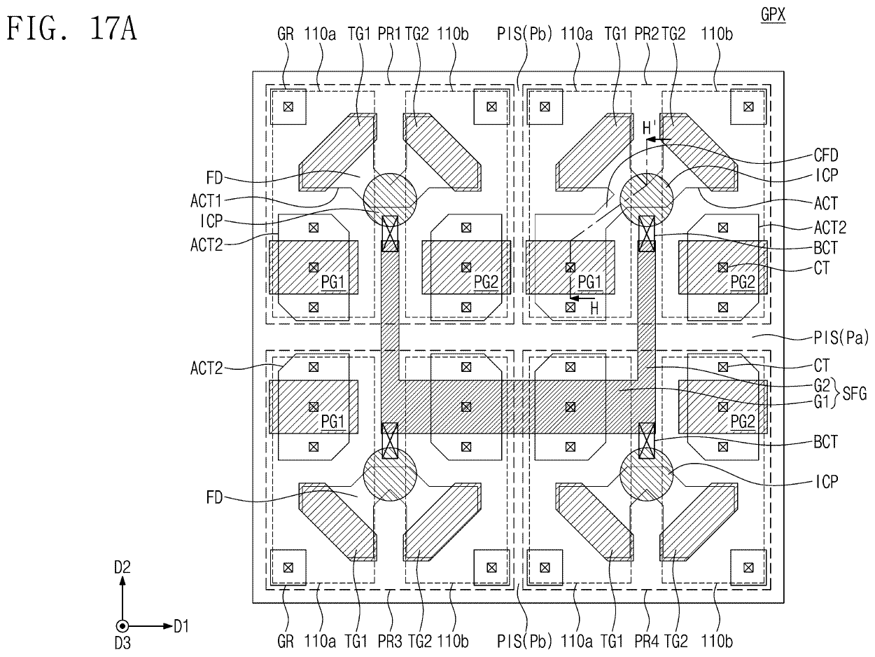

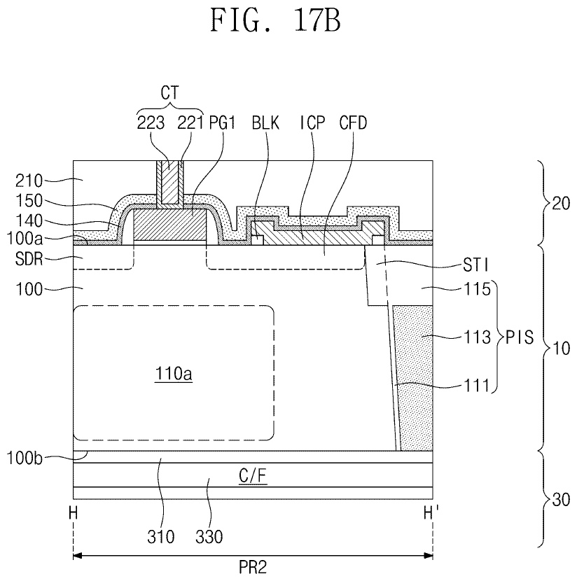

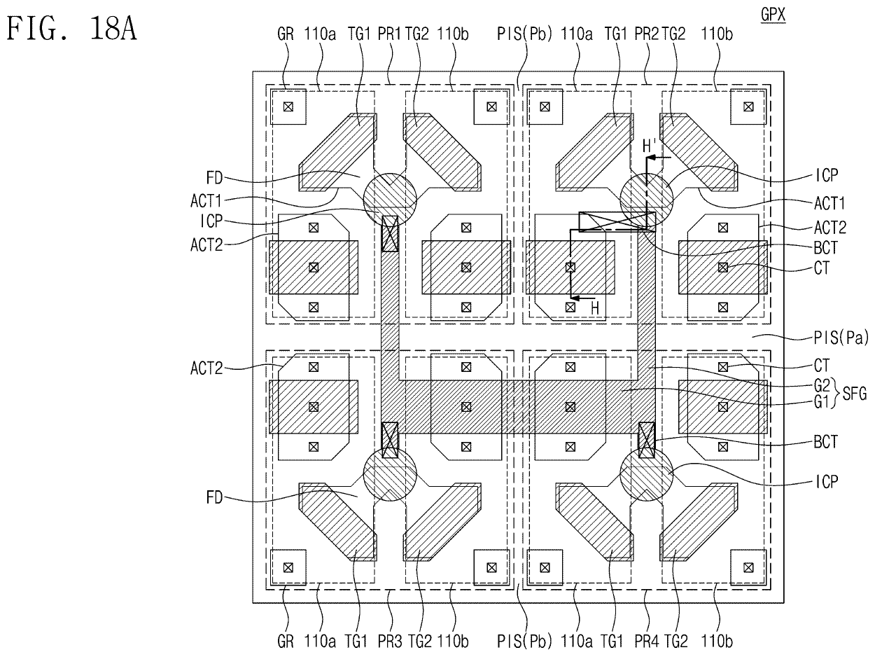

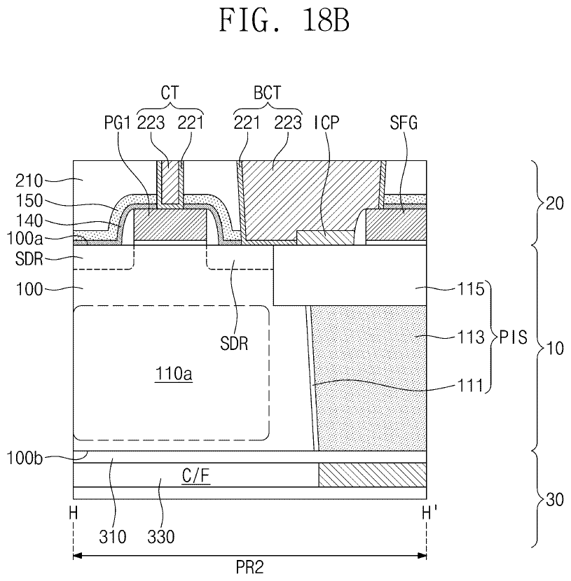

FIGS. 17A and 18A are plan views illustrating an image sensor according to some embodiments of the disclosed concepts. FIGS. 17B and 18B are cross-sectional views taken along a line H-H′ of FIGS. 17A and 18A, respectively.

Referring to FIGS. 17A and 17B, as described with reference to FIG. 3, the first to fourth PD regions PR1 to PR4 may be defined by a PD isolation pattern PIS in the semiconductor substrate 100.

The device isolation layer STI may define a first active portion ACT1 and second active portions ACT2 in each of the first to fourth PD regions PR1 to PR4. As described with reference to FIG. 3, the device isolation layer STI may be provided with one first active portion ACT1 and two second active portions ACT2 in each of the first, third, and fourth PD regions PR1 PR3 and PR4.

According to some embodiments, in the second PD region PR2, the first active portion ACT1 may be connected to one of the second active portions ACT2 to define one common active portion ACT.

A common floating diffusion region CFD may be provided in the common active portion ACT at one side of the first pixel gate electrode PG1 and at one side of first and second transfer gate electrodes TG1 and TG2 in the second PD region.

The interconnection conductive pattern ICP of the second PD region PR2 may directly contact the common floating diffusion region CFD. In other words, the common floating diffusion region CFD, the source/drain region SDR of the pixel transistor (e.g., a reset or dual conversion gain transistor) of the second PD region PR2, and the source follower gate electrode SFG may be electrically connected to each other through the interconnection conductive pattern ICP and the common contact plug BCT.

Referring to FIGS. 18A and 18B, as described with reference to FIG. 3, one first active portion ACT1 and two second active portions ACT2 may be provided in each of the first to fourth PD regions PR1 to PR4.

According to some embodiments, one of the common contact plugs BCT in the second PD region PR2 may directly contact the interconnection conductive pattern ICP of the second PD region PR2, the second portion G2 of the source follower gate electrode SFG, and the source/drain region SDR at one side of the first pixel gate electrode of the second PD region PR2.

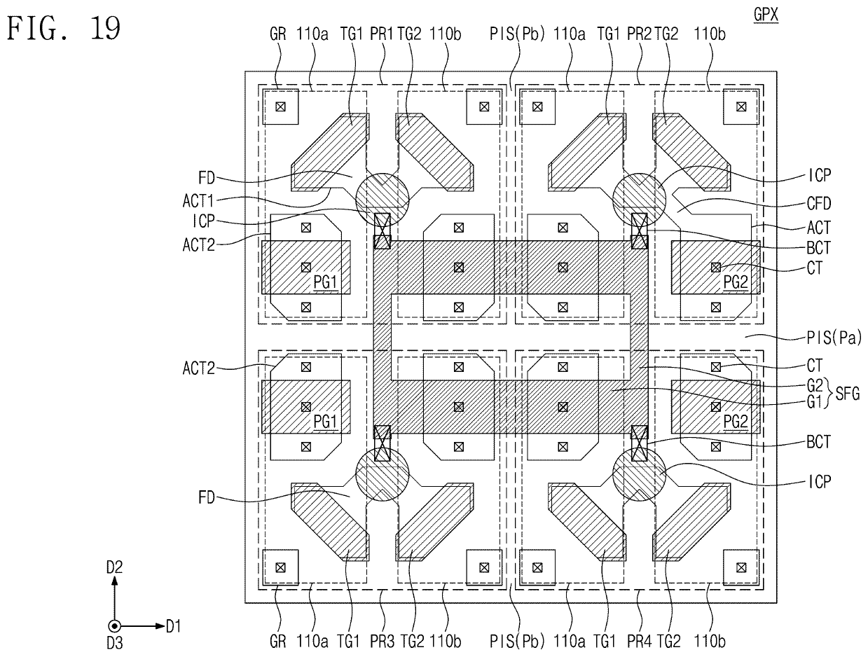

FIGS. 19, 20, 21, and 22 are plan views illustrating an image sensor according to some embodiments of the disclosed concepts.

Referring to FIG. 19, the device isolation layer STI may define a first active portion ACT1 and second active portions ACT2 in each of the first to fourth PD regions PR1 to PR4. As described with reference to FIG. 3, the device isolation layer STI may be provided with one first active portion ACT1 and two second active portions ACT2 in each of the first, third, and fourth PD regions PR1 PR3 and PR4.

According to some embodiments, in the second PD region PR2, the first active portion ACT1 may be connected to one of the second active portions ACT2 to define one common active portion ACT. A common floating diffusion region CFD may be provided in the common active portion ACT at one side of the second pixel gate electrode PG2 and between the first and second transfer gate electrodes TG1 and TG2 in the second PD region PR2. The interconnection conductive pattern ICP of the second PD region PR2 may directly contact the common floating diffusion region CFD.

In addition, the source follower gate electrode SFG may be commonly disposed in the first to fourth PD regions PR1 to PR4. In other words, the source follower gate electrode SFG may include first portions G1 crossing the second active portions ACT2 and second portions G2 extended from the first portions in the second direction D2 and disposed on the device isolation layer STI or the PD isolation pattern PIS. Here, one of the first portions G1 may cross the second active portions ACT2 of the first and second PD regions PR1 and PR2, and the other of the first portions G1 may cross the second active portions ACT2 of the third and fourth PD regions PR3 and PR4. In addition, one of the second portions G2 may be adjacent to the interconnection conductive patterns ICP of the first and third PD regions PR1 and PR3, and the other of the second portions G2 may be adjacent the connection conduction pattern ICP of the second and fourth PD regions PR2 and PR4.

The interconnection conductive patterns ICP of the first to fourth PD regions PR1 to PR4 may be connected to the second portions G2 of the source follower gate electrode SFG through the common contact plugs BCT.

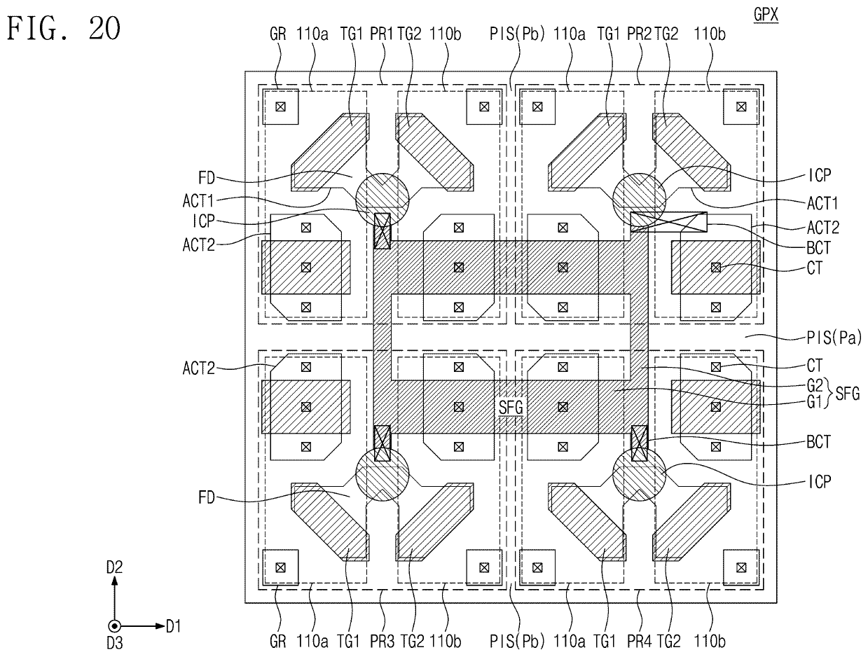

Referring to FIG. 20, unlike the embodiment described with reference to FIG. 19, one first active portion ACT1 and two second active portions ACT2 may be provided in each of the first to fourth PD regions PR1 to PR4.

According to some embodiments, the common contact plug BCT in the second PD region PR2 may directly contact the interconnection conductive pattern ICP of the second PD region PR2, the second portion G2 of the source follower gate electrode SFG, and the source/drain region SDR at one side of the second pixel gate electrode PG2 of the second PD region PR2.

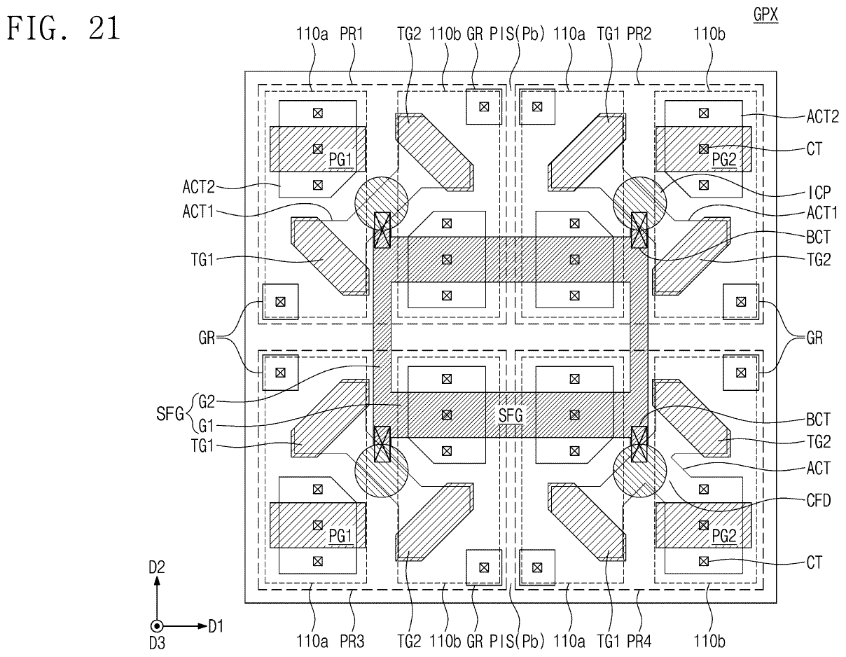

According to the embodiment shown in FIG. 21, unlike the embodiment shown in FIGS. 19A and 19B, the device isolation layer STI may be provided with one first active portion ACT1 and two second active portions ACT2 in each of the first, third, and fourth PD regions PR1 PR3 and PR4.

According to some embodiments, in the fourth PD region PR4, the first active portion ACT1 may be connected to one of the second active portions ACT2 to define one common active portion ACT. In addition, in each of the first to fourth PD regions PR1 to PR4, the second active portions ACT2 may be arranged in a diagonal direction with respect to the first direction D1 and the second direction D2. The interconnection conductive pattern ICP of the fourth PD region PR4 may directly contact the common floating diffusion region CFD.

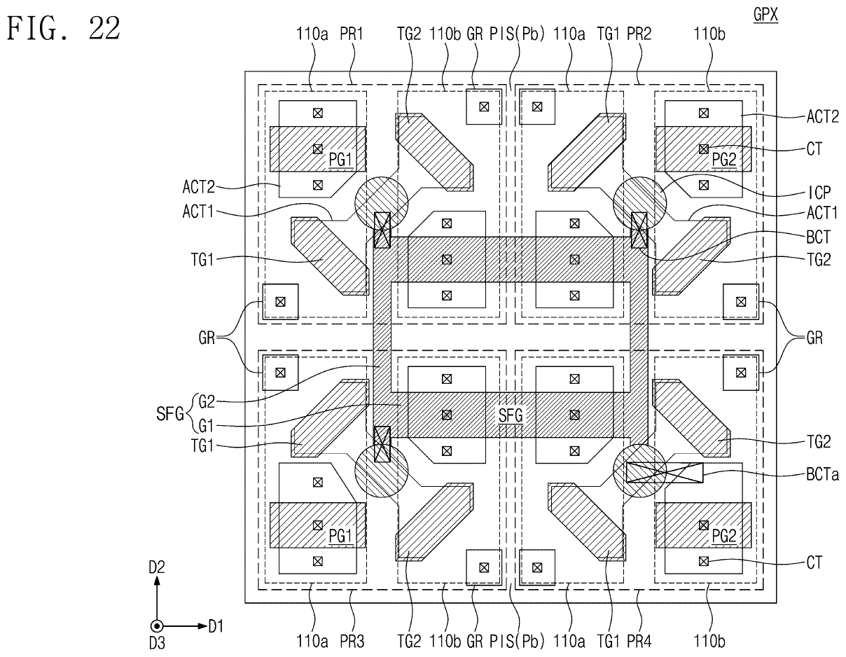

Referring to FIG. 22, unlike the embodiment shown in FIG. 20, in each of the first to fourth PD regions PR1 to PR4, the first and second transfer gate electrodes TG1 and TG2 provided on the first active portion ACT1 may face each other in the diagonal direction. The directions in which the first and second transfer gate electrodes TG1 and TG2 face each other may be different from each other in the first to fourth PD regions PR1 to PR4. In addition, in each of the first to fourth PD regions PR1 to PR4, the second active portions ACT2 may be arranged in the diagonal direction to each other.

Further, the common contact plug BCT in the fourth PD region PR4 may directly contact the interconnection conductive pattern ICP of the fourth PD region PR4, the second portion G2 of the source follower gate electrode SFG, and the source/drain region SDR at one side of the second pixel gate electrode PG2 of the fourth PD region PR4.

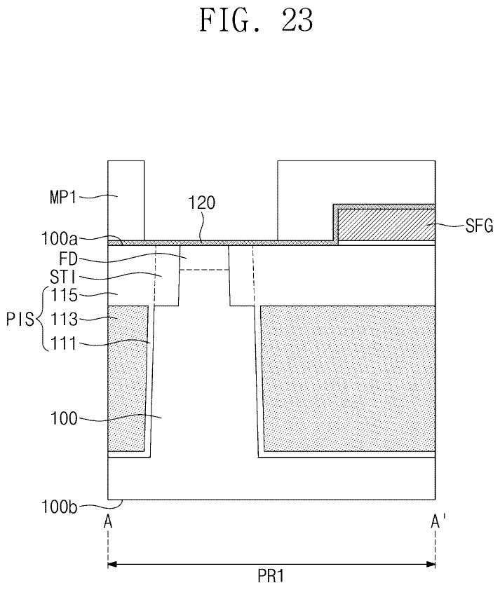

FIGS. 23 to 27 are cross-sectional views, which are taken along a line A-A′ of FIG. 3 to illustrate a method of fabricating an image sensor according to embodiments of the disclosed concepts.

Referring to FIGS. 3 and 23, a semiconductor substrate 100 of a first conductivity type (e.g., p-type) may be provided. In some embodiments, the semiconductor substrate 100 may include an epitaxial layer. The semiconductor substrate 100 may have a first surface 100a and a second surface 100b opposite to the first surface 100a.

In some embodiments, the semiconductor substrate 100 may be a bulk semiconductor substrate including wells of a first conductivity type. Alternatively, the semiconductor substrate 100 may be a silicon-on-insulator (SOI) substrate, a germanium substrate, a Germanium on-insulator (GOI) substrate, or a silicon-germanium substrate.

A device isolation layer STI adjacent to the first surface 100a of the semiconductor substrate 100 and defining active portions may be formed on the semiconductor substrate 100 in each of the PD regions PR1 to PR4. Forming the device isolation layer STI may include patterning the first surface 100a of the semiconductor substrate 100 to form a first trench, forming a liner insulating layer conformally covering an inner surface of the first trench, and forming an insulating layer filling the first trench in which the liner insulating layer is formed. Forming the device isolation layer STI may be performed before or after forming the photoelectric conversion regions 110a and 110b.

A PD isolation pattern PIS defining the PD regions PR1 to PR4 may be formed on the semiconductor substrate 100. Forming the PD isolation pattern PIS may include patterning the first surface 100a of the semiconductor substrate 100 to form a second trench, forming a liner insulating layer conformally covering an inner side of the second trench, depositing a semiconductor layer to fill the second trench in which the liner insulating layer is formed, and planarizing the liner insulating layer and the buried pattern 113 to expose the first surface 100a of the semiconductor substrate and to form the liner insulating pattern 111, the buried pattern 113, and the capping insulation pattern 115 in the second trench.

The liner insulating pattern 111 and the capping insulation pattern 115 may include, for example, silicon oxide, silicon nitride, and/or silicon oxynitride. The buried pattern 113 may include an impurity-doped polysilicon layer and/or an undoped poly-silicon layer.

Next, the first photoelectric conversion region 110a and the second photoelectric conversion region 110b may be formed in the semiconductor substrate 100 of each of the PD regions PR1 to PR4.

The first and second photoelectric conversion regions 110a and 110b may be formed by doping dopants of a second conductivity type (e.g., n-type) different from the first conductivity type in the semiconductor substrate 100 in the respective PD regions PR1 to PR4. The first and second photoelectric conversion regions 110a and 110b may be spaced apart from the first surface 100a and the second surface 100b of the semiconductor substrate 100. The first and second photoelectric conversion regions 110a and 110b may be formed before or after forming the PD isolation pattern PIS.

Thereafter, the first transfer gate electrode TG1 and the second transfer gate electrode TG2 may be formed in the first active portion ACT1 of each of the PD regions PR1 to PR4. Forming the first and second transfer gate electrodes TG1 and TG2 includes patterning the first surface 100a of the semiconductor substrate 100 to form a gate recess region in each of the PD regions PR1 to PR4, forming a gate insulating layer conformally covering an inner surface of the gate recess region, and forming a gate conductive layer filling the gate recess region and patterning the gate conductive layer. In some embodiments, each of the first and second transfer gate electrodes TG1 and TG2 may include two vertical portions disposed in the semiconductor substrate 100.

The gate insulating layer may include a silicon oxide layer, a silicon oxynitride layer, or a silicon nitride layer. The gate insulating layer may be formed by performing a deposition process so as to conformally cover the inner wall of the vertical trench.

The first and second transfer gate electrodes TG1 and TG2 may be formed by forming a gate conductive layer filling a vertical trench in which a gate insulating layer is formed and then patterning the gate conductive layer. The gate conductive layer may include a doped polysilicon layer, a metal silicide layer, a conductive metal nitride layer, or a metal layer.

When the first and second transfer gate electrodes TG1 and TG2 are formed, the first and second pixel gate electrodes PG1 and PG2 of the pixel transistors and the source follower gate electrode SFG may be formed together in the second active portions ACT2 of each of the PD regions PR1 to PR4.

After the first and second transfer gate electrodes TG1 and TG2 are formed, floating diffusion regions FD may be formed in the semiconductor substrate 100 between the first and second transferred gate electrodes TG1 and TG2. The floating diffusion regions FD may be formed by ion implanting dopants of the second conductivity type using an ion implantation mask. Further, when forming the floating diffusion regions FD, source/drain regions of the pixel transistors may be formed together.

Subsequently, a spacer insulating layer 120 may be deposited on the first surface 100a of the semiconductor substrate 100. The spacer insulating layer 120 may cover the first and second transfer gate electrodes TG1 and TG2 and the pixel gate electrodes PG1 and PG2. SFG with a substantially uniform thickness.

The spacer insulating layer 120 may include, for example, silicon oxide, silicon nitride, silicon oxynitride, silicon carbon nitride (SiCN), or silicon carbon oxynitrate (SiCON). The spacer insulating layer 120 may be deposited by, for example, an atomic layer deposition (ALD) process, a plasma-enhanced chemical vapor deposition (PECVD) process, a low-pressure CVD (LPCVD) process, or a flowable CVD (FCVD) process.

A first mask pattern MP1 having an opening that exposes a portion of the spacer insulating layer 120 may be formed on the spacer insulating layer 120. The opening of the first mask pattern MP1 may overlap portions of the floating diffusion regions FD of the PD regions PR1 to PR4. For example, the first mask pattern MP1 may be formed by coating a photoresist layer on the first surface 100a of the semiconductor substrate 100 and performing exposure and development processes on the photoresist layer.

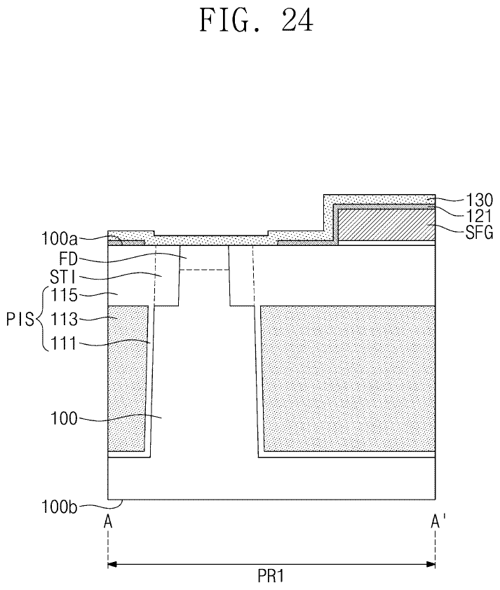

Referring to FIGS. 3 and 24, a spacer insulating pattern 121 may be formed by anisotropically etching the spacer insulating layer 120 using the first mask pattern MP1 as an etching mask.

Thereafter, the floating diffusion region FD may be formed by ion implanting dopants of the second conductivity type into the first active portion ACT1 of the semiconductor substrate 100 using the spacer insulating pattern 121 as an ion implantation mask pattern.

Then, a conductive layer 130 may be deposited on the entire surface of the semiconductor substrate 100 to have a substantially uniform thickness. The conductive layer 130 may directly contact the second doped regions FDb and may cover the spacer insulating pattern 121. The conductive layer 130 may include, for example, a doped polysilicon layer, a metal silicide layer, a conductive metal nitride layer, or a metal layer. For example, the conductive layer 130 may be formed by depositing a semiconductor layer, and impurities may be doped in-situ when the semiconductor layer is deposited.

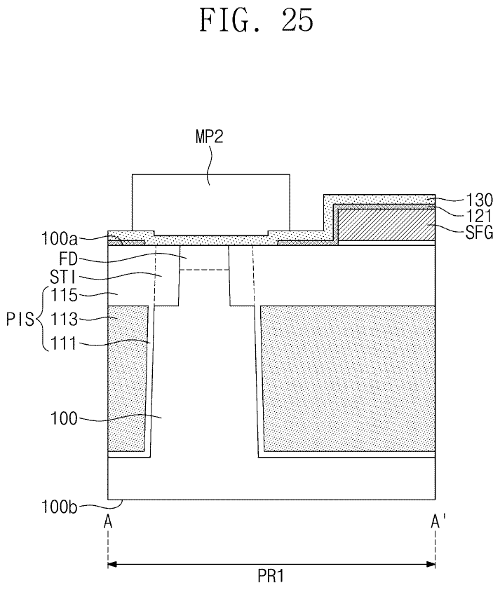

Referring to FIGS. 3 and 25, a second mask pattern MP2 may be formed on the conductive layer 130, and the second mask pattern MP1 may overlap the floating diffusion regions FD.

Thereafter, the interconnection conductive pattern ICP may be formed by anisotropically etching the conductive layer 130 using the second mask pattern MP2 as an etching mask. After forming the interconnection conductive pattern ICP, the second mask pattern MP2 may be removed.

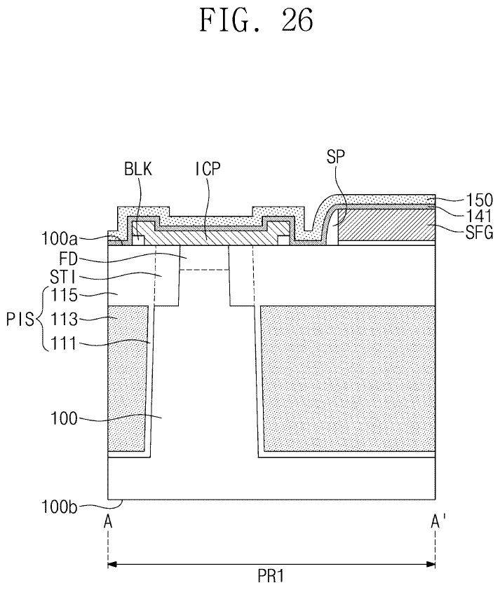

Referring to FIGS. 3 and 26, an etching process (e.g., etch-back) may be performed on the first surface 100a of the semiconductor substrate 100 on which the spacer insulating pattern 121 is formed. As a result, a part of the spacer insulating pattern 121 may remain, and insulating spacers SP may be formed on opposite sidewalls of the first and second transfer gate electrodes TG1 and TG2, opposite sidewalls of each of the pixel gate electrodes PG1 and PG2 and opposite sidewalls of the source follower gate electrode SFG. A blocking pattern BLK may be formed on an edge portion of the interconnection conductive pattern ICP.

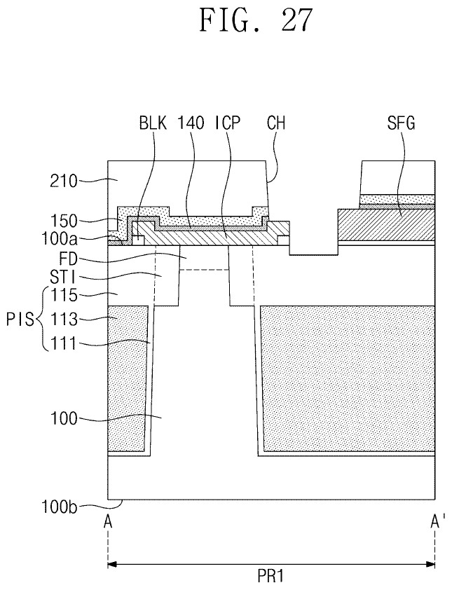

Thereafter, referring to FIGS. 3 and 27, the first and second etch stop layers 140 and 150 may be sequentially deposited to a substantially uniform thickness on the first surface 100a of the semiconductor substrate 100.

The first and second etch stop layers 140 and 150 may be deposited by, for example, a plasma enhanced CVD (PECVD), a low-pressure CVD (LPCVD), or a flowable chemical vapor deposition (FCVD) process. The first and second etch stop layers 140 and 150 may include silicon nitride or silicon oxynitride.

An interlayer insulating layer 210 may be formed on the second etch stop layer 150. The interlayer insulating layer 210 may include, for example, at least one of a silicon oxide layer, a silicon oxynitride layer, and a silicon nitride layer. The interlayer insulating layer 210 may be formed using at least one of physical vapor deposition (PVD), chemical vapor deposition (CVD), or atomic layer deposition (ALD) techniques. The interlayer insulating layer 210 may have a top surface planarized by a planarization process.

After a mask pattern (not shown) is formed on the interlayer insulating layer 210, a common contact hole CH exposing a part of the interconnection conductive pattern ICP and a part of the source follower gate electrode SFG may be formed by sequentially etching the interlayer insulating layer 210 and the first and second etch stop layers 140 and 150. The common contact hole CH may expose a portion of the PD isolation pattern PIS between the interconnection conductive pattern ICP and the source follower gate electrode SFG.

Thereafter, a barrier metal layer and a metal layer may be sequentially deposited on the interlayer insulating layer 210, and a planarization process for the barrier metal layer and the metal layer may be performed to expose a top surface of the interlayer insulating layer 210. Accordingly, as shown in FIGS. 3 and 4A to 4C, a common contact plug BCT filling the common contact hole CH may be formed.

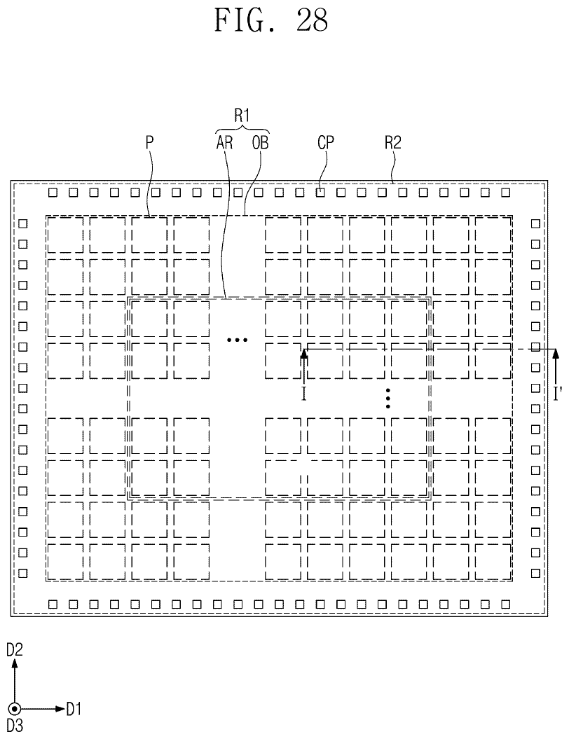

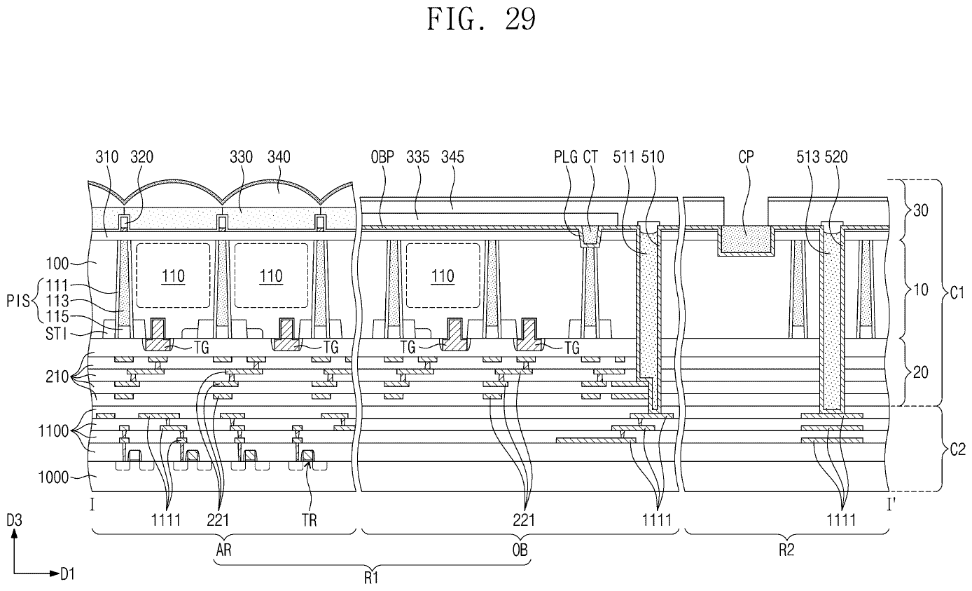

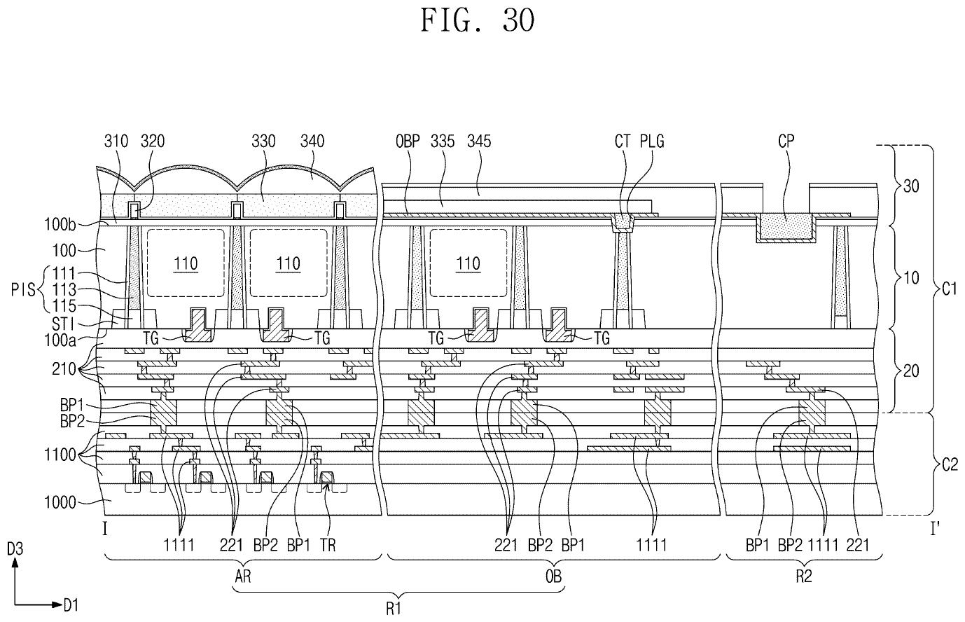

FIG. 28 is a schematic plan view illustrating an image sensor according to embodiments of the disclosed concepts. FIGS. 29 and 30 are cross-sectional views, which are taken along a line I-I′ of FIG. 28 to illustrate an image sensor according to some example embodiments.

Referring to FIGS. 28 and 29, the image sensor may include a sensor chip C1 and a logic chip C2. The sensor chip C1 may include a pixel array region R1 and a pad region R2.

The pixel array region R1 may include a plurality of unit pixels P, which are two-dimensionally arranged along the first direction D1 and the second direction D2 intersecting each other. Each of the unit pixels P may include a photoelectric conversion element and readout elements. An electrical signal generated by incident light may be output from each of the unit pixels P of the pixel array region R1.

The pixel array region R1 may include a light receiving region AR and a light-blocking region OB. The light-blocking region OB may surround the light-receiving region AR in a plan view. For example, the light-blocking region OB may surround the light-receiving region AR in four different directions (e.g., up, down, left, and rights directions), in a plan view. In embodiments, reference pixels on which light is not incident may be provided in the light shielding region OB, and a magnitude of an electric signal sensed in the unit pixels PX may be calculated by comparing an amount of charges sensed in the unit pixels PX of the light-receiving region AR with a reference amount of charges generated in the reference pixels.

A plurality of conductive pads CP used to input and output control signals, a photoelectric signal, and the like may be disposed in the pad region R2. The pad region R2 may surround the pixel array region R1 in a plan view to facilitate electrical connection with external devices. The conductive pads CP may input/output an electrical signal generated in the unit pixels P to/from the external devices.

In the light-receiving region AR, the sensor chip C1 may include the same technical features as the image sensor described above. That is, as described above, the sensor chip C1 may include the photoelectric conversion circuit layer 10 between the pixel circuit layer 20 and the optically-transparent layer 30 in the third direction D3. The photoelectric conversion circuit layer 10 of the sensor chip C1 may include the semiconductor substrate 100, the PD isolation pattern PIS defining PD regions, and photoelectric conversion regions 110 provided in the PD regions, as described above. The PD isolation pattern PIS may have substantially the same structure in the light-receiving region AR and the light-blocking region OB. The PD isolation pattern PIS may be disposed in the semiconductor substrate 100 of the light-blocking region OB. The buried pattern 113 of the PD isolation pattern PIS may be electrically connected to the backside contact plug PLG in the light-blocking region OB. A predetermined bias may be applied to the buried pattern 113 via the backside contact plug PLG. The backside contact plug PLG may have a width greater than a width of the PD isolation pattern PIS. The backside contact plug PLG may include a metal and/or a metal nitride. For example, the backside contact plug PLG may include titanium and/or titanium nitride.

The contact pattern CT may be embedded in a contact hole in which the backside contact plug PLG is formed. The contact pattern CT may include a material different from the backside contact plug PLG. For example, the contact pattern CT may include aluminum (Al).

The contact pattern CT and the backside contact plug PLG may be electrically connected to the buried pattern 113 of the PD isolation pattern PIS. A negative bias may be applied to the buried pattern 113 of the PD isolation pattern PIS via the contact pattern CT, and the negative bias may be transferred from the light-blocking region OB to the light receiving region AR. Accordingly, dark current generated at the interface between the PD isolation pattern PIS and the semiconductor substrate 100 may be reduced.

The optically-transparent layer 30 may include a light-blocking pattern OBP, a filtering layer 335, and an organic layer 345 in the light-blocking region OB. In some embodiments, the PD isolation pattern PIS may extend continuously from light-receiving region AR to the light-blocking region OB.

In the light-blocking region OB, the light-blocking pattern OBP may be disposed on the top surface of the planarization insulating layer 310. The light-blocking pattern OBP may include the same material as the conductive pattern of the grid 320 of the light-receiving region AR. In other words, the light-blocking pattern OBP may include a metal pattern and a metal oxide pattern. For example, the light-blocking pattern OBP may include titanium nitride and titanium oxynitride. The light-blocking pattern OBP may not extend to the light-receiving region AR.

The light-blocking pattern OBP may block light from being incident on the photoelectric conversion regions PD, in the light-blocking region OB. The photoelectric conversion regions PD may output a noise signal without outputting a photoelectric signal in reference PD regions of the light shielding region OB. The noise signal may be generated due to electrons generated by dark current or heat generation.

The filtering layer 335 may cover the light-blocking pattern OBP in the light-blocking region OB. The filtering layer 335 may block light having a wavelength different from that of the color filters 330. For example, the filtering layer 335 may block infrared rays. The filtering layer 335 may include, but is not limited to, a blue color filter.

The organic layer 345 and the passivation layer may be provided on the protective layer in the light-blocking region OB and the pad region R2. The organic layer 345 may include the same material as the micro-lenses 340.

In the light-blocking region OB, a first through conductive pattern 510 may penetrate the semiconductor substrate 100 to be electrically connected to metal wirings of the pixel circuit layer 20 and metal wirings 1111 of the logic chip C2. The first through conductive pattern 510 may have a first bottom surface and a second bottom surface located at different levels. A first buried pattern 511 may be provided inside the first through conductive pattern 510. The first buried pattern 511 includes a low-refractive-index material and may have insulating properties.

In the pad region R2, conductive pads CP may be provided on the second surface 100b of the semiconductor substrate 100. The conductive pads CP may be embedded in the second surface 100b of the semiconductor substrate 100. For example, the conductive pads CP may be provided in a pad trench formed in the second surface 100b of the semiconductor substrate 100 in the pad region R2. The conductive pads CP may be formed of or include at least one of metallic materials (e.g., aluminum, copper, tungsten, titanium, tantalum, or alloys thereof). In a process of mounting an image sensor, bonding wires may be bonded to the conductive pads CP. The conductive pads CP may be electrically connected to an external device through the bonding wires.

In the pad region R2, a second through-conduction pattern 520 may penetrate the semiconductor substrate 100 to be electrically connected to the metal wirings 1111 of the logic chip C2. The second through conductive pattern 520 may extend on the second surface 100b of the semiconductor substrate 100 to be electrically connected to the conductive pads CP. A portion of the second through conductive pattern 520 may cover the bottom surface and the sidewall of the conductive pads CP. A second buried pattern 513 may be provided inside the second through conductive pattern 520. The second buried pattern 513 includes a low-refractive-index material and may have insulating properties. In the pad region R2, the PD isolation patterns PIS may be provided around the second through conductive pattern 520.

The logic chip C2 may include a logic semiconductor substrate 1000, logic circuits TR, the metal wirings 1111 connected to the logic circuits TR and logic interlayer insulating layers 1100. An uppermost layer of the logic interlayer insulating layers 1100 may be bonded to the pixel circuit layer 20 of the sensor chip C1. The logic chip C2 may be electrically connected to the sensor chip C1 through the first through conductive pattern 510 and the second through conductive pattern 520.

In embodiments, the sensor chip C1 and the logic chip C2 have been described as being electrically connected to each other via the first and second through conductive patterns 510 and 520, but the disclosed concepts is not limited thereto.

According to the embodiment shown in FIG. 30, the first and second through conductive patterns 510 and 520 shown in FIG. 29 may be omitted, and the sensor chip C1 and the logic chip C2 may be electrically connected by directly bonding the bonding pads provided in the top metal layers of the sensor chip C2 and the logic chip C2 to each other.

In detail, in the sensor chip C1, the buried pattern 113 of the PD isolation pattern PIS extending from the light-receiving region AR to the light-blocking region OB may be connected to the backside contact plug PLG in the light-blocking region OB.

In addition, the sensor chip C1 may include first bonding pads BP1 provided in the uppermost metal layer of the pixel circuit layer 20, and the logic chip C2 may include second bonding pads BP2 provided in the upper most metal layer of the metal wirings 1111. The first and second bonding pads BP1 and BP2 may include, for example, at least one of tungsten (W), aluminum (Al), copper (Cu), tungsten nitride (WN), tantalum nitride (TaN), and titanium nitride (TiN).

The first bonding pads BP1 of the sensor chip C1 and the second bonding pads BP2 of the logic chip C2 may be directly and electrically connected to each other in a hybrid bonding manner. The hybrid bonding manner may refer to bonding for fusing two components including homogeneous materials at an interface therebetween. For example, when the first and second bonding pads BP1 and BP2 are formed of copper (Cu), the first and second bonding pads BP1 and BP2 may be physically and electrically connected by copper (Cu)-copper (Cu) bonding. In addition, a surface of an insulating layer of the sensor chip C1 and a surface of an insulating layer of the logic chip C2 may be bonded by dielectric-dielectric bonding.

According to embodiments of the disclosed concepts, by forming an interconnection conductive pattern connecting the floating diffusion regions spaced apart from each other, it is possible to prevent or reduce an increase of capacitance and a delay of signals, which may occur when a metal layer is used for the connection, and to improve a conversion gain in a unit pixel. In addition, it may be possible to increase a degree of freedom of constructing an interconnection structure the image sensor.

Further, a portion of the source follower gate electrode may be extended onto the device isolation layer or the PD isolation pattern to be adjacent to the interconnection conductive pattern, and a common contact plug may be commonly connected to the interconnection conductive pattern and a portion of the source follower gate electrode. Accordingly, the metal wirings connecting the floating diffusion regions and the source follower gate electrode may be reduced, so that the conversion gain in the unit pixel can be further improved.

While embodiments are described above, a person skilled in the art may understand that many modifications and variations are made without departing from the spirit and scope of the disclosed concepts defined in the following claims. Accordingly, the example embodiments of the disclosed concepts should be considered in all respects as illustrative and not restrictive, with the spirit and scope of the disclosed concepts being indicated by the appended claims.

What is claimed is:

1. An image sensor, comprising:
a semiconductor substrate;
a PD isolation pattern disposed in the semiconductor substrate and defining first and second PD regions;
a first floating diffusion region provided in the semiconductor substrate of the first PD region;
an interconnection conductive pattern disposed on a first surface of the semiconductor substrate and contacting the first floating diffusion region;
a source follower gate electrode provided in the second PD region, the source follower gate electrode including a first portion disposed on the semiconductor substrate of the second PD region and a second portion extended from the first portion and disposed on the PD isolation pattern, the second portion being adjacent to the interconnection conductive pattern; and
a common contact plug commonly connected to the source follower gate electrode and the interconnection conductive pattern.

2. The image sensor of claim 1, wherein the common contact plug contacts a top surface of the second portion of the source follower gate electrode and a top surface of the interconnection conductive pattern.

3. The image sensor of claim 1, wherein a top surface of the interconnection conductive pattern is located at a different level from a top surface of the source follower gate electrode.

4. The image sensor of claim 1, wherein a portion of the common contact plug contacts the PD isolation pattern between the second portion of the source follower gate electrode and the interconnection conductive pattern.

5. The image sensor of claim 1, wherein the common contact plug contacts a sidewall and a top surface of the second portion of the source follower gate electrode.

6. The image sensor of claim 1, wherein a bottom surface of the common contact plug is located at a lower level than a top surface of the PD isolation pattern.

7. The image sensor of claim 1, further comprising a contact plug connected to the source follower gate electrode,
wherein the contact plug comprises the same conductive material as the common contact plug.

8. The image sensor of claim 1, wherein the interconnection conductive pattern is spaced apart from the second portion of the source follower gate electrode in a first direction, and
wherein the common contact plug has a length in the first direction and a width less than the length in a second direction perpendicular to the first direction.

9. The image sensor of claim 1, further comprising:
first and second photoelectric conversion regions disposed in the semiconductor substrate in each of the first and second PD regions; and
first and second transfer gate electrodes provided in the first and second PD regions, respectively,
wherein the first floating diffusion region is provided in common between the first and second transfer gate electrodes.

10. The image sensor of claim 1, further comprising:
first and second photoelectric conversion regions disposed in the semiconductor substrate, in each of the first and second PD regions; and
first and second transfer gate electrodes provided in each of the first and second PD regions, respectively,
wherein each of the first and second floating diffusion regions includes a first doped region provided at a first side of the first transfer gate electrode and a second doped region provided at a first side of the second transfer gate electrode, and
wherein the interconnection conductive pattern commonly contacts the first and second doped regions of the first floating diffusion region.

11. The image sensor of claim 1, further comprising:
a pixel gate electrode provided in the first PD region;
source/drain regions provided in the semiconductor substrate at opposite sides of the pixel gate electrode;
a conductive pad contacting one of the source/drain regions; and
a connection contact plug commonly contacts with the conductive pad and the interconnection conductive pattern.

12. The image sensor of claim 11, wherein the interconnection conductive pattern includes a first connection portion contacting the first floating diffusion region and a second connection portion extended from the first connection portion and being adjacent to the conductive pad, and
wherein the connection contact plug contacts the second connection portion of the interconnection conductive pattern and the conductive pad.

13. An image sensor, comprising:
a semiconductor substrate;
a PD isolation pattern disposed within the semiconductor substrate to define first and second PD regions;
a first floating diffusion region provided in the semiconductor substrate in the first PD region;
a second floating diffusion region provided in the semiconductor substrate in the second PD region;
an interconnection conductive pattern disposed on a first surface of the semiconductor substrate and contacting the first floating diffusion region;
a pixel transistor provided in the second PD region and including a pixel gate electrode and source/drain regions at opposite sides of the pixel gate electrode; and
a common contact plug connecting the interconnection conductive pattern with either the pixel gate electrode or the source/drain regions.

14. The image sensor of claim 13, wherein the pixel gate electrode includes a first portion disposed on the semiconductor substrate of the second PD region and a second portion adjacent to the first floating diffusion region and disposed on the PD isolation pattern, and
wherein the common contact plug contacts the second portion of the pixel gate electrode and a portion of the interconnection conductive pattern.

15. The image sensor of claim 13, further comprising a conductive pad contacts one of the source/drain regions,
wherein the common contact plug contacts a portion of the interconnection conductive pattern and a portion of the conductive pad.

16. The image sensor of claim 15, wherein the interconnection conductive pattern includes a first connection portion contacting the first and second floating diffusion regions and a second connection portion extended from the first connection portion and disposed on the PD isolation pattern, and
wherein the second connection portion is adjacent to the conductive pad.

17. The image sensor of claim 13, wherein the common contact plug has a length in a first direction and a width less than the length in a second direction perpendicular to the first direction.

18. An image sensor, comprising:
a semiconductor substrate having a first surface and a second surface opposite to the first surface;
a PD isolation pattern disposed in the semiconductor substrate to define first to fourth PD regions;
photoelectric conversion regions provided in the semiconductor substrate in the first to fourth PD regions;
a device isolation layer adjacent to the first surface of the semiconductor substrate, the device isolation layer defining first and second active portions in each of the first to fourth PD regions;
transfer gate electrodes provided in the first active portions of the first to fourth PD regions;
floating diffusion regions provided in the first active portions of the first to fourth PD regions;
pixel transistors provided in the second active portions of the first to fourth PD regions, one of the pixel transistors including a pixel gate electrode including a first portion disposed on the second active portions in the third and fourth PD regions and second portions extending from the first portion and disposed on the PD isolation pattern and adjacent to the floating diffusion regions in the first and second PD regions;
interconnection conductive patterns contacting the floating diffusion regions of the first to fourth PD regions, respectively;
common contact plugs connecting the pixel gate electrode with the interconnection conductive patterns of the first to fourth PD regions;
color filters disposed corresponding to the PD regions on the second surface of the semiconductor substrate;
a grid disposed between the color filters and overlapping with the PD isolation pattern; and
micro-lenses on the color filters.

19. The image sensor of claim 18, wherein a portion of each of the common contact plugs contacts the PD isolation pattern between the pixel gate electrode and the interconnection conductive patterns.

20. The image sensor of claim 18, wherein each of the common contact plugs has a length in a first direction and a width less than the length in a second direction perpendicular to the first direction.
